(19) United States
(12) Patent Application Publication
(10) Pub. No.: US 2017/0244044 A1
(43) Pub. Date: Aug. 24, 2017

(54) ORGANIC ELECTROLUMINESCENT ELEMENT AND ELECTRONIC DEVICE

(71) Applicant: IDEMITSU KOSAN CO., LTD., Chiyoda-ku (JP)

(72) Inventors: Takeshi IKEDA, Mapo-gu (KR); Tetsuya MASUDA, Chiba-shi (JP); Yoshiaki TAKAHASHI, Chiba-shi (JP)

(73) Assignee: IDEMITSU KOSAN CO., LTD., Chiyoda-ku (JP)

(21) Appl. No.: 15/415,063

(22) Filed: Jan. 25, 2017

(30) Foreign Application Priority Data
Feb. 18, 2016 (JP) 2016-029054

(51) Int. Cl. H01L 51/00

(52) U.S. Cl. CPC H01L 51/0052; H01L 51/0072; H01L 51/0067; H01L 51/0058; H01L 51/0054; H01L 51/0073; H01L 51/5072

(57) ABSTRACT

The present invention provides an organic electroluminescence device including a cathode, an anode, and an organic thin film layer which is formed of one layer or plural layers at least containing a light emitting layer and which is sandwiched between the cathode and an anode, the device further includes an electron transporting layer between the light emitting layer and the cathode, wherein the electron transporting layer contains at least a specific compound (1) and a specific compound (2), and the compound (1) and the compound (2) satisfy the expression (A): Electron mobility of compound (1)>Electron mobility of compound (2)>10⁻⁷ cm²/Vs. The organic electroluminescence device has a high light emission efficiency and has a more prolonged lifetime. The present invention also provides an electronic device provided with the organic EL device.

### FIELD OF THE INVENTION

The present invention relates to an organic electroluminescence device and an electronic device provided with the organic electroluminescence device.

### BACKGROUND OF THE INVENTION

In general, an organic electroluminescence (EL) device is composed of an anode, a cathode and one or more organic thin film layers sandwiched between the anode and the cathode. When voltage is applied across the electrodes, electrons and holes are injected into the light emitting region from the cathode side and from the anode side, respectively. The injected electrons and holes recombine in the light emitting region to form an excited state, and light is emitted when the excited state returns to the ground state.

Because a wide variety of colors can be obtained when various luminescent materials are used for the light emitting layer, intensive studies on the practical use of an organic EL device, for example use in a display, are conducted. In particular, the studies on luminescent materials for the three primary colors, red, green and blue, are most extensively conducted, and the materials are studied intensively for the improvement of the properties.

A problem with an organic EL device is mainly how to increase the light emission efficiency and the lifetime thereof. As an invention to solve the problem, for example, PTLs 1 and 2 describe organic electroluminescence devices in which an interlayer energy relationship thereof is specified.

### CITATION LIST

### Patent Literature

PTL 1: JP 2006-172762 A
PTL 2: Japanese Patent 5238889

### SUMMARY OF THE INVENTION

### Technical Problem

Further investigations made by the present inventors have clarified that, in the inventions disclosed in PTLs 1 and 2, there is still room for further improvement.

Given the situation, an object of the present invention is to provide an organic EL device having a high light emission efficiency and having a prolonged lifetime, and an electronic device provided with the organic EL device.

### Solution to Problem

For solving the above-mentioned problems, the present inventors have assiduously studied and, as a result, have found that, when the electron transporting layer to be used between a light emitting layer and a cathode contains specific two or more kinds of compounds, which each have a specific electron mobility, the above-mentioned problems can be solved.

Aspects of the present invention are the following [1] to [3].

[1] An organic electroluminescence device including a cathode, an anode, and an organic thin film layer which is formed of one layer or plural layers at least containing a light emitting layer and which is sandwiched between the cathode and the anode,

the device further including an electron transporting layer between the light emitting layer and the cathode,

wherein the electron transporting layer contains at least compound (1) and compound (2), and the compound (1) and the compound (2) satisfy the following expression (A):

Electron mobility of compound (1)>Electron mobility of compound (2)>10⁻⁷ cm²/Vs (A)

wherein the compound (1) is a compound selected from compounds represented by the following formulae (I), (II) and (III) and the compound (2) is a compound selected from compounds represented by the following formula (IV) and compounds represented by the following formula (V):

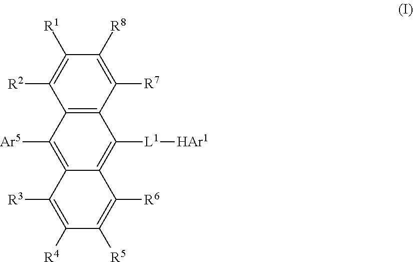

wherein L¹ represents a single bond, a substituted or unsubstituted arylene group having 6 to 30 ring carbon atoms, or a substituted or unsubstituted heteroarylene group having 5 to 30 ring atoms;

Ar⁵ represents a substituted or unsubstituted awl group having 6 to 30 ring carbon atoms, or a substituted or unsubstituted heteroaryl group having 5 to 30 ring atoms; and

HAr¹ represents a group represented by the following formula (a):

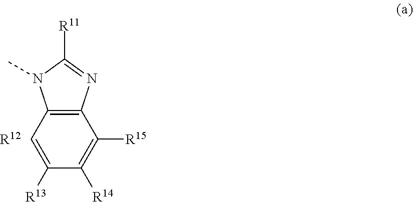

wherein R¹ to R⁸ and R¹¹ to R¹⁵ each independently represent a hydrogen atom, a fluorine atom, a cyano group, a substituted or unsubstituted alkyl group having 1 to 20 carbon atom, a substituted or unsubstituted cycloalkyl group having 3 to 20 ring carbon atoms, a substituted or unsubstituted alkoxy group having 1 to 20 carbon atoms, a substituted or unsubstituted aryloxy group having 6 to 30 ring carbon atoms, a substituted or unsubstituted alkylthio group having 1 to 20 carbon atoms, a substituted or unsubstituted arylthio group having 6 to 30 ring carbon atoms, a substituted or unsubstituted aryl group having 6 to 30 ring carbon atoms, a substituted or unsubstituted heteroaryl group having 5 to 30 ring atoms, or a group represented by —Si(R₁₀₁)(R₁₀₂)(R₁₀₃) where R₁₀₁ to R₁₀₃ each independently represent a hydrogen atom, a substituted or unsubstituted alkyl group having 1 to 20 carbon atoms, or a substituted or unsubstituted aryl group having 6 to 30 ring carbon atoms:

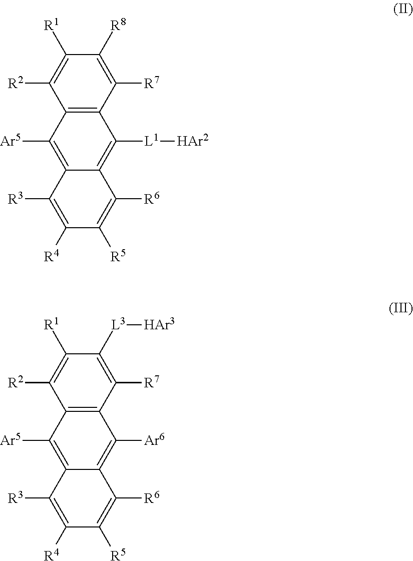

wherein L² and L³ each independently represent a single bond, a substituted or unsubstituted arylene group having 6 to 30 ring carbon atoms, or a substituted or unsubstituted heteroarylene group having 5 to 30 ring atoms;

Ar⁵ and Ar⁶ each represent a substituted or unsubstituted aryl group having 6 to 30 ring carbon atoms, or a substituted or unsubstituted heteroaryl group having 5 to 30 ring atoms;

R¹ to R⁸ are as defined above;

HAr² and HAr³ each independently represent a group represented by the following formula (b):

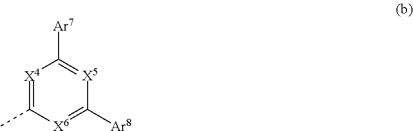

wherein Ar⁷ and Ar⁸ each independently represent a hydrogen atom, a substituted or unsubstituted aryl group having 6 to 30 ring carbon atoms, or a substituted or unsubstituted heteroaryl group having 5 to 30 ring atoms; and

X⁴ to X⁶ each independently represent N or CR⁰, with the proviso that at least one is N, R⁰ represents a hydrogen atom, a substituted or unsubstituted alkyl group having 1 to 20 carbon atoms, or a substituted or unsubstituted aryl group having 6 to 30 ring carbon atoms, and when plural R⁰'s are present, they may be the same or different:

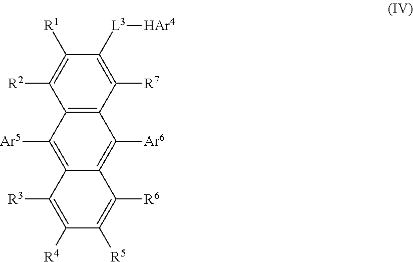

wherein Ar⁵, Ar⁶, and R¹ to R⁷ are as defined above;

L⁴ represents a single bond, a substituted or unsubstituted aryl ene group having 6 to 30 ring carbon atoms, or a substituted or unsubstituted heteroarylene group having 5 to 30 ring atoms; and

HAr⁴ represents a group represented by the following formula (a) or (c):

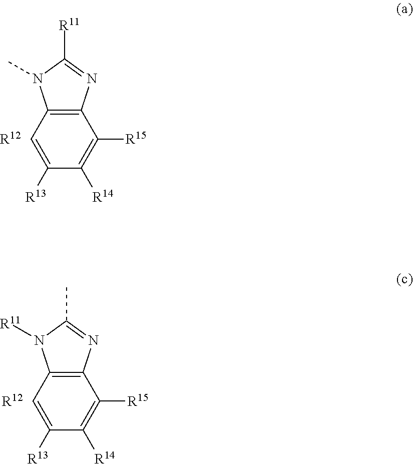

wherein R¹¹ to R¹⁵ are as defined above: and

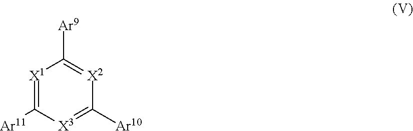

wherein Ar⁹ to Ar¹¹ each independently represent a hydrogen atom, or a monovalent residue containing at least one selected from aromatic hydrocarbon compounds represented by the following formulae (d) to (l), substituted or unsubstituted heteroaromatic compounds each having 5 to 30 ring atoms, and groups formed by bonding a plurality of these compounds to each other, and when a plurality of the compounds is bonded, the compounds which each constitute a bonding unit may be the same or different:

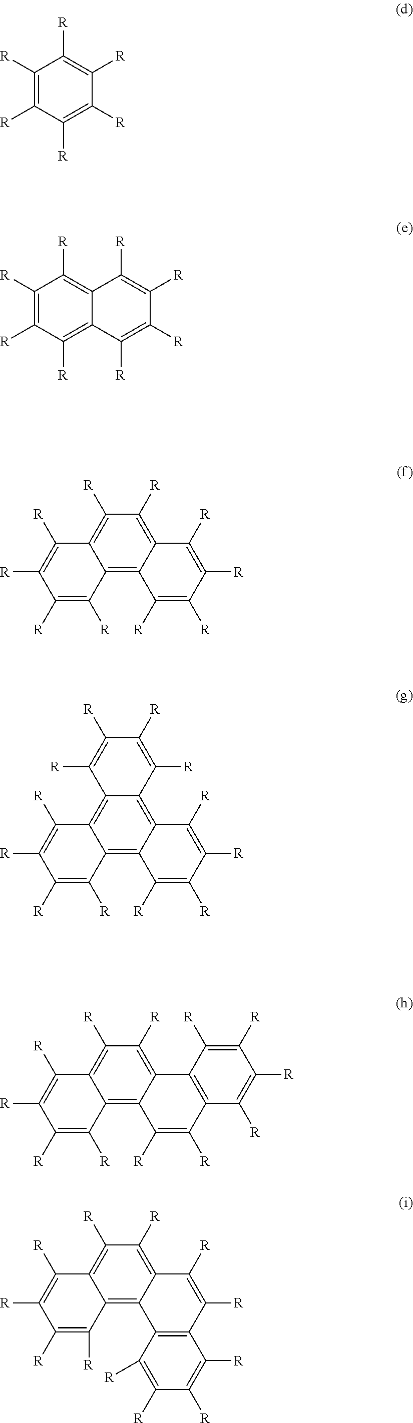

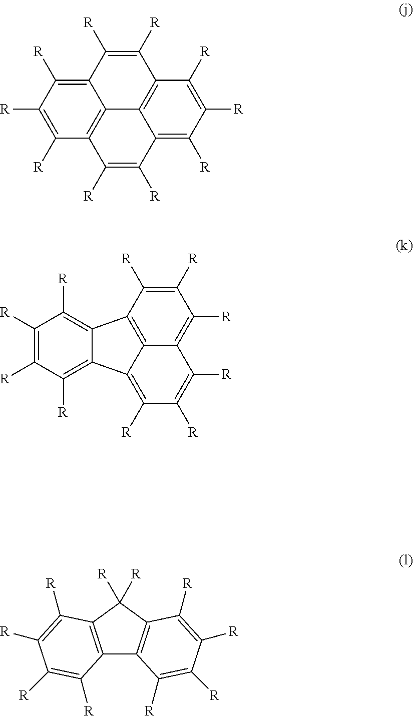

wherein R represents a hydrogen atom, a fluorine atom, a cyano group, or a substituted or unsubstituted alkyl group having 1 to 20 carbon atoms; and

X¹ to X³ each independently represent N or CR⁰, with the proviso that at least one is N, and R⁰ is as defined above.

[2] An organic electroluminescence device including a cathode, an anode, and an organic thin film layer which is formed of one layer or plural layers at least containing a light emitting layer and which is sandwiched between the cathode and the anode,

the device further including an electron transporting layer between the light emitting layer and the cathode,

wherein the electron transporting layer contains at least the following compound (1′) and the following compound (2), and

the compound (1′) is a compound selected from the compounds represented by the following formula (I) and the compound (2) is a compound selected from compounds represented by the following formula (IV) and compounds represented by the following formula (V).

[3] An electronic device provided with the organic electroluminescence device according to the above [1] or [2].

### Advantageous Effects of Invention

The organic EL device of the present invention has a high light emission efficiency and a long lifetime. Accordingly, the device is useful as various electronic devices.

### BRIEF DESCRIPTION OF DRAWINGS

FIG. 1 is a schematic view showing an example of a configuration of an organic electroluminescence device according to an embodiment of the present invention.

### DETAILED DESCRIPTION OF THE INVENTION

In this description, the “XX to YY carbon atoms” in an expression “a substituted or unsubstituted ZZ group having XX to YY carbon atoms” refer to the number of the carbon atoms of the unsubstituted ZZ group, and when the ZZ group has a substituent, the carbon atoms of the substituent are not included.

Also in this description, the “XX to YY atoms” in an expression “a substituted or unsubstituted ZZ group having XX to YY atoms” refer to the number of the atoms of the unsubstituted ZZ group, and when the ZZ group has a substituent, the atoms of the substituent are not included.

In this description, the number of the ring carbon atoms refers to the number of the carbon atoms of the atoms constituting the ring itself of a compound having a structure in which the atoms combine and form a ring (for example, a monocyclic compound, a condensed ring compound, a cross-linked compound, a carbocyclic compound or a heterocyclic compound). When the ring has a substituent, the carbon atoms contained in the substituent are not counted as the ring carbon atoms. The term “ring carbon atoms” used below is the same unless otherwise noted. For example, a benzene ring has six ring carbon atoms, and a naphthalene ring has 10 ring carbon atoms. A pyridinyl group has five ring carbon atoms, and a furanyl group has four ring carbon atoms. When a benzene ring or a naphthalene ring has an alkyl group as a substituent for example, the carbon atoms of the alkyl group are not counted as the ring carbon atoms. Also, when a fluorene ring is bonded to another fluorene ring as a substituent for example (including a spirofluorene ring), the carbon atoms of the fluorene ring as the substituent are not counted as the ring carbon atoms.

In this description, the number of the ring atoms refers to the number of the atoms constituting the ring itself of a compound having a structure in which the atoms combine and form a ring (for example a monocycle, a condensed ring or a ring assembly) (for example, the compound is a monocyclic compound, a condensed ring compound, a cross-linked compound, a carbocyclic compound or a heterocyclic compound). The atoms which do not constitute the ring and the atoms contained in a substituent which the ring has, if any, are not counted as the ring atoms. The term “ring atoms” used below is the same unless otherwise noted. For example, a pyridine ring has six ring atoms, and a quinazoline ring has 10 ring atoms. A furan ring has five ring atoms. The hydrogen atoms bonded to the carbon atoms of a pyridine ring or a quinazoline ring and the atoms constituting a substituent are not counted as the ring atoms. When a fluorene ring is bonded to another fluorene ring as a substituent for example (including a spirofluorene ring), the atoms of the fluorene ring as the substituent are not counted as the ring atoms.

In this description, the term “hydrogen atom” includes isotopes with a different number of neutrons, namely protium, deuterium and tritium.

In this description, the “heteroaryl group”, the “heteroarylene group” and the “heterocyclic group” each are a group containing at least one hetero atom as a ring atom, and the hetero atom is preferably one or more selected from a nitrogen atom, an oxygen atom, a sulfur atom, a silicon atom and a selenium atom.

In this description, the “substituted or unsubstituted carbazolyl group” includes the following carbazolyl groups:

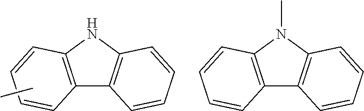

and substituted carbazolyl groups of the above groups further having any optional substituent.

In the substituted carbazolyl group, the optional substituents may bond to each other to form a condensed ring, and may contain a hetero atom such as a nitrogen atom, an oxygen atom, a sulfur atom, a silicon atom, a selenium atom and the like, and the bonding position may be any of the 1-position to 9-position. Specific examples of the substituted carbazolyl group include the following groups.

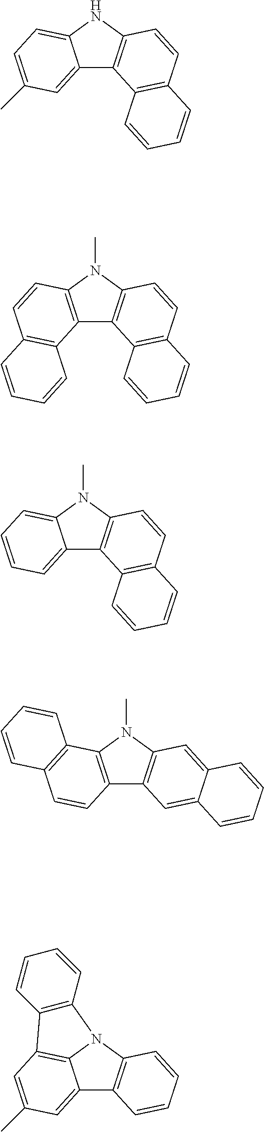 [SMILES: Cc1ccc2[nH]c3ccc4ccccc4c3c2c1 ; Cn1c2ccc3ccccc3c2c2c3ccccc3ccc21 ; Cn1c2ccccc2c2c3ccccc3ccc21 ; Cn1c2cc3ccccc3cc2c2ccc3ccccc3c21 ; Cc1cc2c3ccccc3n3c4ccccc4c(c1)c23]

In this description, the “substituted or unsubstituted dibenzofuranyl group” and the “substituted or unsubstituted dibenzothiophenyl group” include the following dibenzofuranyl group and dibenzothiophenyl group:

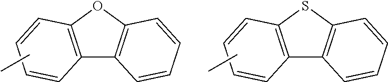

and substituted dibenzofuranyl groups and substituted dibenzothiophenyl groups of the above groups further having any optional substituent.

In the substituted dibenzofuranyl group and dibenzothiophenyl group, the optional substituents may bond to each other to form a condensed ring, and may contain a hetero atom such as a nitrogen atom, an oxygen atom, a sulfur atom, a silicon atom, a selenium atom and the like, and the bonding position may be any of the 1-position to 8-position.

Specific examples of the substituted dibenzofuranyl group and the substituted dibenzothiophenyl group include the following groups.

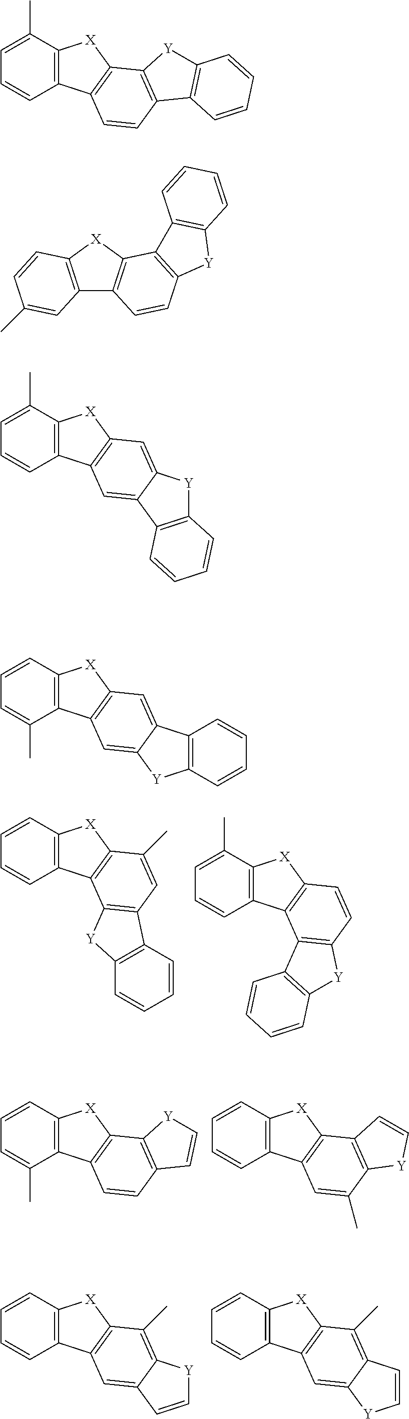

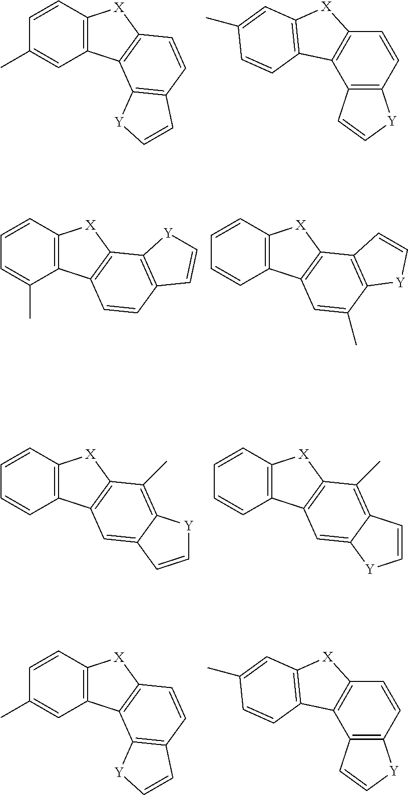

In the above formulae, X represents an oxygen atom or a sulfur atom, Y represents an oxygen atom, a sulfur atom, NH, NR^{a} (where R^{a} represents an alkyl group or an aryl group), CH₂ or CR^{b}₂ (where R^{b} represents an alkyl group or an aryl group).

The substituent referred to by the term “substituted or unsubstituted” and the substituent referred to by the simple term “substituent” are preferably at least one selected from the group consisting of: an alkyl group having 1 to 50 (preferably 1 to 18, and more preferably 1 to 8) carbon atoms; a cycloalkyl group having 3 to 50 (preferably 3 to 10, more preferably 3 to 8, and still more preferably 5 or 6) ring carbon atoms; an aryl group having 6 to 50 (preferably 6 to 25, and more preferably 6 to 18) ring carbon atoms; an aralkyl group having 7 to 51 (preferably 7 to 30, and more preferably 7 to 20) carbon atoms which has an aryl group having 6 to 50 (preferably 6 to 25, and more preferably 6 to 18) ring carbon atoms; an amino group; a mono-substituted or di-substituted amino group having a substituent selected from an alkyl group having 1 to 50 (preferably 1 to 18, and more preferably 1 to 8) carbon atoms and an aryl group having 6 to 50 (preferably 6 to 25, and more preferably 6 to 18) ring carbon atoms; an alkoxy group which has an alkyl group having 1 to 50 (preferably 1 to 18, and more preferably 1 to 8) carbon atoms; an aryloxy group which has an aryl group having 6 to 50 (preferably 6 to 25, and more preferably 6 to 18) ring carbon atoms; a mono-substituted, di-substituted or tri-substituted silyl group having a substituent selected from an alkyl group having 1 to 50 (preferably 1 to 18, and more preferably 1 to 8) carbon atoms and an aryl group having 6 to 50 (preferably 6 to 25, and more preferably 6 to 18) ring carbon atoms; a heteroaryl group having 5 to 50 (preferably 5 to 24, and more preferably 5 to 13) ring atoms; a haloalkyl group having 1 to 50 (preferably 1 to 18, and more preferably 1 to 8) carbon atoms; a halogen atom (a fluorine atom, a chlorine atom, a bromine atom or an iodine atom); a cyano group; a nitro group; a sulfonyl group having a substituent selected from an alkyl group having 1 to 50 (preferably 1 to 18, and more preferably 1 to 8) carbon atoms and an aryl group having 6 to 50 (preferably 6 to 25, and more preferably 6 to 18) ring carbon atoms; a di-substituted phosphoryl group having substituents selected from an alkyl group having 1 to 50 (preferably 1 to 18, and more preferably 1 to 8) carbon atoms and an aryl group having 6 to 50 (preferably 6 to 25, and more preferably 6 to 18) ring carbon atoms; an alkylsulfonyloxy group; an aryl sulfonyloxy group; an alkylcarbonyloxy group; an arylcarbonyloxy group; a boron-containing group; a zinc-containing group; a tin-containing group; a silicon-containing group; a magnesium-containing group; a lithium-containing group; a hydroxy group; an alkyl-substituted or aryl-substituted carbonyl group; a carboxyl group; a vinyl group; a (meth)acryloyl group; an epoxy group; and an oxetanyl group; however, the substituent is not specifically limited to these.

These substituents may further have any of the optional substituents above. Also, a plurality of these substituents may combine to form a ring.

“Unsubstituted” in the expression of “substituted or unsubstituted” means that the group is not substituted with any of the above-mentioned substituents, but has a hydrogen atom bonded thereto.

Of the substituents, more preferable substituents are a substituted or unsubstituted alkyl group having 1 to 50 (preferably 1 to 18, and more preferably 1 to 8) carbon atoms, a substituted or unsubstituted cycloalkyl group having 3 to 50 (preferably 3 to 10, more preferably 3 to 8, and still more preferably 5 or 6) ring carbon atoms, a substituted or unsubstituted aryl group having 6 to 50 (preferably 6 to 25, and more preferably 6 to 18) ring carbon atoms, a mono-substituted or di-substituted amino group having a substituent selected from a substituted or unsubstituted alkyl group having 1 to 50 (preferably 1 to 18, and more preferably 1 to 8) carbon atoms and a substituted or unsubstituted aryl group having 6 to 50 (preferably 6 to 25, and more preferably 6 to 18) ring carbon atoms, a substituted or unsubstituted heteroaryl group having 5 to 50 (preferably 5 to 24, and more preferably 5 to 13) ring atoms, a halogen atom and a cyano group.

In this description, preferred embodiments (for example, compounds, various groups, numerical ranges, etc.) may be combined with any other embodiments (for example, compounds, various groups, numerical ranges, etc.) in any desired combination, and combinations of preferred embodiments (including more preferred embodiments, even more preferred embodiments, especially preferred embodiments) can be said to be more preferred.

### [Organic EL Device]

The organic EL device of one aspect of the present invention is an organic electroluminescence device including a cathode, an anode, and an organic thin film layer which is formed of one layer or plural layers at least containing a light emitting layer and which is sandwiched between the cathode and the anode,

the device includes an electron transporting layer between the light emitting layer and the cathode,

wherein the electron transporting layer contains at least the following compound (1) and the following compound (2), and the compound (1) and the compound (2) satisfy the following expression (A).

Electron mobility of compound (1)>Electron mobility of compound (2)>10⁻⁷ cm²/Vs (A)

In the electron transporting layer of the organic EL device, when a compound having a high electron injection/transportation capability (electron mobility) is used alone, the driving voltage could lower but on the other hand, electrons may accumulate in the light emitting layer to interfere with light emission (deactivation of excitons owing to interaction with excitons), and electron may break through the light emitting layer before recombined with holes and, as a result, the light emission efficiency may lower. In addition, the hole transporting layer adjacent to the light emitting layer may be deteriorated by electrons and to shorten the lifetime of the organic EL device. Accordingly, when a compound which can maintain electron injection from cathode and which has a relatively low electron transportation capability is mixed, the electron accumulation in the light emitting layer may be reduced and the light emission efficiency and the lifetime could be thereby improved.

In the present invention, the two compounds (1) and (2) that differ in the electron transportation performance to satisfy the above-mentioned expression (A) are used, and the electron mobility of the compound (1) and the compound (2) is defined to be larger than 10⁻⁷ cm²/Vs, and the light emission efficiency and the lifetime are thereby improved.

In the expression (A), preferably, the electron mobility of the compound (1) is two times or more the electron mobility of the compound (2), more preferably 5 times or more, and even more preferably 10 times or more.

In addition, when the compounds satisfy the following expression (B), the light emission efficiency and the lifetime may be further improved.

Electron affinity (Af1) of compound (1)<Electron affinity (Af2) of compound (2) (B)

Further, when the electron mobility of the compound (1)>10⁻⁴ cm²/Vs, the light emission efficiency and the lifetime may be further more improved.

The organic EL device of one aspect of the present invention is an organic electroluminescence device including a cathode, an anode, and an organic thin film layer formed of one layer or plural layers at least containing a light emitting layer and which is sandwiched between the cathode and the anode,

the EL device further including an electron transporting layer between the light emitting layer and the cathode,

wherein the electron transporting layer contains at least the following compound (1′) and the following compound (2).

In the present invention, preferably, the light emitting layer is adjacent to the electron transporting layer that contains the above-mentioned compound (1) and the above-mentioned compound (2), and also preferably, the light emitting layer is adjacent to the electron transporting layer that contains the above-mentioned compound (1′) and the above-mentioned compound (2). In these cases, the light emission efficiency and the lifetime can be more improved.

In the present invention, the electron transporting layer preferably contains the compound (1) or (1′) and the compound (2).

Also preferably, the ratio by mass of the compound (1) or (1′) to the compound (2) is 1/9 to 9/1, more preferably 2/8 to 8/2.

Compound (1) is a compound selected from compounds represented by the following formulae (I), (II) and (III).

Compound (1′) is a compound selected from compounds represented by the following formula (I).

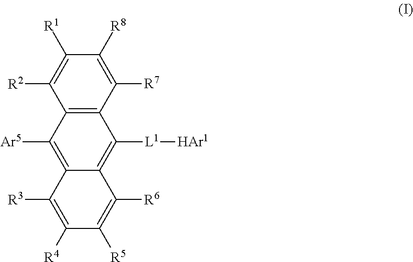

In the formula, L¹ represents a single bond, a substituted or unsubstituted arylene group having 6 to 30 ring carbon atoms, or a substituted or unsubstituted heteroarylene group having 5 to 30 ring atoms;

Ar⁵ represents a substituted or unsubstituted awl group having 6 to 30 ring carbon atoms, or a substituted or unsubstituted heteroaryl group having 5 to 30 ring atoms; and

HAr¹ represents a group represented by the following formula (a).

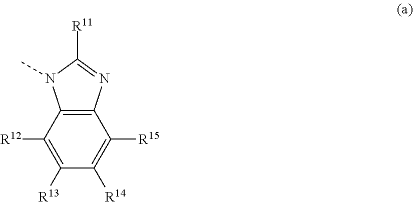

In the formulae, R¹ to R⁸ and R¹¹ to R¹⁵ each independently represent a hydrogen atom, a fluorine atom, a cyano group, a substituted or unsubstituted alkyl group having 1 to 20 carbon atom, a substituted or unsubstituted cycloalkyl group having 3 to 20 ring carbon atoms, a substituted or unsubstituted alkoxy group having 1 to 20 carbon atoms, a substituted or unsubstituted aryloxy group having 6 to 30 ring carbon atoms, a substituted or unsubstituted alkylthio group having 1 to 20 carbon atoms, a substituted or unsubstituted arylthio group having 6 to 30 ring carbon atoms, a substituted or unsubstituted awl group having 6 to 30 ring carbon atoms, a substituted or unsubstituted heteroaryl group having 5 to 30 ring atoms, or a group represented by —Si(R₁₀₁)(R₁₀₂)(R₁₀₃) where R₁₀₁ to R₁₀₃ each independently represent a hydrogen atom, a substituted or unsubstituted alkyl group having 1 to 20 carbon atoms, or a substituted or unsubstituted aryl group having 6 to 30 ring carbon atoms.

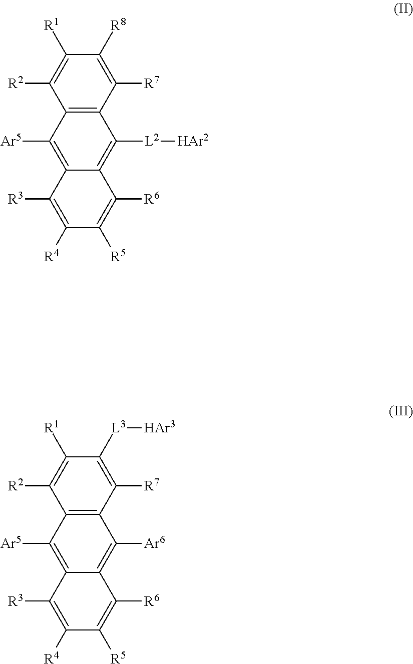

In the formulae, L² and L³ each independently represent a single bond, a substituted or unsubstituted aryl ene group having 6 to 30 ring carbon atoms, or a substituted or unsubstituted heteroarylene group having 5 to 30 ring atoms;

Ar⁵ and Ar⁶ each represent a substituted or unsubstituted aryl group having 6 to 30 ring carbon atoms, or a substituted or unsubstituted heteroaryl group having 5 to 30 ring atoms;

R¹ to R⁸ are the same as above;

HAr² and HAr³ each independently represent a group represented by the following formula (b).

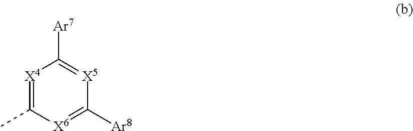

In the formula, Ar⁷ and Ar⁸ each independently represent a hydrogen atom, a substituted or unsubstituted aryl group having 6 to 30 ring carbon atoms, or a substituted or unsubstituted heteroaryl group having 5 to 30 ring atoms; and

X⁴ to X⁶ each independently represent N or CR⁰, with the proviso that at least one is N, and R⁰ represents a hydrogen atom, a substituted or unsubstituted alkyl group having 1 to 20 carbon atoms, or a substituted or unsubstituted aryl group having 6 to 30 ring carbon atoms, and when plural R⁰'s are present, they may be the same or different.

Preferably, the compound (1) is a compound selected from compounds represented by the formula (I).

Compound (2) is a compound selected from compounds represented by the following formula (IV) and compounds represented by the following formula (V).

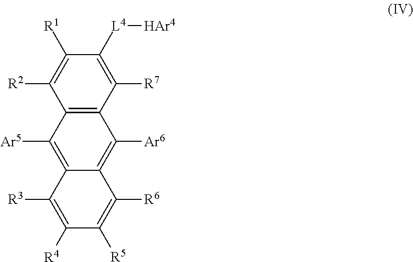

In the formula, Ar⁵, Ar⁶, and R¹ to R⁷ are the same as above;

L⁴ represents a single bond, a substituted or unsubstituted arylene group having 6 to 30 ring carbon atoms, or a substituted or unsubstituted heteroarylene group having 5 to 30 ring atoms; and

HAr⁴ represents a group represented by the following formula (a) or (c):

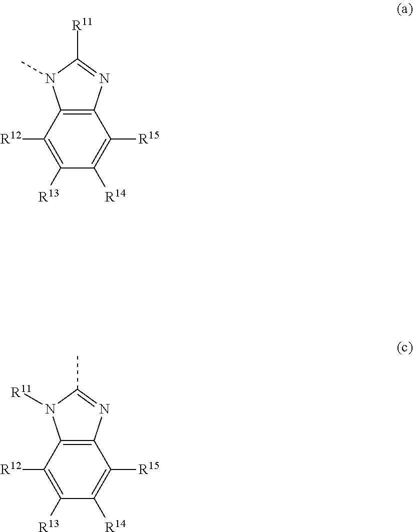

wherein R¹¹ to R¹⁵ are the same as above.

In the formula (IV), preferably, Ar⁵ and Ar⁶ each are an aryl group having 6 to 10 ring carbon atoms, more preferably a naphthyl group.

In the formula (IV), HAr⁴ is preferably represented by the formula (a). R¹¹ is preferably an aryl group having 6 to 10 ring carbon atoms, more preferably a phenyl group.

L⁴ is preferably an arylene group having 6 to 10 ring carbon atoms, more preferably a phenylene group.

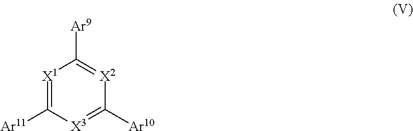

In the formula, Ar⁹ to Ar¹¹ each independently represent a hydrogen atom, or a monovalent residue containing at least one selected from aromatic hydrocarbon compounds represented by the following formulae (d) to (l), substituted or unsubstituted heteroaromatic compounds each having 5 to 30 ring atoms, and groups formed by bonding a plurality of these compounds to each other, and when a plurality of the compounds is bonded, the compounds which each constitute a bonding unit may be the same or different:

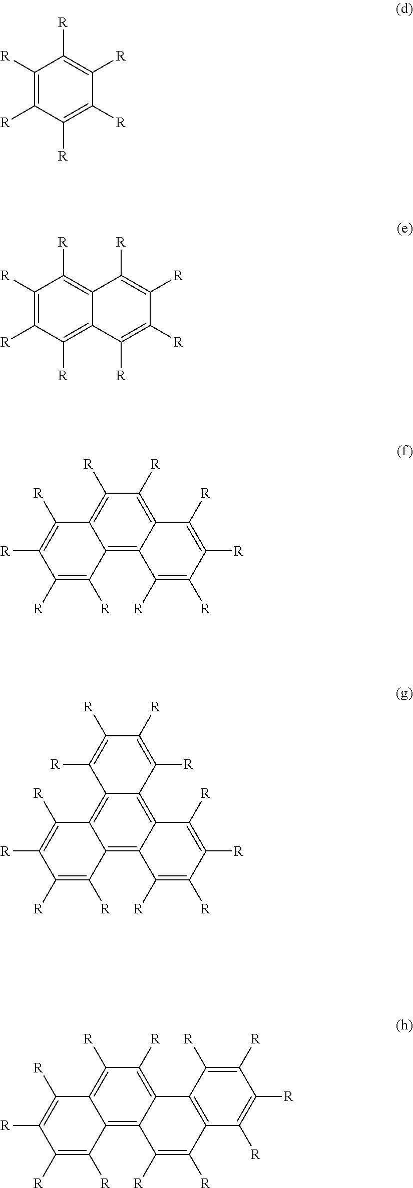

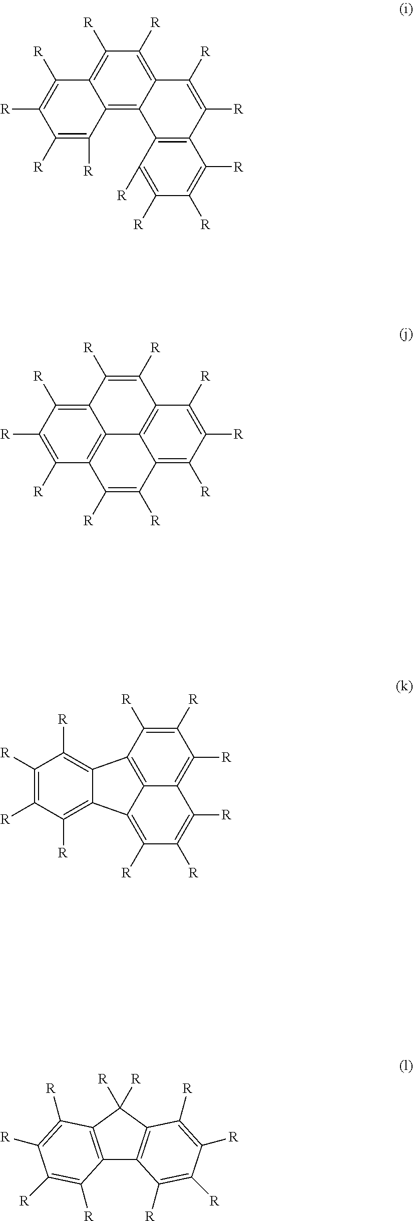

wherein R represents a hydrogen atom, a fluorine atom, a cyano group, or a substituted or unsubstituted alkyl group having 1 to 20 carbon atoms;

X¹ to X³ each independently represent N or CR⁰, with the proviso that at least one is N; and

R⁰ is the same as above.

Examples of the alkyl group having 1 to 20 (preferably 1 to 10, more preferably 1 to 6) carbon atoms represented by R, R⁰, R¹ to R⁸, R¹¹ to R¹⁵ and R₁₀₁ to R₁₀₃ in the formulae (I) to (V), and (a) to (l) include a methyl group, an ethyl group, a n-propyl group, an isopropyl group, a n-butyl group, an isobutyl group, a s-butyl group, a t-butyl group, a pentyl group (including isomer groups), a hexyl group (including isomer groups), a heptyl group (including isomer groups), an octyl group (including isomer groups), a nonyl group (including isomer groups), a decyl group (including isomer groups), an undecyl group (including isomer groups), a dodecyl group (including isomer groups), etc. Among these, a methyl group, an ethyl group, a n-propyl group, an isopropyl group, a n-butyl group, an isobutyl group, a s-butyl group, a t-butyl group and a pentyl group (all including isomer groups) are preferred; a methyl group, an ethyl group, a n-propyl group, an isopropyl group, a n-butyl group, an isobutyl group, a s-butyl group and a t-butyl group are more preferred; and a methyl group, an ethyl group, an isopropyl group and a t-butyl group are especially preferred.

Examples of the cycloalkyl group having 3 to 20 (preferably 3 to 6, more preferably 5 or 6) ring carbon atoms represented by R¹ to R⁸ and R¹¹ to R¹⁵ in the formulae (I) to (IV), (a) and (c) include a cyclopropyl group, a cyclobutyl group, a cyclopentyl group, a cyclohexyl group, a cycloheptyl group, a cyclooctyl group, an adamantyl group, etc. Among these, a cyclopentyl group and a cyclohexyl group are preferred.

An alkoxy group having 1 to 20 (preferably 1 to 10, more preferably 1 to 6) carbon atoms represented by R¹ to R⁸ and R¹¹ to R¹⁵ in the formulae (I) to (IV), (a) and (c) includes an alkoxy group in which the alkyl group moiety is the above-mentioned alkyl group having 1 to 20 carbon atoms. Preferred examples of the alkoxy group are those where the alkyl group moiety is the above-mentioned preferred alkyl group.

The aryloxy group having 6 to 30 (preferably 6 to 24, more preferably 6 to 18, even more preferably 6 to 10) ring carbon atoms represented by R¹ to R⁸ and R¹¹ to R¹⁵ in the formulae (I) to (IV), (a) and (c) includes those where the aryl group moiety is an aryl group having 6 to 30 ring carbon atoms of R⁰ to be mentioned hereinunder. Preferred examples of the aryloxy group include those where the aryl group moiety is the preferred aryl group to be mentioned below.

The alkylthio group having 1 to 20 (preferably 1 to 10, more preferably 1 to 6) carbon atoms represented by R¹ to R⁸ and R¹¹ to R¹⁵ in the formulae (I) to (IV), (a) and (c) includes an alkylthio group in which the alkyl group moiety is the above-mentioned alkyl group having 1 to 20 carbon atoms. Preferred examples of the alkylthio group include those where the alkyl group moiety is the above-mentioned preferred alkyl group.

The arylthio group having 6 to 30 (preferably 6 to 24, more preferably 6 to 18, even more preferably 6 to 10) ring carbon atoms represented by R¹ to R⁸ and R¹¹ to R¹⁵ in the formulae (I) to (IV), (a) and (c) includes those where the aryl group moiety is an aryl group having 6 to 30 ring carbon atoms of R⁰ to be mentioned hereinunder. Preferred examples of the arylthio group include those where the aryl group moiety is the preferred aryl group to be mentioned below.

Specifically, the “group represented by —Si(R₁₀₁)(R₁₀₂)(R₁₀₃)” represented by R¹ to R⁸ and R¹¹ to R¹⁵ in the formulae (I) to (IV), (a) and (c) includes a monoalkylsilyl group, a dialkylsilyl group, a trialkylsilyl group; a monoarylsilyl group, a diarylsilyl group, a triarylsilyl group; and a monoalkyldiarylsilyl group, a dialkylmonoarylsilyl group.

In these substituted silyl groups, the carbon number of the alkyl group moiety is preferably 1 to 20, more preferably 1 to 10, even more preferably 1 to 6. The ring carbon number of the aryl group moiety is preferably 6 to 30, more preferably 6 to 24, even more preferably 6 to 18, especially preferably 6 to 10.

Among these, a trialkylsilyl group and a triarylsilyl group are preferred; and a trimethylsilyl group, a triethylsilyl group, a triisopropylsilyl group, a t-butyldimethylsilyl group, a triphenylsilyl group and a tritolylsilyl group are more preferred.

The aryl group having 6 to 30 (preferably 6 to 24, more preferably 6 to 18, even more preferably 6 to 10) ring carbon atoms represented by R⁰, R¹ to R⁸, R¹¹ to R¹⁵, R₁₀₁ to R₁₀₃, and Ar⁵ to Ar⁸ in the formulae (I) to (IV) and (a) to (c) may be a condensed ring or a non-condensed ring. Examples of the aryl group include a phenyl group, a biphenylyl group, a terphenylyl group, a naphthyl group, an acenaphthylenyl group, an anthryl group, a benzoanthryl group, an aceanthryl group, a phenanthryl group, a benzo[c]phenanthryl group, a phenalenyl group, a fluorenyl group, a picenyl group, a pentaphenyl group, a pyrenyl group, a chrysenyl group, a benzo[g]chrysenyl group, a s-indacenyl group, an as-indacenyl group, a fluoranthenyl group, a benzo[k]fluoranthenyl group, a triphenylenyl group, a benzo[b]triphenylenyl group, a perylenyl group, etc. Among these, a phenyl group, a biphenylyl group, a terphenylyl group, a naphthyl group, an anthryl group, a pyrenyl group and fluoranthenyl group are preferred; a phenyl group, a biphenylyl group and a terphenylyl group are more preferred; and a phenyl group is even more preferred.

The heteroaryl group having 5 to 30 (preferably 5 to 24, more preferably 5 to 12) ring atoms represented by R¹ to R⁸, R¹¹ to R¹⁵ and Ar⁵ to Ar⁸ in the formulae (I) to (IV) and (a) to (c) contains at least one, preferably 1 to 5, more preferably 1 to 4, even more preferably 1 to 3 hetero atoms. Examples of the hetero atom include a nitrogen atom, a sulfur atom and an oxygen atom; and a nitrogen atom and an oxygen atom are preferred.

Examples of the heteroaryl group include a pyrrolyl group, a furyl group, a thienyl group, a pyridyl group, an imidazopyridyl group, a pyridazinyl group, a pyrimidinyl group, a pyrazinyl group, a triazinyl group, an imidazolyl group, an oxazolyl group, a thiazolyl group, a pyrazolyl group, an isoxazolyl group, an isothiazolyl group, an oxadiazolyl group, a thiadiazolyl group, a triazolyl group, a tetrazolyl group, an indolyl group, an isoindolyl group, a benzofuranyl group, an isobenzofuranyl group, a benzothiophenyl group, an isobenzothiophenyl group, an indolidinyl group, a quinolidinyl group, a quinolyl group, an isoquinolyl group, a cinnolyl group, a phthalazinyl group, a quinazolinyl group, a quinoxalinyl group, a benzimidazolyl group, a benzoxazolyl group, a benzothiazolyl group, an indazolyl group, a benzisoxazolyl group, a benzisothiazolyl group, a dibenzofuranyl group, a dibenzothiophenyl group, a carbazolyl group, a 9-phenylcarbazolyl group, a phenanthridinyl group, an acridinyl group, a phenanthrolinyl group, a phenazinyl group, a phenothiazinyl group, a phenoxazinyl group, a xanthenyl group, etc. Among these, a pyridyl group, an imidazopyridyl group, a pyridazinyl group, a pyrimidinyl group, a pyrazinyl group, a triazinyl group, a benzimidazolyl group, a dibenzofuranyl group, a dibenzothiophenyl group, a carbazolyl group, a 9-phenylcarbazolyl group, a phenanthrolinyl group and a quinazolinyl group are preferred.

The arylene group having 6 to 30 (preferably 6 to 24, more preferably 6 to 18, even more preferably 6 to 10) ring carbon atoms represented by L¹ to L⁴ in the formulae (I) to (IV) includes a divalent group formed by removing one hydrogen atom from the above-mentioned aryl group. Among these, a phenylene group, a naphthylene group, an anthrylene group, a phenanthrylene group, a pyrenylene group, and a fluorenylene group having two substituents at the 9-position are preferred; and a 1,4-phenylene group, a 1,3-phenlene group, a 1,2-phenylene group, a 1,4-naphthylene group, a 2,6-naphthylene group, a 9,9-dimethyl-2,7-fluorenylene group, and a 9,9-diphenyl-2,7-fluorenylene group are more preferred.

The heteroarylene group having 5 to 30 (preferably 5 to 24, more preferably 5 to 12) ring atoms represented by L¹ to L⁴ in the formulae (I) to (IV) includes a divalent group formed by removing one hydrogen atom from the above-mentioned heteroaryl group. Among these, a pyridinylene group is preferred; and a 2,5-pyridinylene group and a 2 pyridinylene group are more preferred.

The heteroaromatic compound having 5 to 30 (preferably 5 to 24, more preferably 5 to 12) ring atoms represented by Ar⁹ to Ar¹¹ in the formula (V) includes at least 1, preferably 1 to 5, more preferably 1 to 4, even more preferably 1 to 3 hetero atoms. Examples of the hetero atom include a nitrogen atom, a sulfur atom and an oxygen atom, and a nitrogen atom and an oxygen atom are preferred.

Examples of the heteroaromatic compound include pyrrole, furan, thiophene, pyridine, imidazopyridine, pyridazine, pyrimidine, pyrazine, triazine, imidazole, oxazole, thiazole, pyrazole, isoxazole, isothiazole, oxadiazole, thiadiazole, triazole, tetrazole, indole, isoindole, benzofuran, isobenzofuran, benzothiophene, isobenzothiophene, indole, quinolidine, quinoline, isoquinoline, cinnoline, phthalazine, quinazoline, quinoxaline, benzimidazole, benzoxazole, benzothiazole, indazole, benzisoxazole, benzisothiazole, dibenzofuran, dibenzothiophene, carbazole, 9-phenylcarbazole, phenanthridine, acridine, phenanthroline, phenazine, phenothiazine, phenoxazine, xanthene, etc. Among these, pyridine, imidazopyridine, pyridazine, pyrimidine, pyrazinine, triazine, benzimidazole, dibenzofuran, dibenzothiophene, carbazole, 9-phenylcarbazole, phenanthroline and quinazoline are preferred.

In the formula (I), preferably, R¹ to R⁸ are each independently a hydrogen atom.

In the formula (I), preferably, L¹ is a substituted or unsubstituted arylene group having 6 to 30 (more preferably 6 to 18, even more preferably 6 to 10) ring carbon atoms, and is more preferably an unsubstituted arylene group having 6 to 30 (more preferably 6 to 18, even more preferably 6 to 10) ring carbon atoms.

In the formula (I), preferably, Ar⁵ is a substituted or unsubstituted arylene group having 6 to 30 (more preferably 6 to 18, even more preferably 6 to 12) ring carbon atoms, and is more preferably an unsubstituted arylene group having 6 to 30 (more preferably 6 to 18, even more preferably 6 to 12) ring carbon atoms.

In the formula (I), preferably, R¹¹ to R¹⁵ in the formula (a) each are independently a hydrogen atom, or a substituted or unsubstituted alkyl group having 1 to 20 carbon atoms (more preferably a substituted or unsubstituted alkyl group having 1 to 6 carbon atoms, even more preferably a substituted or unsubstituted alkyl group having 1 to 3 carbon atoms, and especially preferably a substituted or unsubstituted alkyl group having 1 to 2 carbon atoms).

In the formula (I), preferably, R¹¹ in the formula (a) is an unsubstituted alkyl group having 1 to 6 carbon atoms (more preferably an unsubstituted alkyl group having 1 to 3 carbon atoms, even more preferably an unsubstituted alkyl group having 1 to 2 carbon atoms). More preferably, R¹¹ in the formula (a) is an unsubstituted alkyl group having 1 to 6 carbon atoms (more preferably an unsubstituted alkyl group having 1 to 3 carbon atoms, even more preferably an unsubstituted alkyl group having 1 to 2 carbon atoms), and R¹² to R¹⁵ each are independently a hydrogen atom.

In the formula (I), preferably, Ar⁵ is an unsubstituted aryl group having 6 to 18 ring carbon atoms, L¹ is an unsubstituted arylene group having 6 to 18 ring carbon atoms, R¹ to R⁸ each are independently a hydrogen atom, R¹¹ in the formula (a) is an unsubstituted alkyl group having 1 to 6 carbon atoms, and R¹² to R¹⁵ each are independently a hydrogen atom.

In the formula (I), more preferably, Ar⁵ is an unsubstituted aryl group having 6 to 12 ring carbon atoms, L¹ is an unsubstituted phenylene group, R¹ to R⁸ each are independently a hydrogen atom, R¹¹ in the formula (a) is an unsubstituted alkyl group having 1 to 2 carbon atoms, and R¹² to R¹⁵ each are independently a hydrogen atom.

In the formula (V), preferably, at least one of Ar⁹ to Ar¹¹ is a group selected from the following formulae (m) and (n), and Ar⁹ is a group selected from the following formulae (m) and (n).

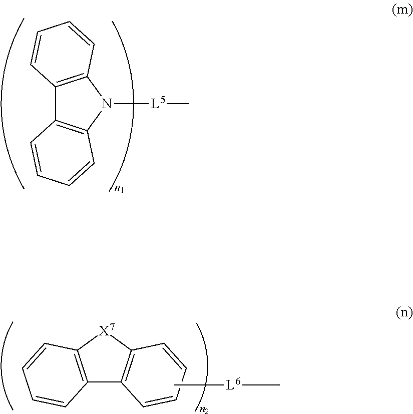

In the formulae, X⁷ represents S or O; L⁵ represents a single bond, a residue having a valence of (n₁+1) derived from a substituted or unsubstituted arylene group having 6 to 30 ring carbon atoms, or a residue having a valence of (n₁+1) derived from a substituted or unsubstituted heteroarylene group having 5 to 30 ring atoms; L⁶ represents a single bond, a residue having a valence of (n₂+1) derived from a substituted or unsubstituted arylene group having 6 to 30 ring carbon atoms, or a residue having a valence of (n₂+1) derived from a substituted or unsubstituted heteroarylene group having 5 to 30 ring atoms; and

n₁ represents an integer of 1 to 3, and n₂ represents an integer of 1 to 3.

The residue having a valence of (n₁+1) or (n₂+1) derived from an arylene group having 6 to 30 ring carbon atoms represented by L⁵ and L⁶ includes specific examples of the residue having a valence of (n₁+1) or (n₂+1) derived from the arylene group represented by L¹ to L⁴ in the formulae (I) to (IV); and a preferred carbon number and specific examples thereof are also the same.

The residue having a valence of (n₁+1) or (n₂+1) derived from a heteroarylene group having 5 to 30 ring atoms represented by L⁵ and L⁶ includes specific examples of the residue having a valence of (n₁+1) or (n₂+1) derived from the heteroarylene group represented by L¹ to L⁴ in the formulae (I) to (IV); and a preferred carbon number and specific examples thereof are also the same.

This is described with reference to specific examples. For example, when n₁ is 1, the residue having a valence of (n₁+1) derived from a phenylene group (arylene group) is a phenylene group (arylene group). When n₁ is 2, the residue having a valence of (n₁+1) derived from a phenylene group (arylene group) is a trivalent benzene ring.

Preferably, L⁵ and L⁶ each are a residue having a valence of (n₁+1) derived from an arylene group having 6 to 12 ring carbon atoms.

In the formula (V), preferably, Ar⁹ is a group selected from the above-mentioned formulae (m) and (n), X¹ is CR⁰, and X² and X³ each are N.

Also preferably, Ar¹⁰ and Ar¹¹ each are independently a hydrogen atom, or a monovalent residue containing at least one selected from aromatic hydrocarbon compounds represented by the following formulae (d) to (l), substituted or unsubstituted heteroaromatic compounds each having 5 to 12 ring atoms, and groups formed by bonding a plurality of these compounds to each other, more preferably, a monovalent residue containing at least one selected from aromatic hydrocarbon compounds represented by the following formulae (d) to (l), substituted or unsubstituted heteroaromatic compounds each having 5 to 6 ring atoms, and groups formed by bonding a plurality of these compounds to each other.

In the formula (V), also preferably, Ar⁹ is a group selected from the formulae (m) and (n), Ar¹⁰ and Ar¹¹ each are independently a hydrogen atom, or a monovalent residue containing at least one selected from aromatic hydrocarbon compounds represented by the following formulae (d) to (l) (in the formulae, R represents a hydrogen atom or an unsubstituted alkyl group having 1 to 6 carbon atoms), substituted or unsubstituted heteroaromatic compounds each having 5 to 12 ring atoms, and groups formed by bonding a plurality of these compounds to each other, X¹ is CR⁰, and X² and X³ each are N.

Preferably, the compound (2) is a compound selected from compounds represented by the above-mentioned formula (V).

More preferably, the compounds (1) and (1′) each are a compound selected from compounds represented by the formula (I), and the compound (2) is a compound selected from compounds represented by the formula (V).

Preferably, the formula (V) is represented by the following formula (V-1) or the following formula (V-2).

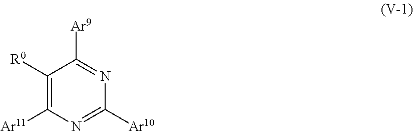

In the formula, Ar⁹ to Ar¹¹, and R⁰ are the same as above.

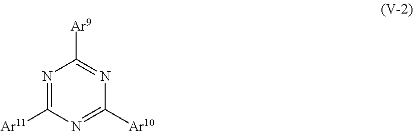

In the formula, Ar⁹ to Ar¹¹ are the same as above.

Specific examples of the compounds represented by the formulae (I) to (V) are shown below, but the compounds are not limited to these. In the following formulae, the broken line means a chemical bond.

### Exemplification of Compounds of Formula (I)

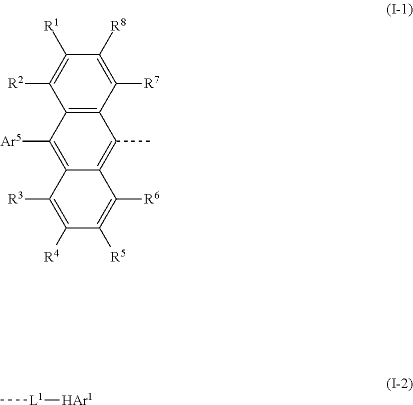

In the formula (I), examples of the structure represented by the above (I-1) include the following:

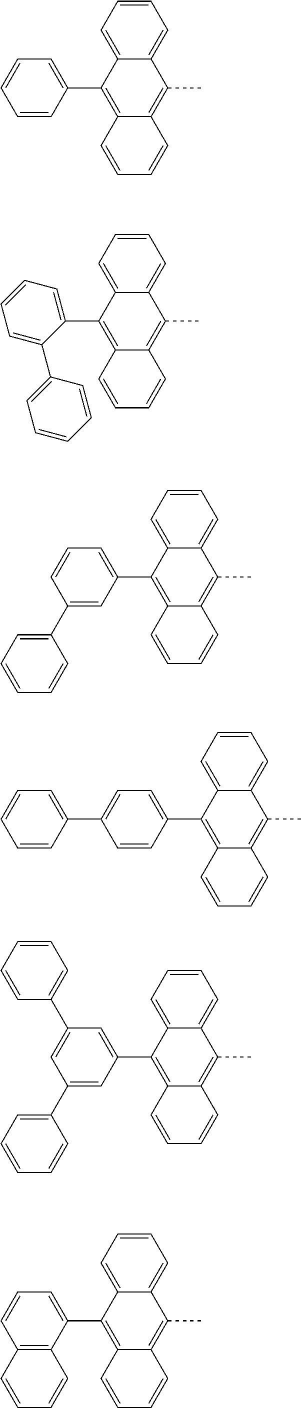

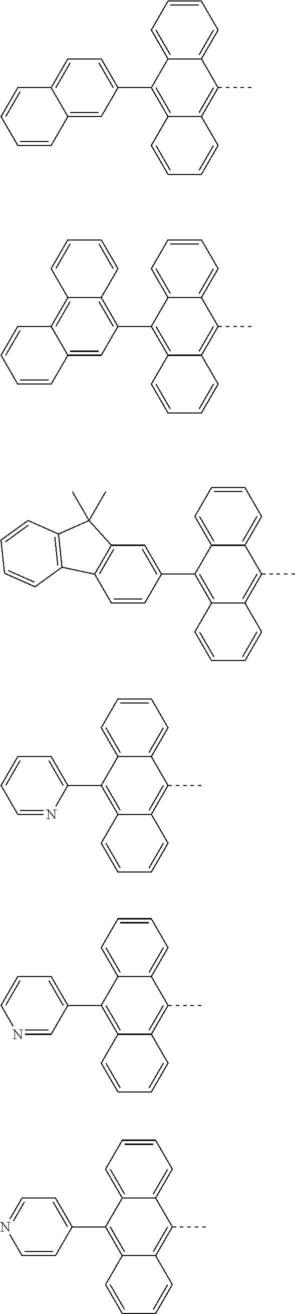

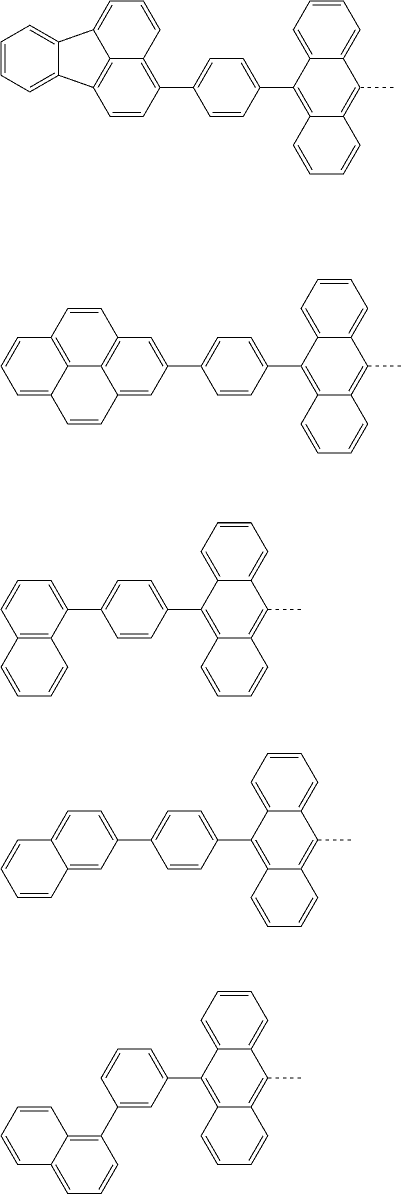

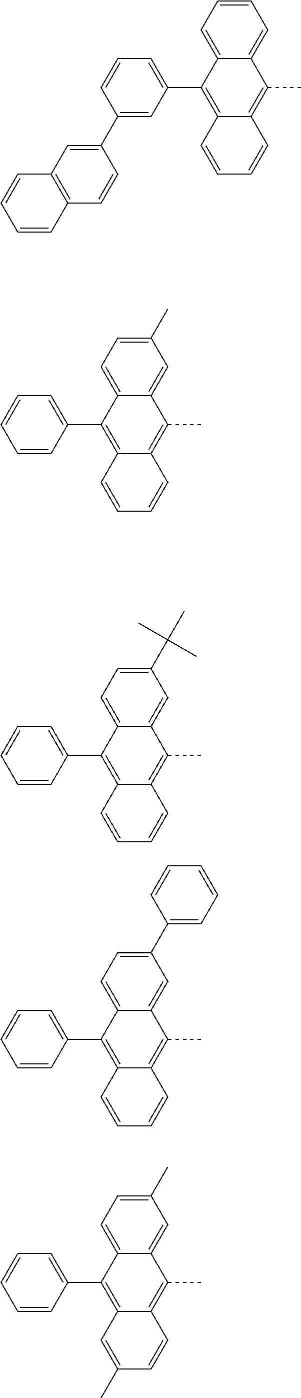

In the formula (I), examples of the structure represented by the above (I-2) include the following:

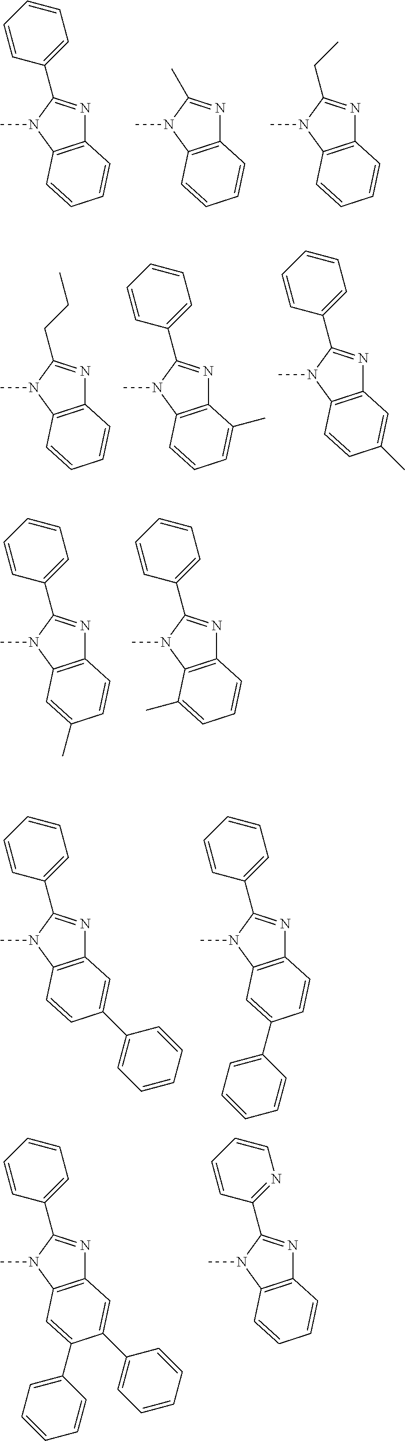

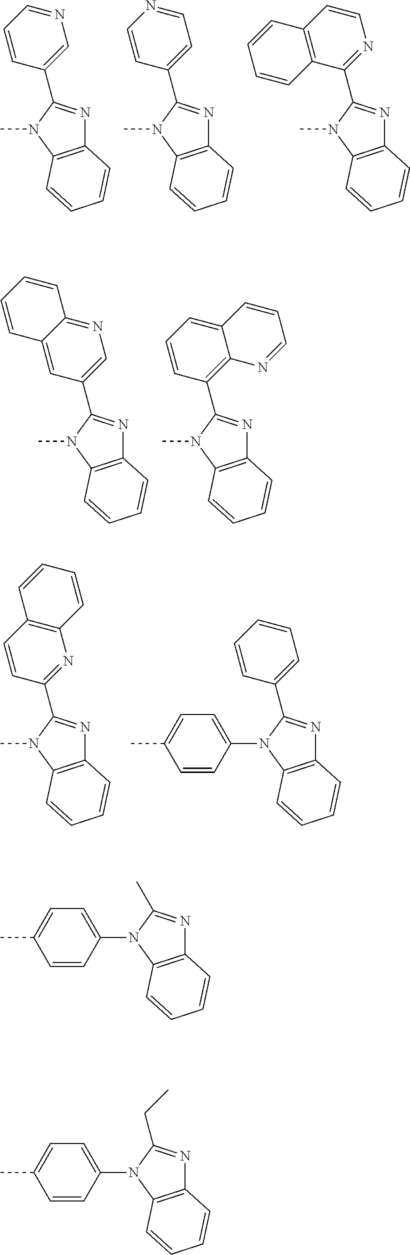

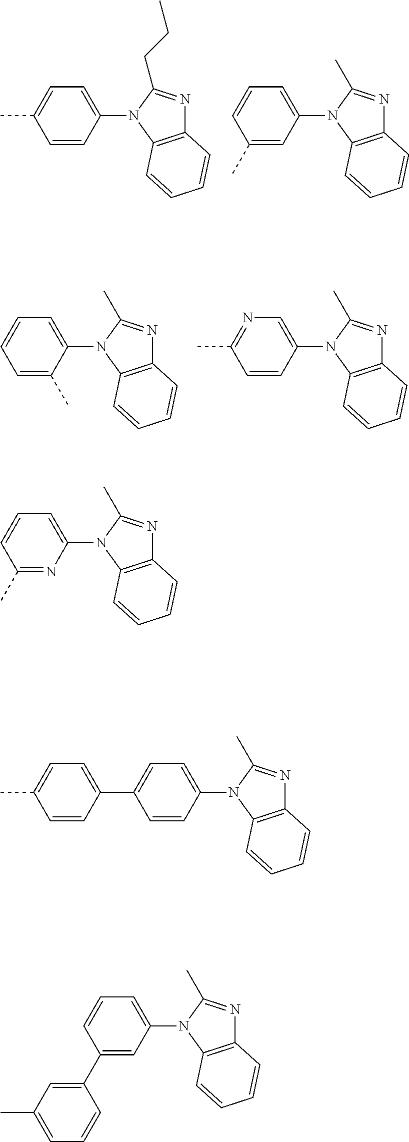

### Exemplification of Compounds of Formula (II)

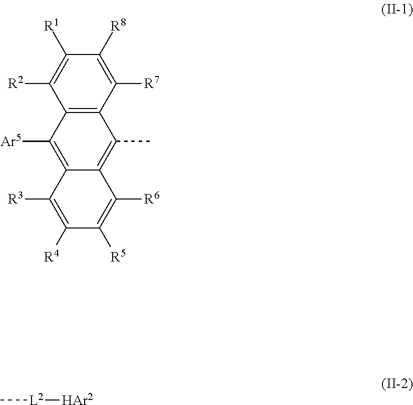

In the formula (II), examples of the structure represented by the above (II-1) are the same as those of the above (I-1).

In the formula (II), examples of the structure represented by the above (II-2) include the following:

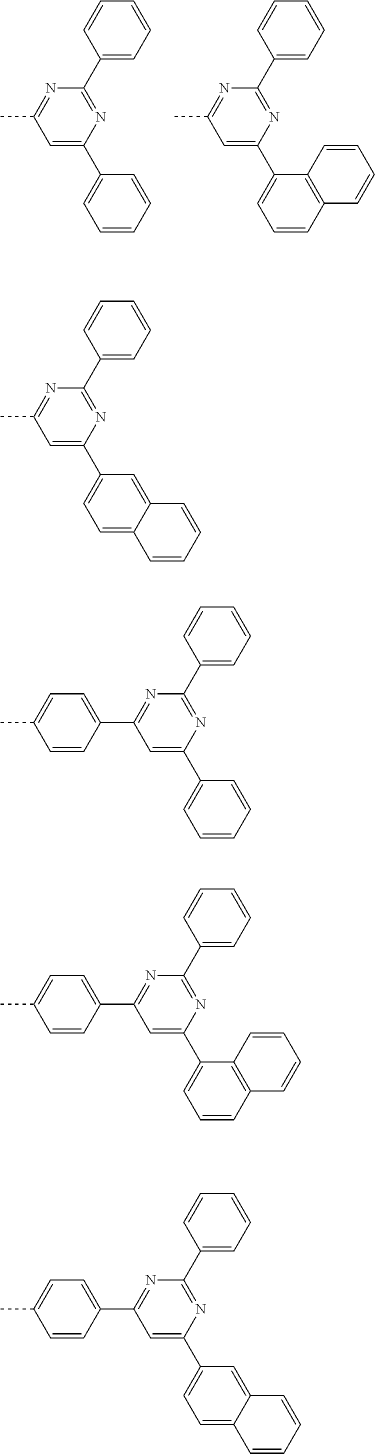

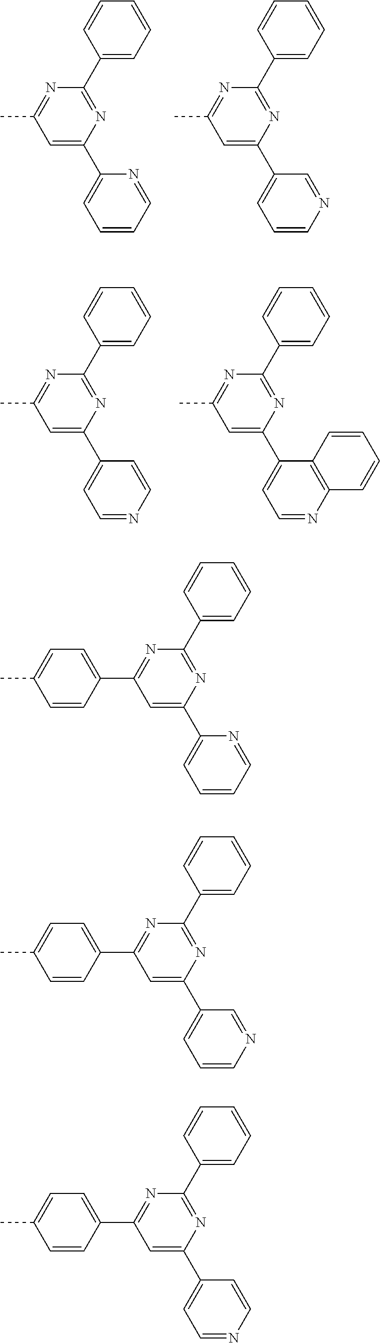

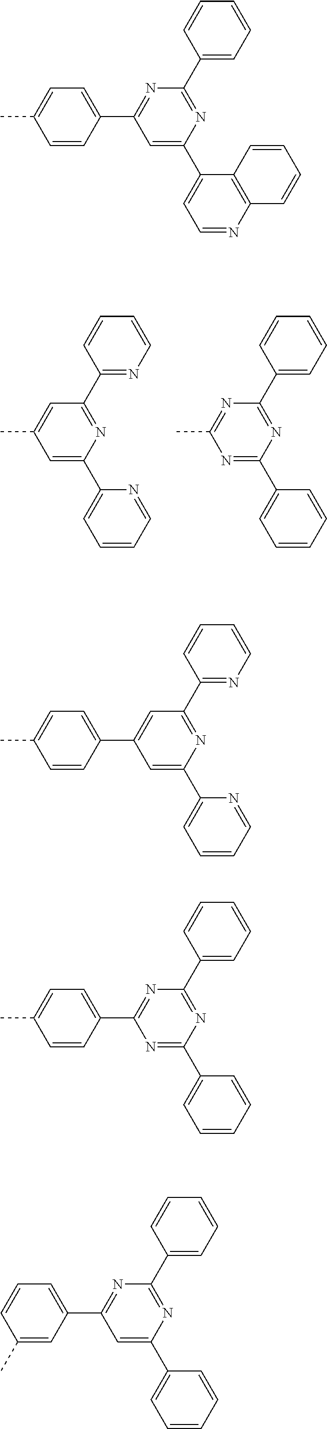

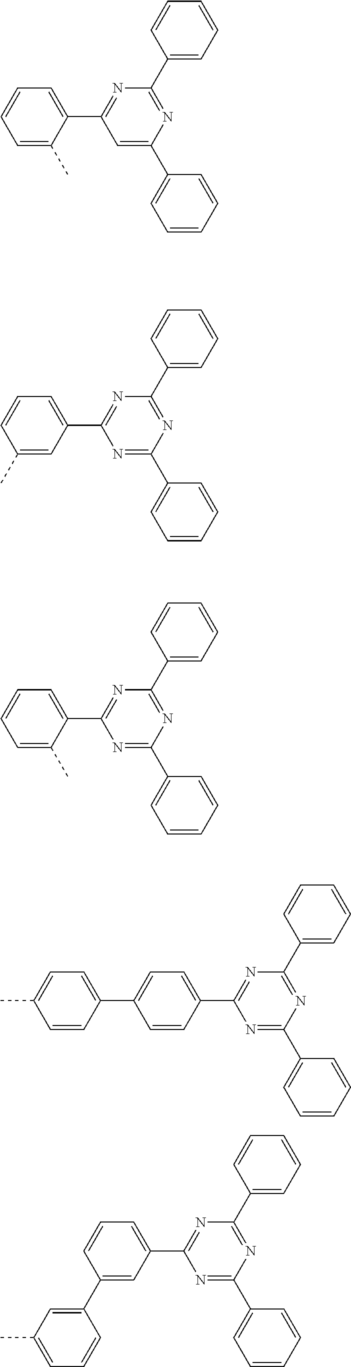

### Exemplification of Compounds of Formula (III)

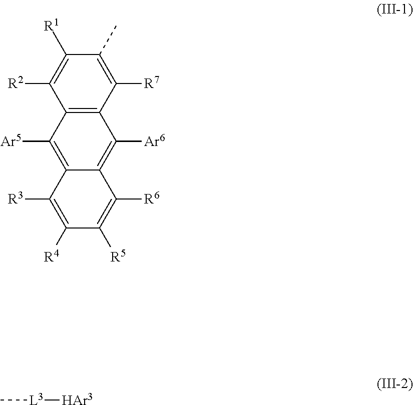

In the formula (III), examples of the structure represented by the above (111-1) include the following:

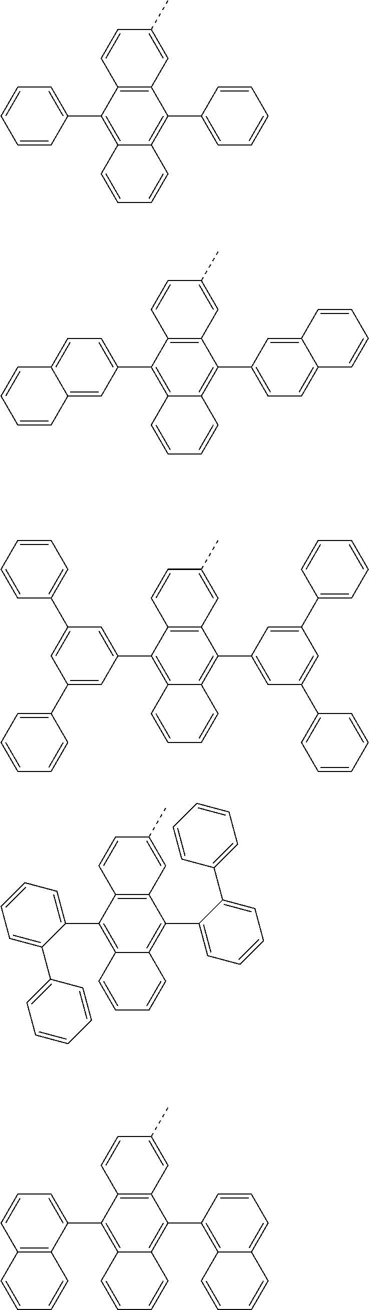

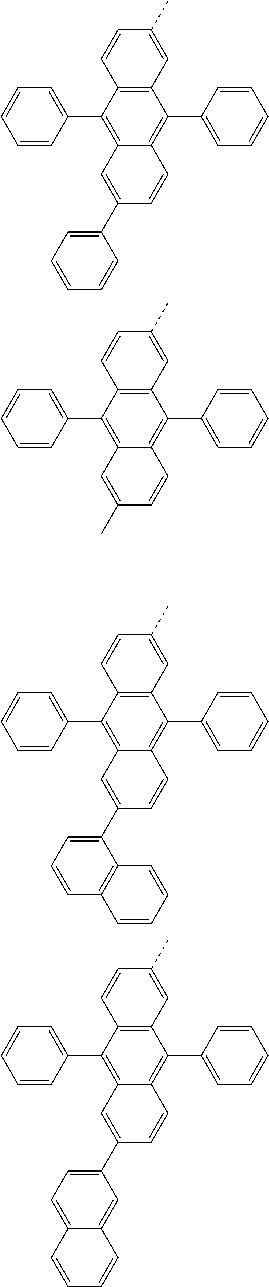

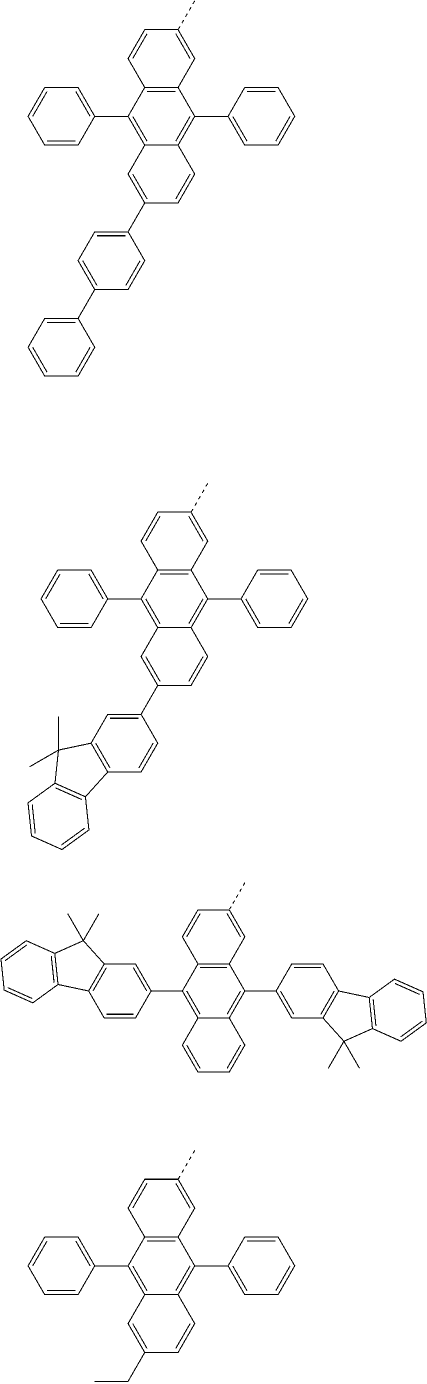

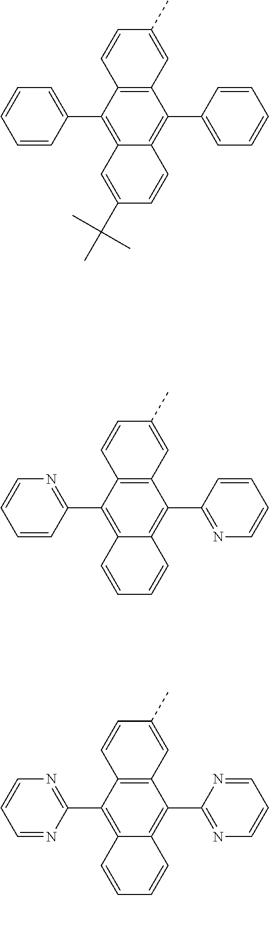

In the formula (III), examples of the structure represented by the above (III-2) are the same as those of the above (II-2).

### Exemplification of Compounds of Formula (IV)

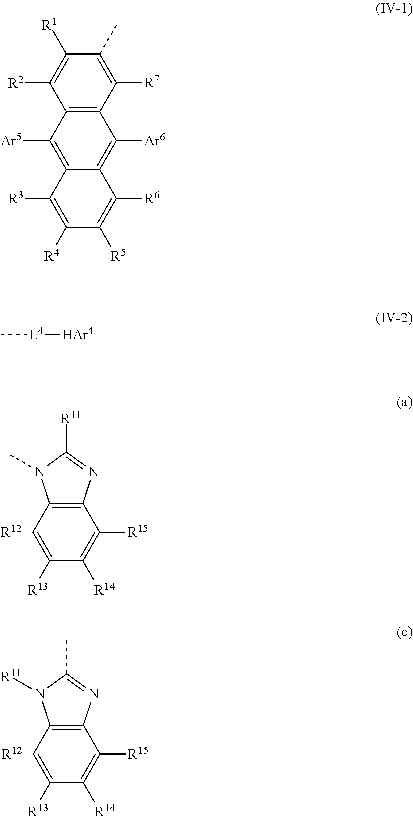

In the formula (IV), examples of the structure represented by the above (IV-1) are the same as those of the above (III-1).

Regarding the above (IV-2) of the formula (IV) where HAr⁴ is represented by the formula (a), examples of the structure represented by the above (IV-2) are the same as those of the above (I-2).

Regarding the above (IV-2) of the formula (IV) where HAr⁴ is represented by the formula (c), examples of the structure represented by the above (IV-2) include the following:

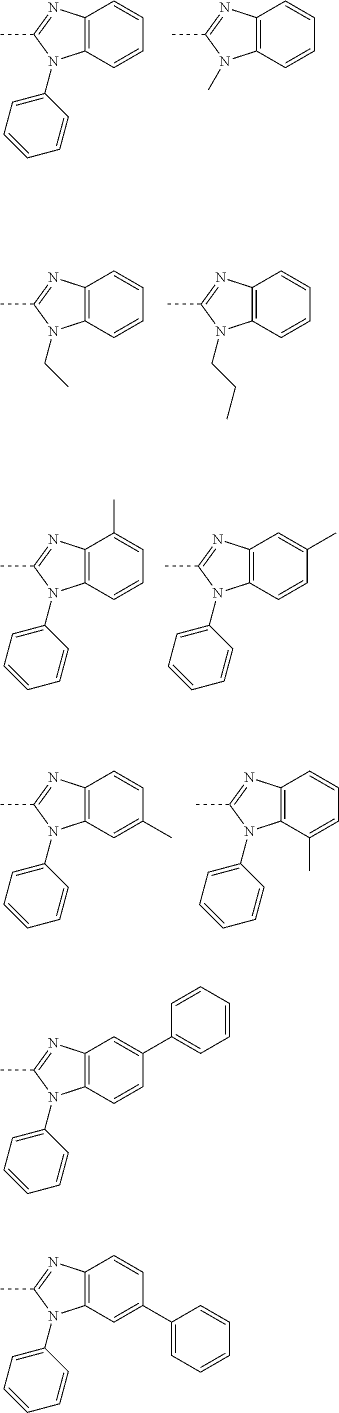

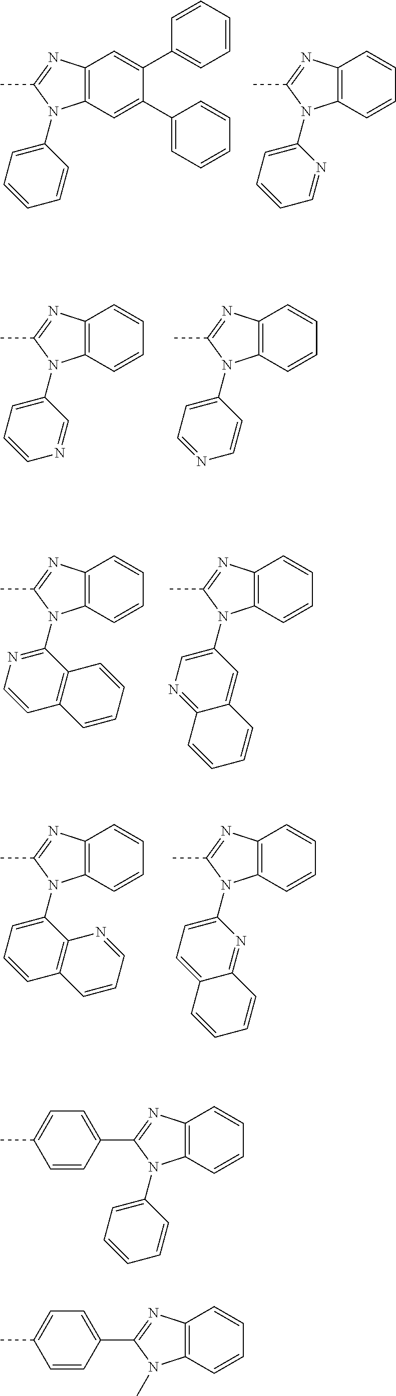

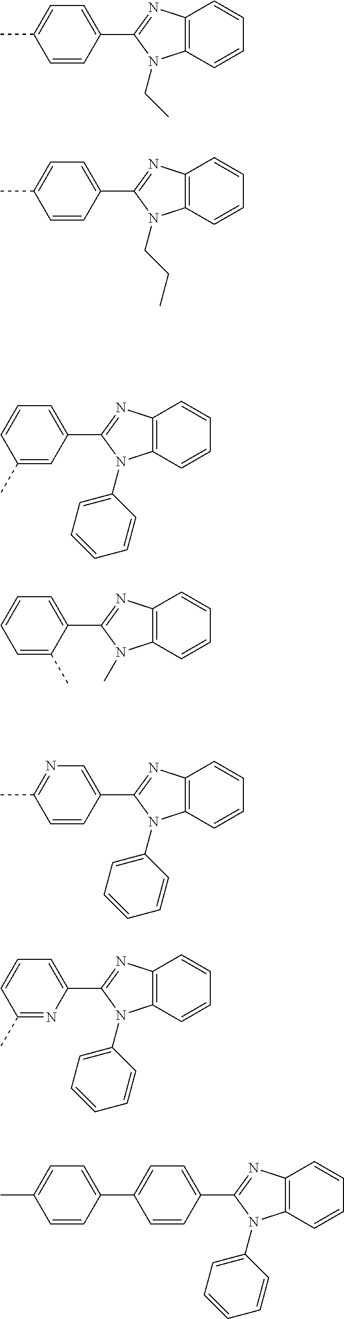

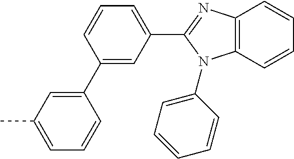

### Exemplification of Compounds of Formula (V)

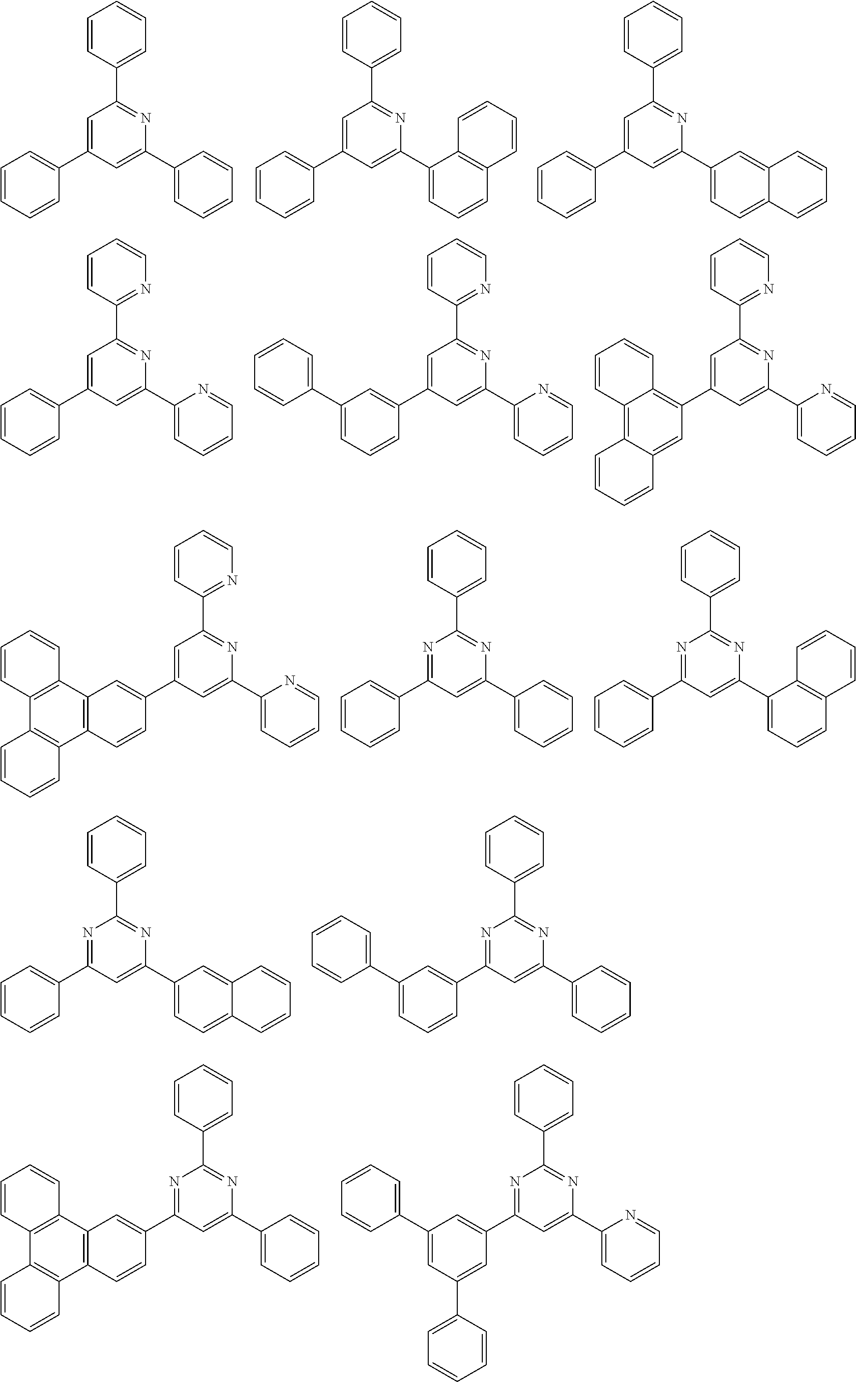

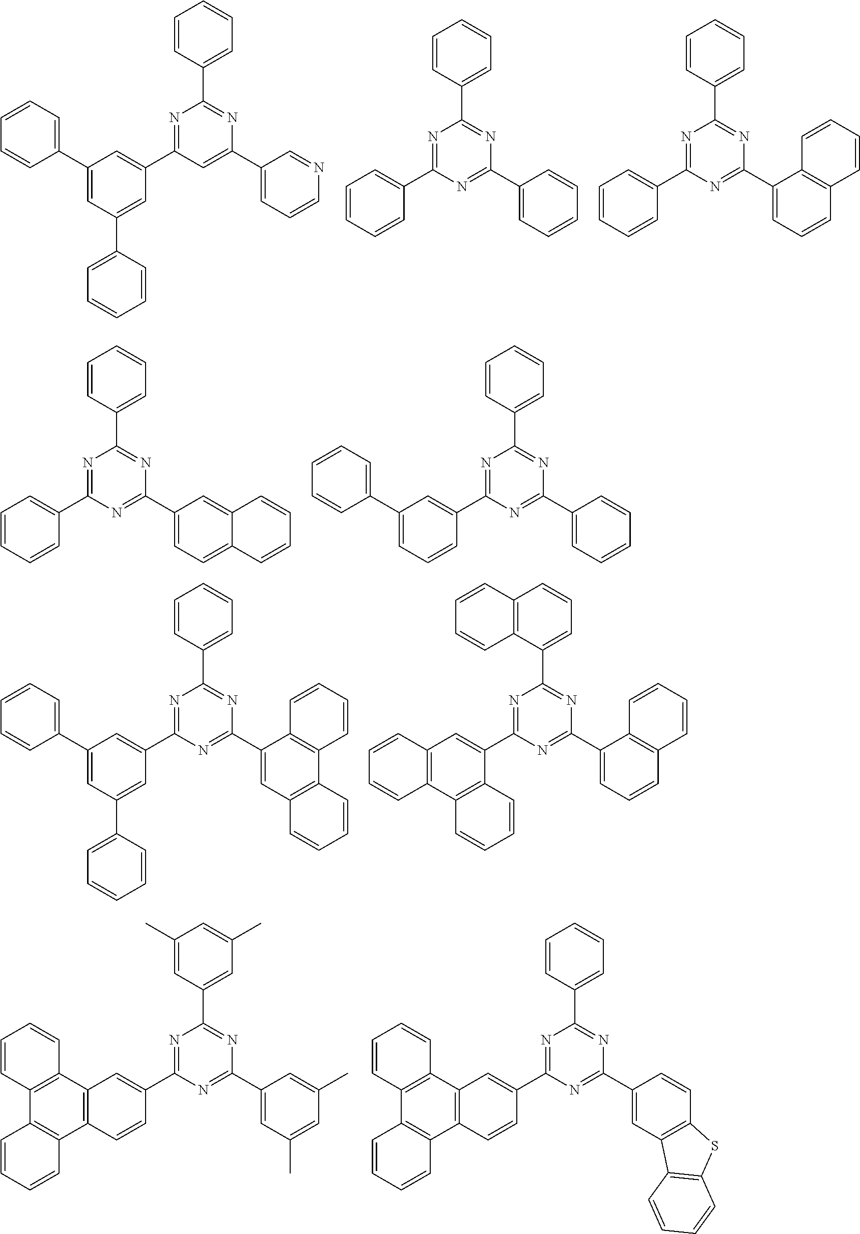

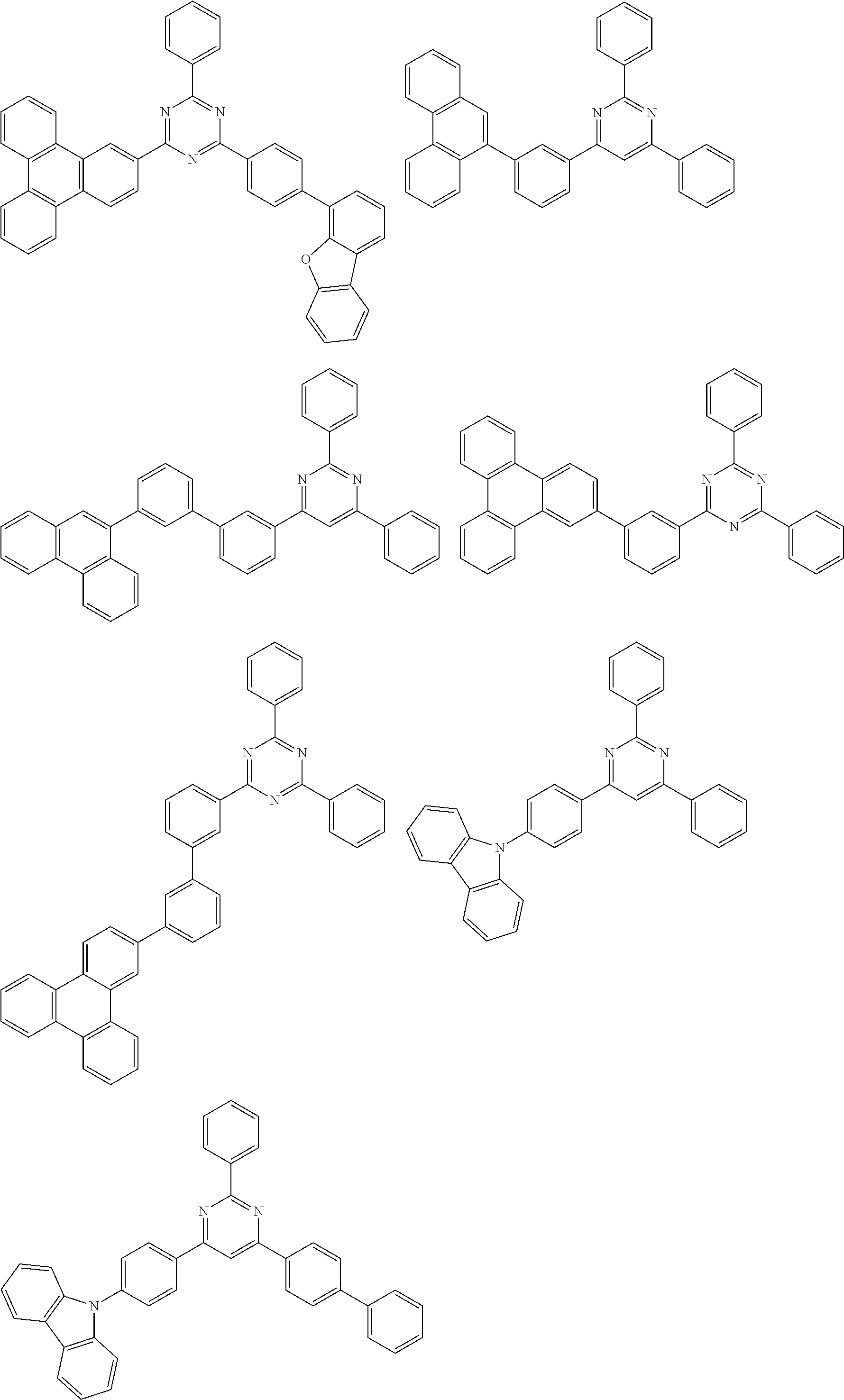

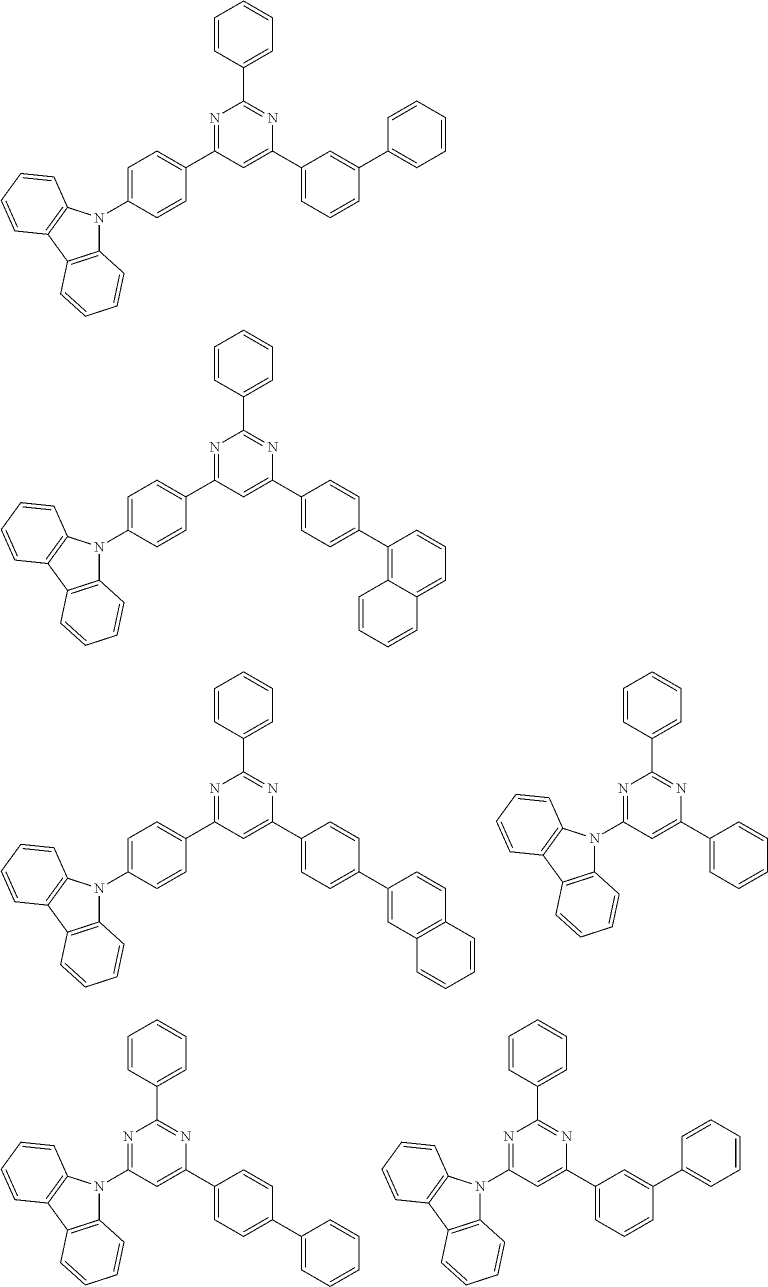 [SMILES: c1ccc(-c2cccc(-c3cc(-c4ccc(-n5c6ccccc6c6ccccc65)cc4)nc(-c4ccccc4)n3)c2)cc1 ; c1ccc(-c2nc(-c3ccc(-c4cccc5ccccc45)cc3)cc(-c3ccc(-n4c5ccccc5c5ccccc54)cc3)n2)cc1 ; c1ccc(-c2nc(-c3ccc(-c4ccc5ccccc5c4)cc3)cc(-c3ccc(-n4c5ccccc5c5ccccc54)cc3)n2)cc1 ; c1ccc(-c2cc(-n3c4ccccc4c4ccccc43)nc(-c3ccccc3)n2)cc1 ; c1ccc(-c2ccc(-c3cc(-n4c5ccccc5c5ccccc54)nc(-c4ccccc4)n3)cc2)cc1 ; c1ccc(-c2cccc(-c3cc(-n4c5ccccc5c5ccccc54)nc(-c4ccccc4)n3)c2)cc1]

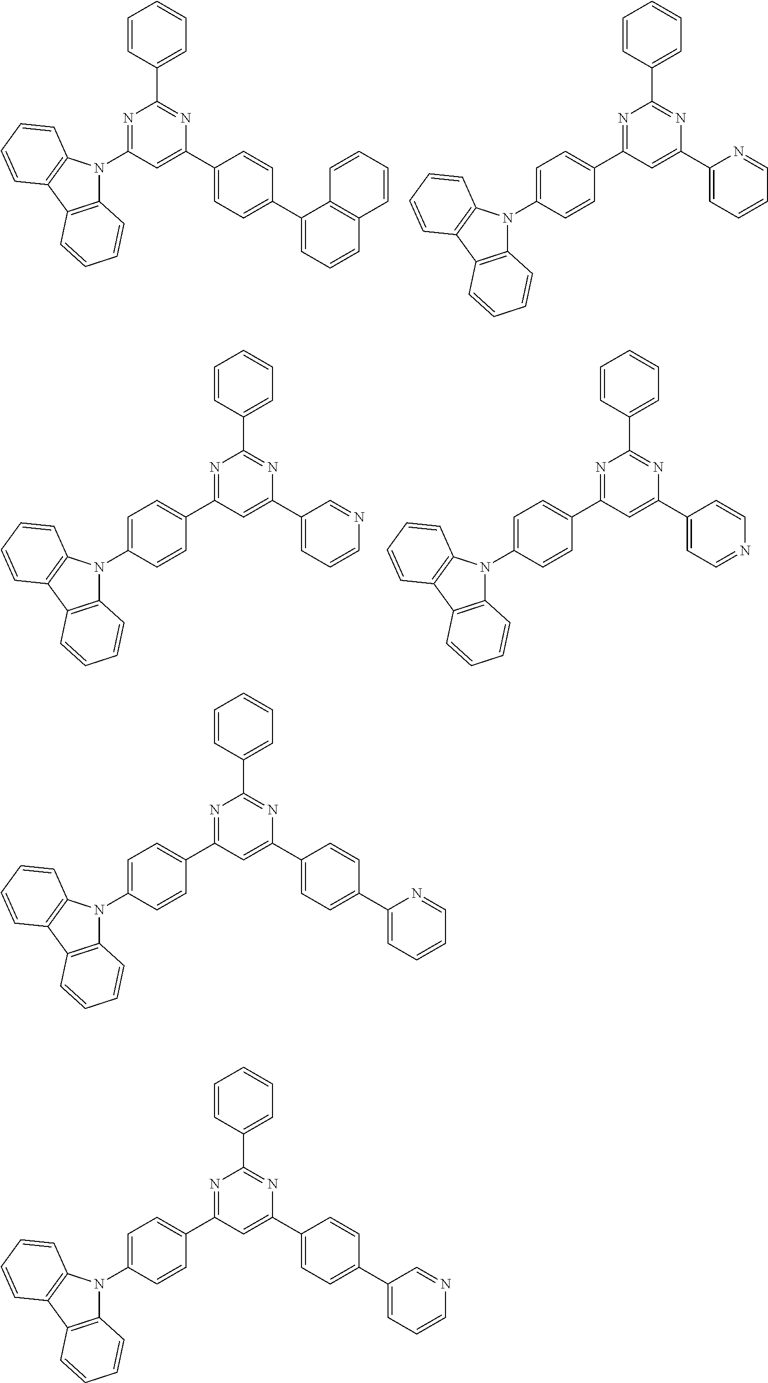

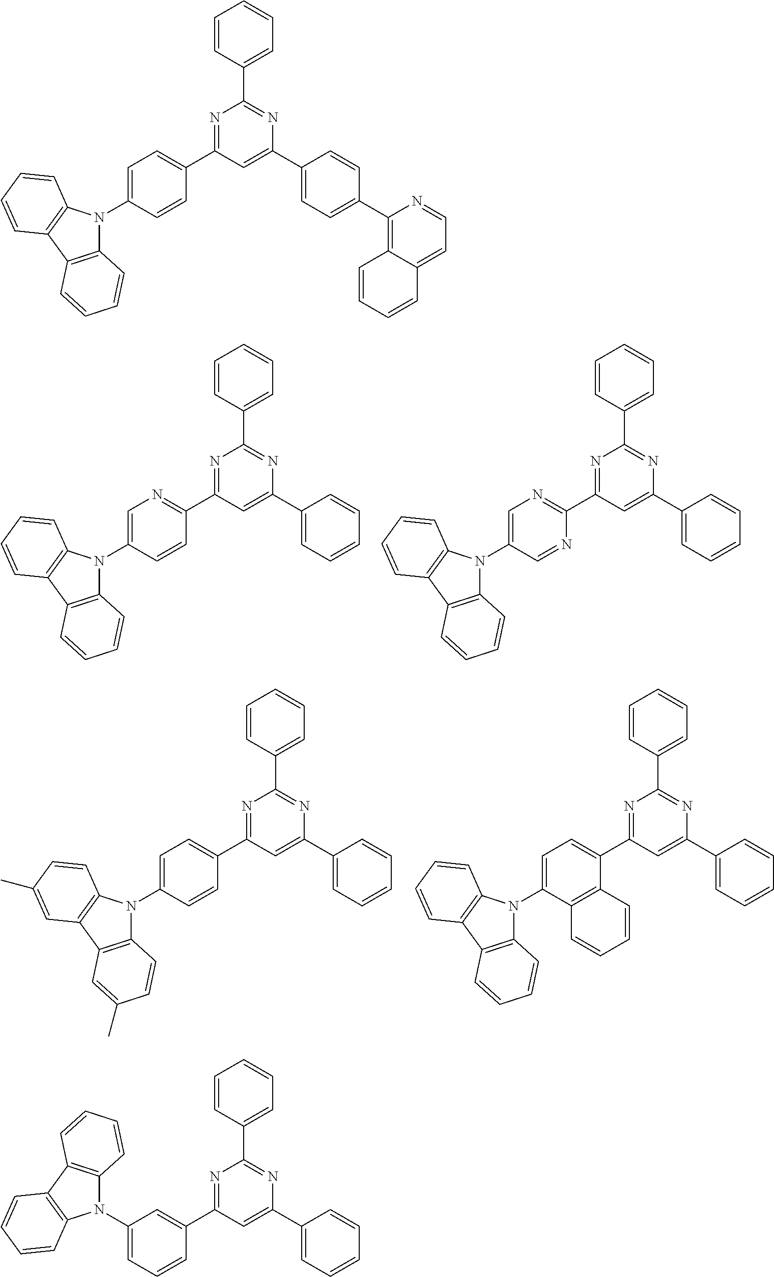

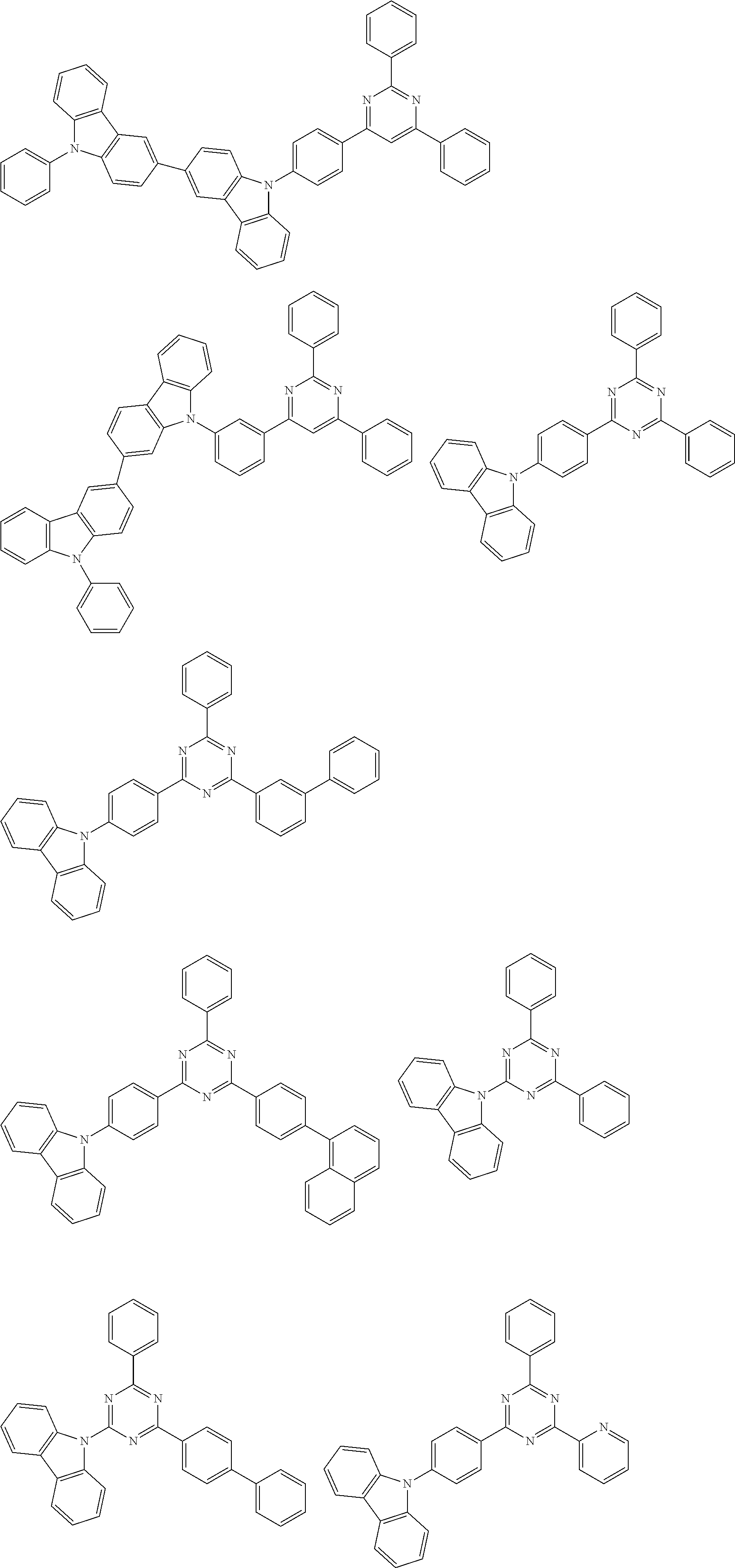

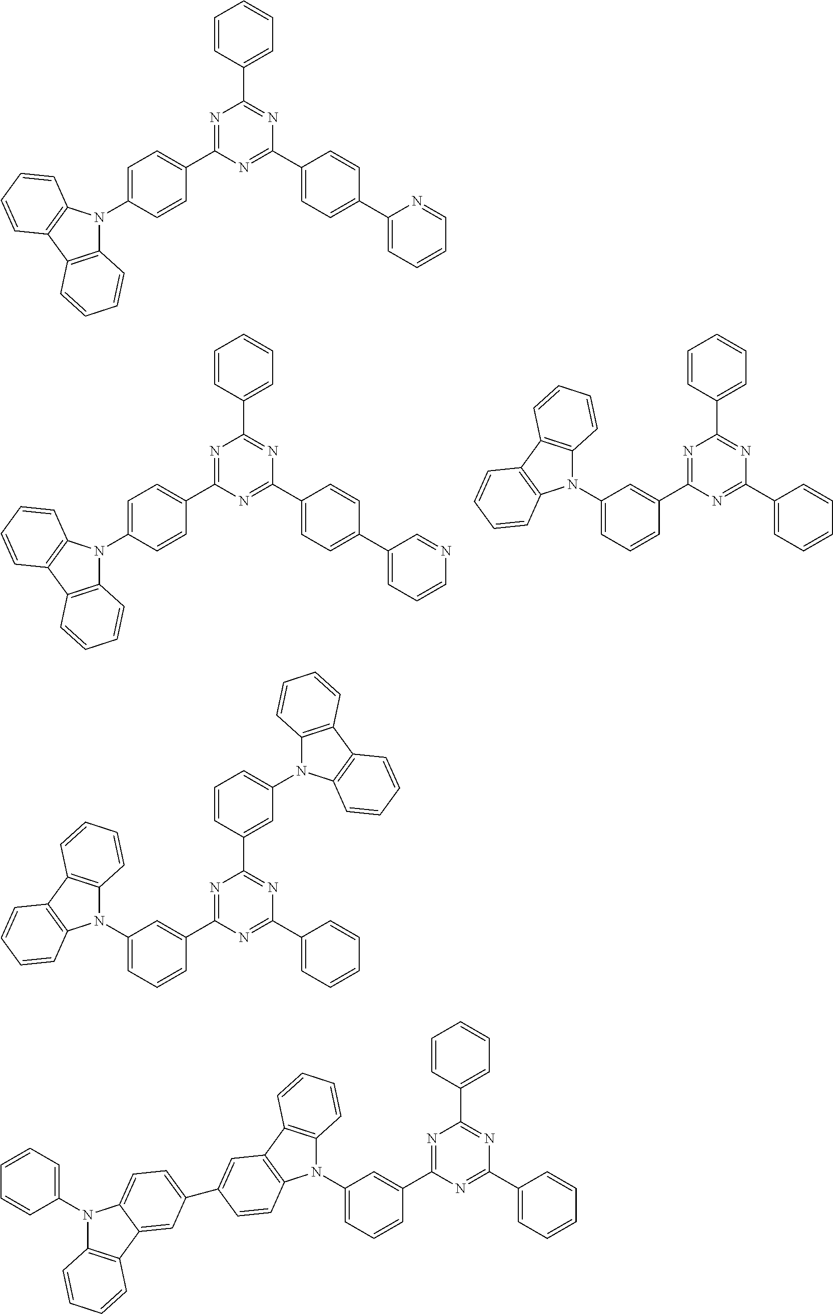 [SMILES: c1ccc(-c2nc(-c3ccc(-c4ccccn4)cc3)nc(-c3ccc(-n4c5ccccc5c5ccccc54)cc3)n2)cc1 ; c1ccc(-c2nc(-c3ccc(-c4cccnc4)cc3)nc(-c3ccc(-n4c5ccccc5c5ccccc54)cc3)n2)cc1 ; c1ccc(-c2nc(-c3ccccc3)nc(-c3cccc(-n4c5ccccc5c5ccccc54)c3)n2)cc1 ; c1ccc(-c2nc(-c3cccc(-n4c5ccccc5c5ccccc54)c3)nc(-c3cccc(-n4c5ccccc5c5ccccc54)c3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

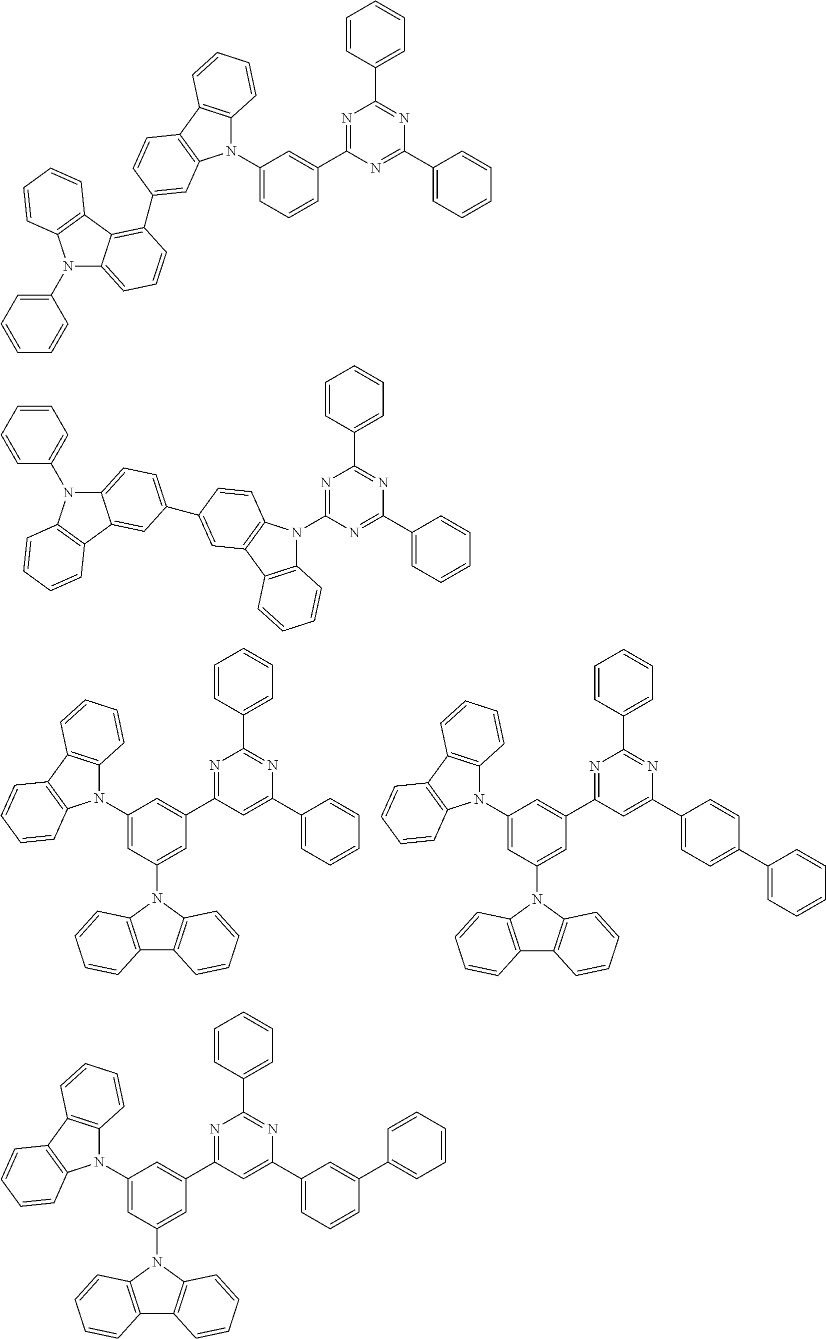

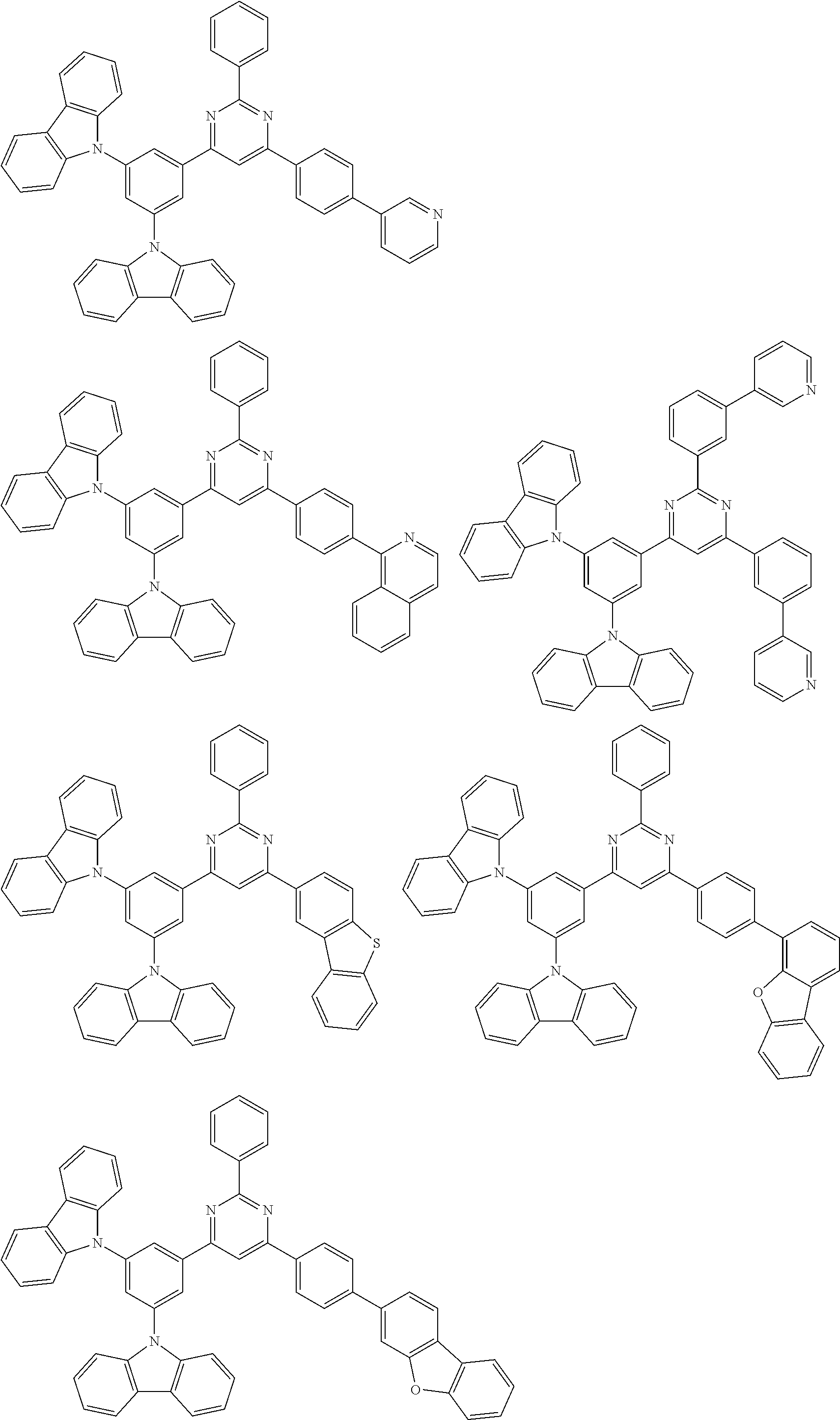

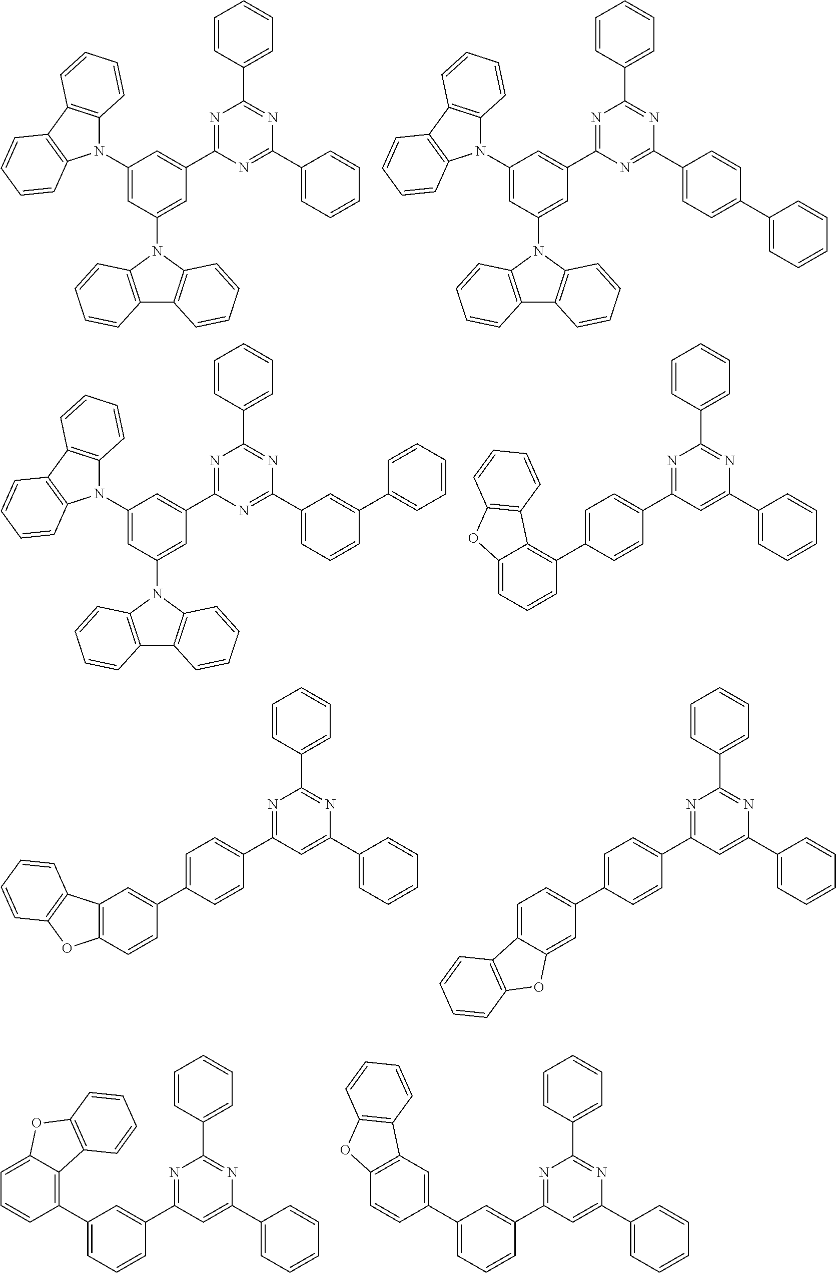

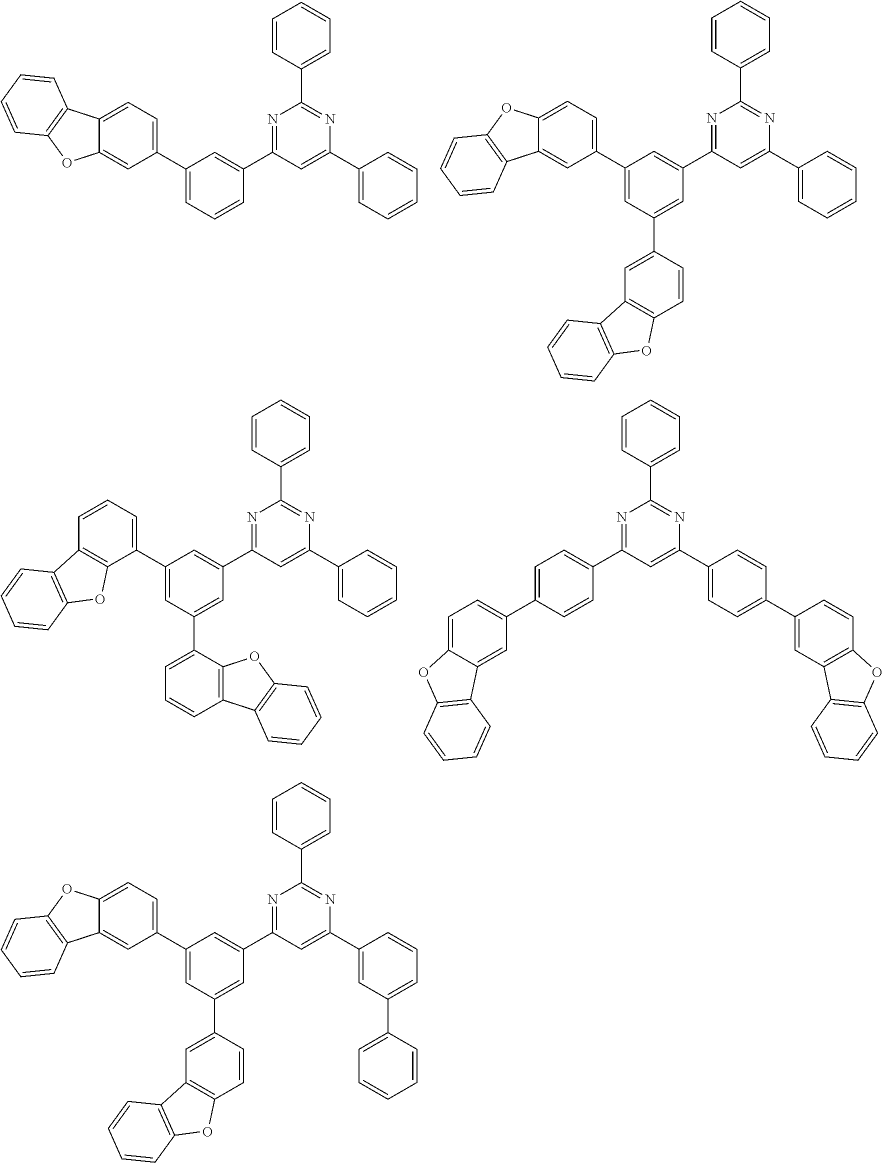

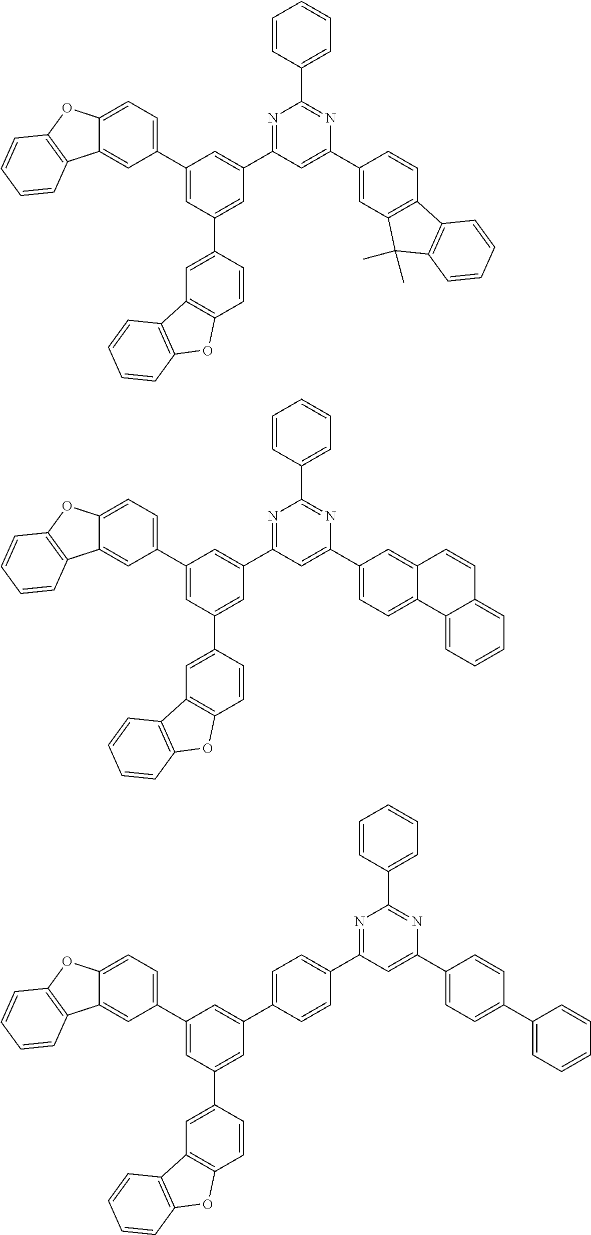 [SMILES: CC1(C)c2ccccc2-c2ccc(-c3cc(-c4cc(-c5ccc6oc7ccccc7c6c5)cc(-c5ccc6oc7ccccc7c6c5)c4)nc(-c4ccccc4)n3)cc21 ; c1ccc(-c2nc(-c3cc(-c4ccc5oc6ccccc6c5c4)cc(-c4ccc5oc6ccccc6c5c4)c3)cc(-c3ccc4c(ccc5ccccc54)c3)n2)cc1 ; c1ccc(-c2ccc(-c3cc(-c4ccc(-c5cc(-c6ccc7oc8ccccc8c7c6)cc(-c6ccc7oc8ccccc8c7c6)c5)cc4)nc(-c4ccccc4)n3)cc2)cc1]

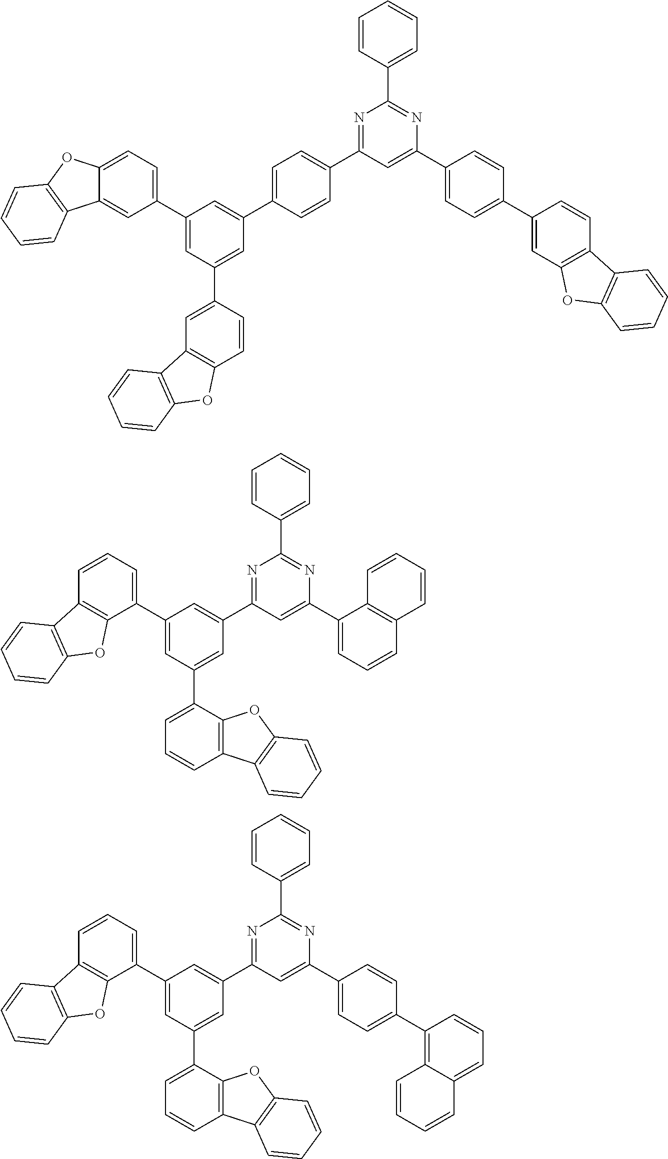

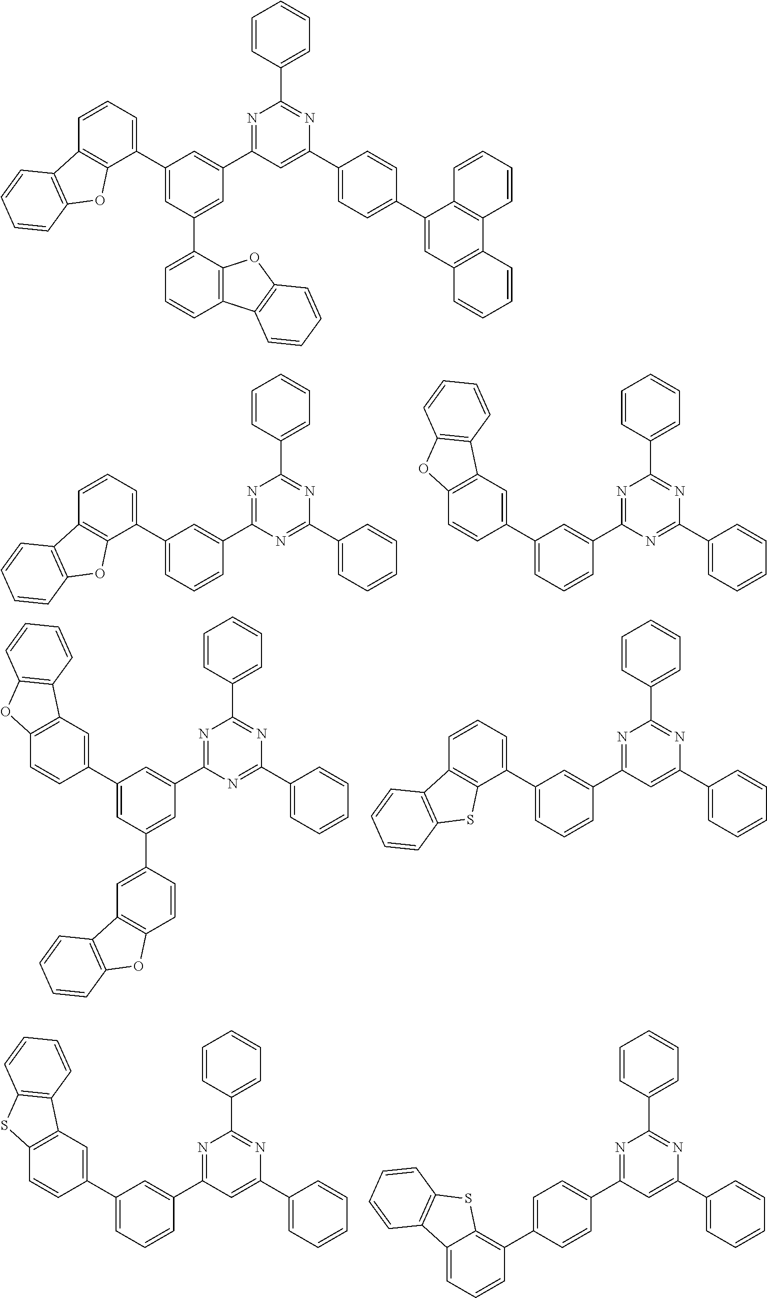

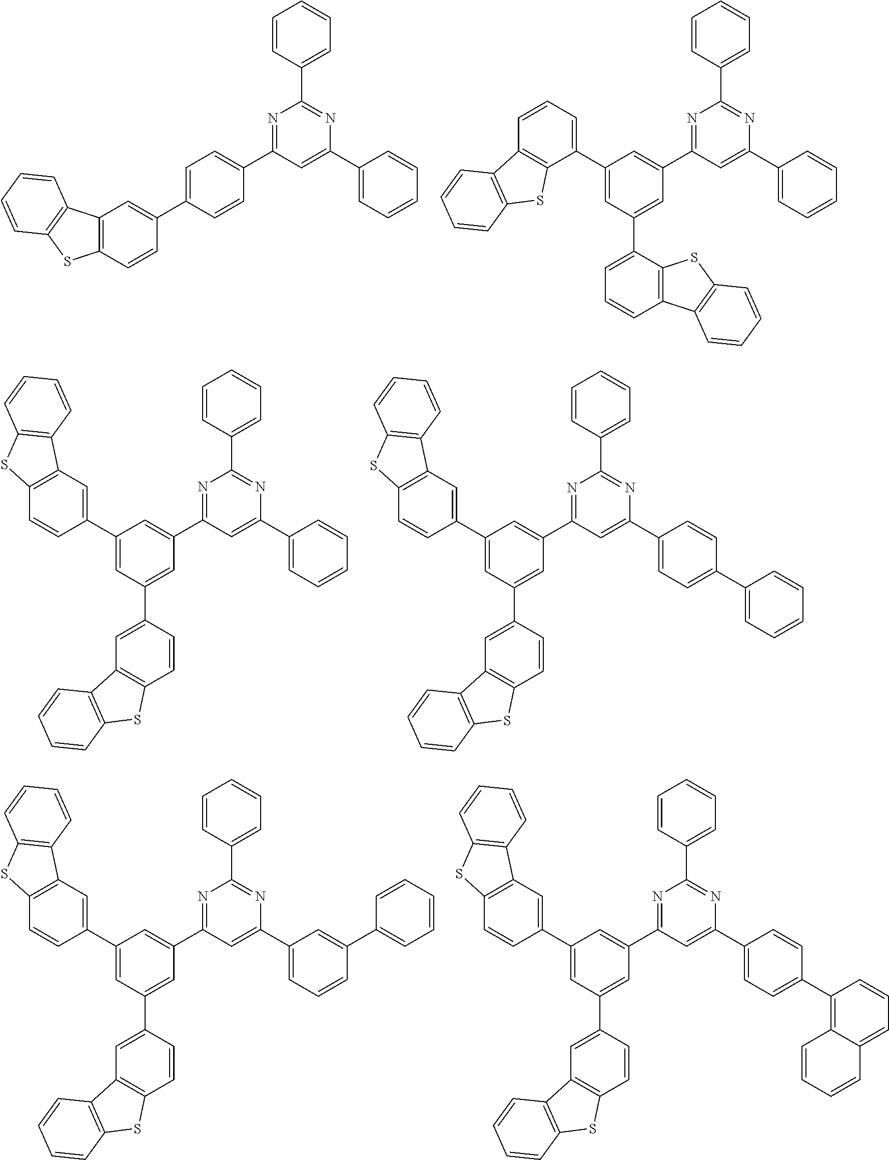

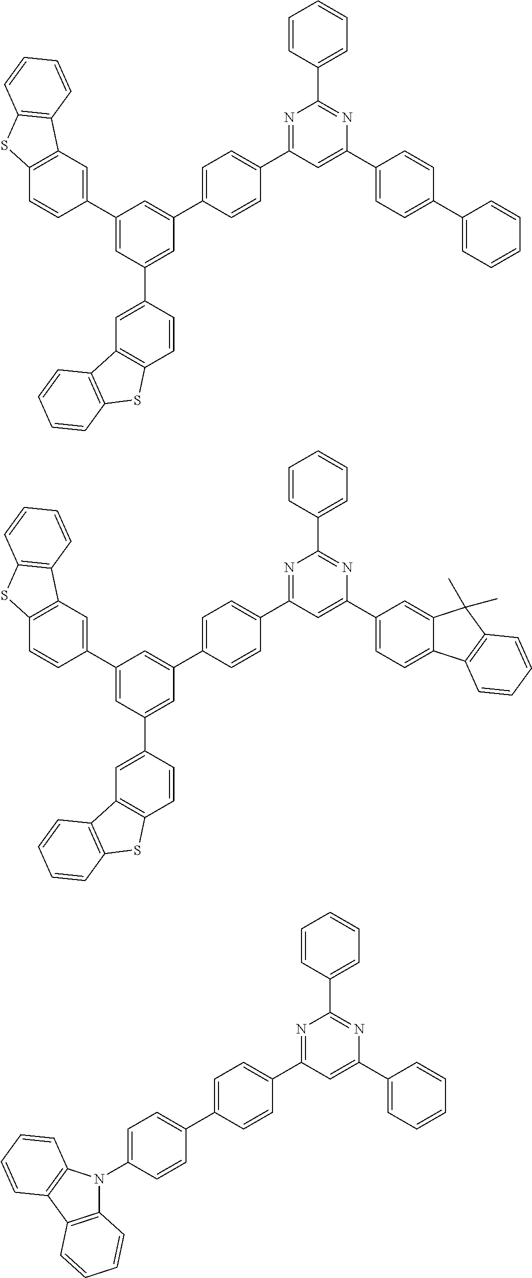 [SMILES: c1ccc(-c2ccc(-c3cc(-c4ccc(-c5cc(-c6ccc7sc8ccccc8c7c6)cc(-c6ccc7sc8ccccc8c7c6)c5)cc4)nc(-c4ccccc4)n3)cc2)cc1 ; CC1(C)c2ccccc2-c2ccc(-c3cc(-c4ccc(-c5cc(-c6ccc7sc8ccccc8c7c6)cc(-c6ccc7sc8ccccc8c7c6)c5)cc4)nc(-c4ccccc4)n3)cc21 ; c1ccc(-c2cc(-c3ccc(-c4ccc(-n5c6ccccc6c6ccccc65)cc4)cc3)nc(-c3ccccc3)n2)cc1]

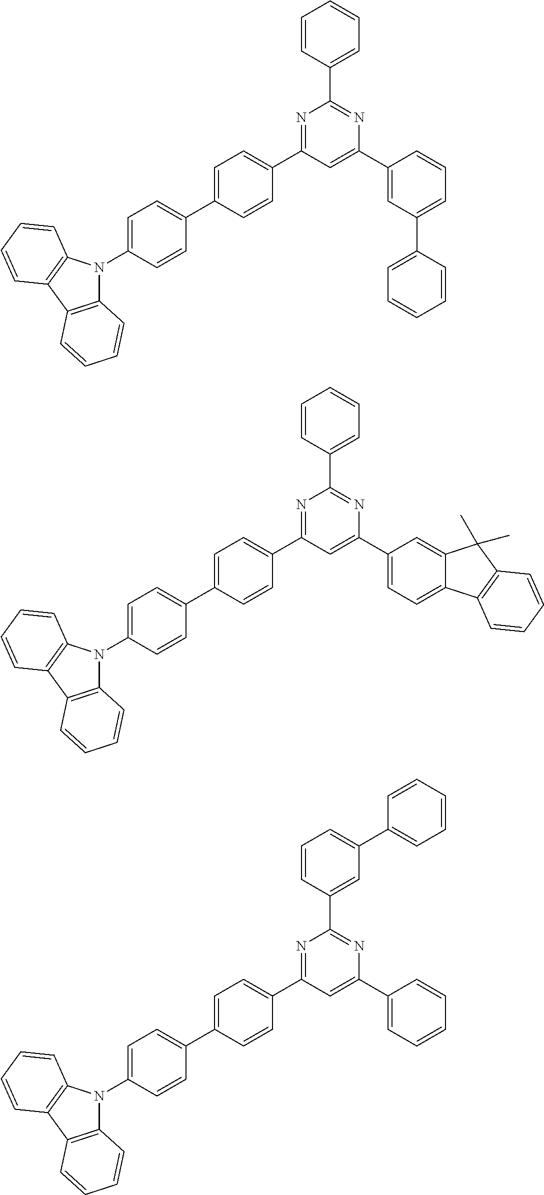 [SMILES: c1ccc(-c2cccc(-c3cc(-c4ccc(-c5ccc(-n6c7ccccc7c7ccccc76)cc5)cc4)nc(-c4ccccc4)n3)c2)cc1 ; CC1(C)c2ccccc2-c2ccc(-c3cc(-c4ccc(-c5ccc(-n6c7ccccc7c7ccccc76)cc5)cc4)nc(-c4ccccc4)n3)cc21 ; c1ccc(-c2cccc(-c3nc(-c4ccccc4)cc(-c4ccc(-c5ccc(-n6c7ccccc7c7ccccc76)cc5)cc4)n3)c2)cc1]

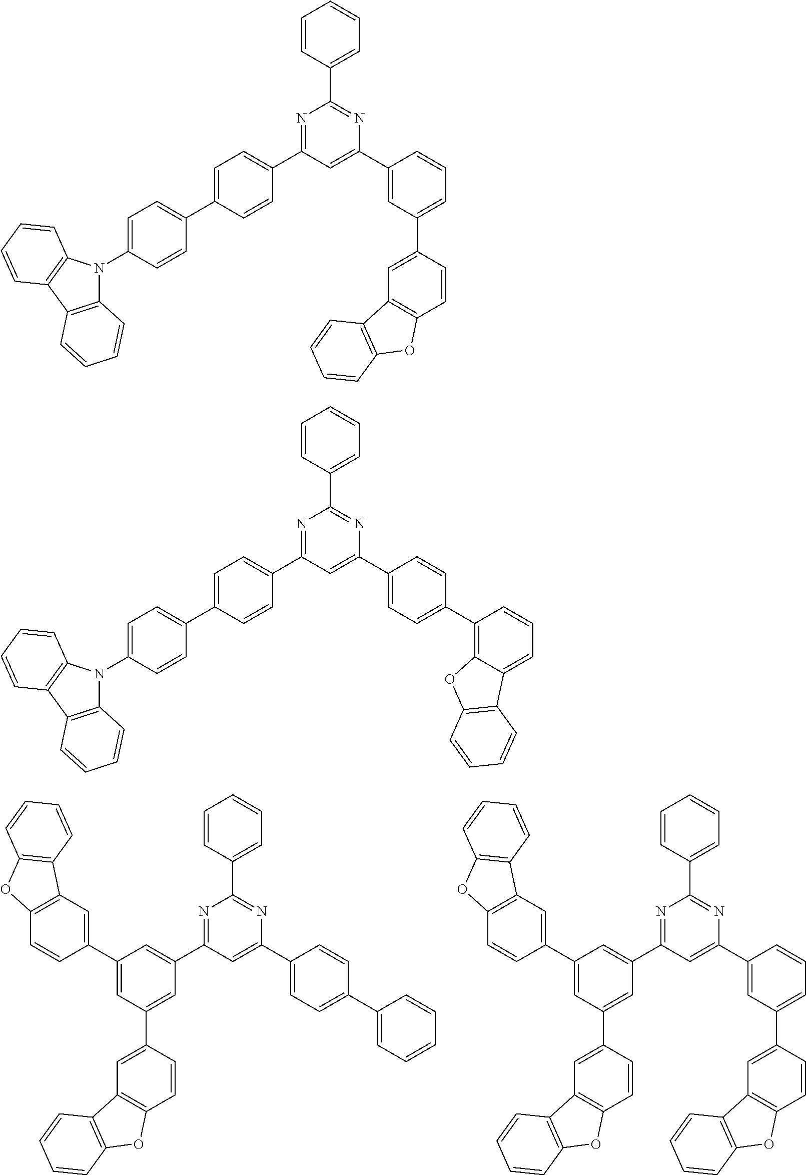

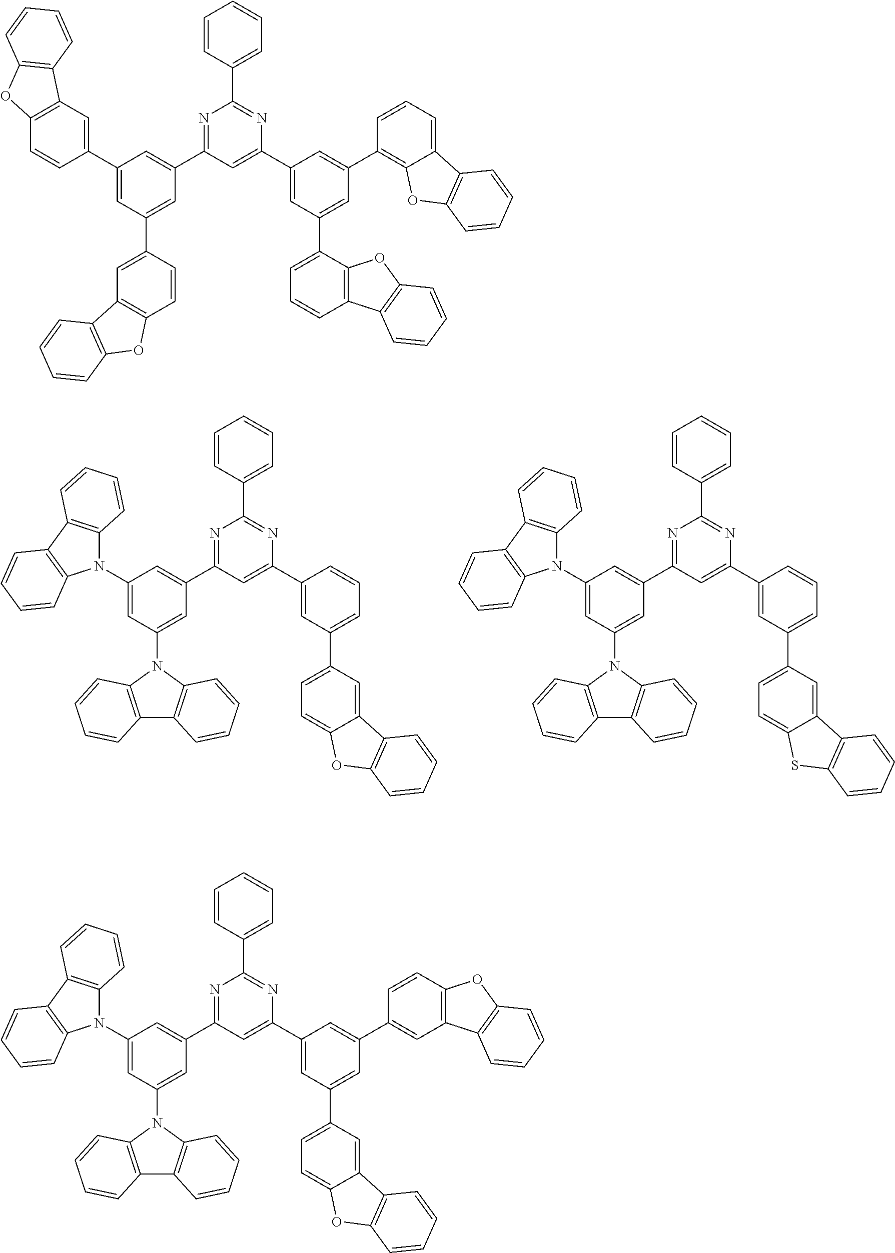 [SMILES: c1ccc(-c2nc(-c3cc(-c4ccc5oc6ccccc6c5c4)cc(-c4ccc5oc6ccccc6c5c4)c3)cc(-c3cc(-c4cccc5c4oc4ccccc45)cc(-c4cccc5c4oc4ccccc45)c3)n2)cc1 ; c1ccc(-c2nc(-c3cccc(-c4ccc5oc6ccccc6c5c4)c3)cc(-c3cc(-n4c5ccccc5c5ccccc54)cc(-n4c5ccccc5c5ccccc54)c3)n2)cc1 ; c1ccc(-c2nc(-c3cccc(-c4ccc5sc6ccccc6c5c4)c3)cc(-c3cc(-n4c5ccccc5c5ccccc54)cc(-n4c5ccccc5c5ccccc54)c3)n2)cc1 ; c1ccc(-c2nc(-c3cc(-c4ccc5oc6ccccc6c5c4)cc(-c4ccc5oc6ccccc6c5c4)c3)cc(-c3cc(-n4c5ccccc5c5ccccc54)cc(-n4c5ccccc5c5ccccc54)c3)n2)cc1]

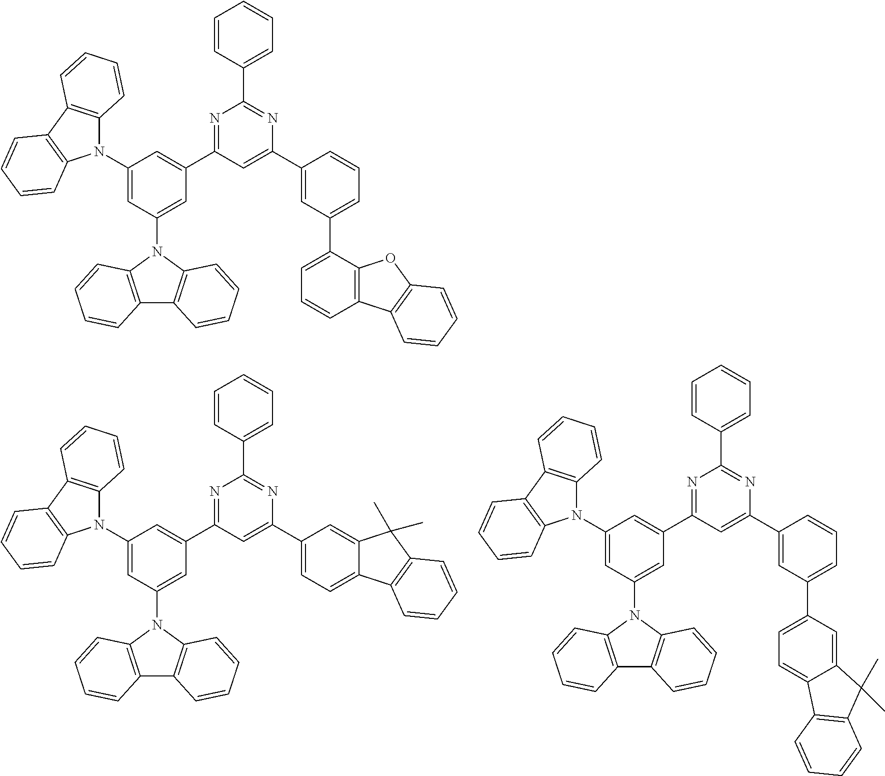

Production methods of the compounds represented by the formulae (I), (II). (III), (IV) and (V) are not specifically limited, and anyone skilled in the art can readily produce these compounds by utilizing and modifying known synthesis reactions. For example, the compound represented by the formula (V) can be produced with reference to the description of WO2003/080760 and WO2013/077352.

The organic EL device of the present invention may be a fluorescent or phosphorescent light emission-type monochromatic light emitting device or may be a fluorescent/phosphorescent hybrid-type white light emitting device, or may also be a simple-type device having a single light emitting unit or a tandem-type device having plural light emitting units. Here, the “light emitting unit” is the smallest unit which includes one or more organic layers, where one of the layers is a light emitting layer, and which can emit light through the recombination of the injected holes and electrons.

Thus, a representative device structure of the simple-type organic EL device is the following device structure.

(1) Anode/Light Emitting Unit/Cathode

The light emitting unit may be a laminate having phosphorescent light emitting layers and fluorescent light emitting layers, and in this case, the light emitting unit may have space layers between the light emitting layers to prevent excitons produced in the phosphorescent light emitting layers from diffusing in the fluorescent light emitting layers. Representative layer structures of the light emitting unit are shown below.

(a) Hole transporting layer/light emitting layer/electron transporting layer

(b) Hole transporting layer/first fluorescent light emitting layer/second fluorescent light emitting layer/electron transporting layer

(c) Hole transporting layer/phosphorescent light emitting layer/space layer/fluorescent light emitting layer/electron transporting layer

(d) Hole transporting layer/first phosphorescent light emitting layer/second phosphorescent light emitting layer/space layer/fluorescent light emitting layer/electron transporting layer

(e) Hole transporting layer/first phosphorescent light emitting layer/space layer/second phosphorescent light emitting layer/space layer/fluorescent light emitting layer/electron transporting layer

(f) Hole transporting layer/phosphorescent light emitting layer/space layer/first fluorescent light emitting layer/second fluorescent light emitting layer/electron transporting layer

The phosphorescent or fluorescent light emitting layers may emit light of colors which are different from each other. A specific layer structure is, in the laminated light emitting unit (d), hole transporting layer/first phosphorescent light emitting layer (which emits red light)/second phosphorescent light emitting layer (which emits green light)/space layer/fluorescent light emitting layer (which emits blue light)/electron transporting layer or the like.

An electron blocking layer may be suitably provided between a light emitting layer and the hole transporting layer or the space layer. Also, a hole blocking layer may be suitably provided between a light emitting layer and the electron transporting layer. When an electron blocking layer or a hole blocking layer is provided, it is possible to trap electrons or holes in the light emitting layer, increase the probability of charge recombination in the light emitting layer and improve the light emission efficiency.

A representative device structure of the tandem-type organic EL device is the following device structure.

(2) Anode/first light emitting unit/intermediate layer/second light emitting unit/cathode

As the first light emitting unit and the second light emitting unit, for example, light emitting units which are similar to the light emitting unit described above can be each independently selected.

The intermediate layer is also generally called an intermediate electrode, an intermediate conductive layer, a charge generating layer, an electron withdrawing layer, a connection layer or an intermediate insulating layer, and a known material composition which supplies electrons to the first light emitting unit and holes to the second light emitting unit can be used.

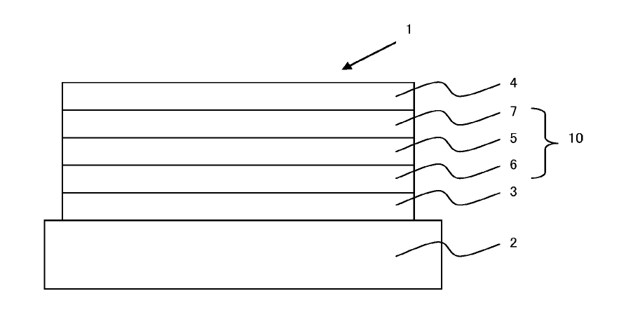

The rough structure of an example of the organic EL device of the present invention is shown in FIG. 1. The organic EL device 1 has a substrate 2, an anode 3, a cathode 4 and a light emitting unit (organic thin film layer) 10 provided between the anode 3 and the cathode 4. The light emitting unit 10 includes a light emitting layer 5 including at least one fluorescent light emitting layer containing a fluorescent host material and a fluorescent dopant material. A hole injection layer/hole transporting layer 6 or the like may be formed between the light emitting layer 5 and the anode 3, and an electron injection layer/electron transporting layer 7 or the like is formed between the light emitting layer 5 and the cathode 4. Also, an electron blocking layer may be provided on the anode 3 side of the light emitting layer 5, and a hole blocking layer may be provided on the cathode 4 side of the light emitting layer 5. The electron blocking layer and the hole blocking layer can trap electrons and holes in the light emitting layer 5 and increase the probability of the exciton generation in the light emitting layer 5.

In this description, a host material combined with a fluorescent dopant material is called a fluorescent host material, and a host material combined with a phosphorescent dopant material is called a phosphorescent host material. The fluorescent host material and the phosphorescent host material are not distinguished from each other only by the molecular structures. That is, the fluorescent host material means a material constituting a fluorescent light emitting layer containing a fluorescent dopant material, but it is not meant that the fluorescent host material cannot be used as a material constituting a phosphorescent light emitting layer. The same applies to the phosphorescent host material.

### (Substrate)

The organic EL device of the present invention is formed on a translucent substrate. The translucent substrate is a substrate to support the organic EL device, and is preferably a smooth substrate having a light transmittance in a visible region of 400 nm to 700 nm of 50% or more. Specifically, there are mentioned a glass sheet, a polymer sheet, etc. As the glass sheet, in particular, there are mentioned those produced using soda lime glass, barium strontium-containing glass, lead glass, aluminosilicate glass, borosilicate glass, barium borosilicate glass, quartz or the like as the starting material. As the polymer sheet, there are mentioned those produced using polycarbonate, acryl, polyethylene terephthalate, polyether sulfide, polysulfone or the like as the starting material.

### (Anode)

The anode of the organic EL device plays a role of injecting holes into the hole transporting layer or the light emitting layer, and using one having a work function of 4.5 eV or more is effective. Specific examples of the anode material include indium tin oxide alloy (ITO), tin oxide (NESA), indium oxide zinc oxide, gold, silver platinum, copper, etc. The anode may be formed of a thin film of the electrode substance according to a vapor deposition method, a sputtering method or the like. In the case where light emitted in the light emitting layer is taken out through the anode, it is preferable that the light transmittance in a visible range of the anode is larger than 10%. Also preferably, the sheet resistivity of the anode is a few hundred a/square or less. Though depending on the material, the thickness of the anode is selected from a range of generally 10 nm to 1 μm, preferably 10 nm to 200 nm.

### (Cathode)

The cathode plays a role of injecting electrons into the electron injection layer, the electron transporting layer or the light emitting layer, and is preferably formed of a material having a small work function. Specific examples of the cathode material include, though not limited thereto, indium, aluminum, magnesium, magnesium-indium alloy, magnesium-aluminum alloy, aluminum-lithium alloy, aluminum-scandium-lithium alloy, magnesium-silver alloy, etc. Like the anode, the cathode may also be formed of a thin film to be formed according to a vapor deposition method, a sputtering method, etc. If desired, emitted light may be taken out from the side of the cathode.

### (Guest Material for Light Emitting Layer)

The light emitting layer is a layer containing a highly luminescent substance, and various materials can be used. For example, as highly luminescent substances, fluorescent compounds which emit fluorescent light and phosphorescent compounds which emit phosphorescent light can be used. A fluorescent compound is a compound which can emit light from the singlet excitation state, and a phosphorescent compound is a compound which can emit light from the triplet excitation state.

As blue fluorescent light emitting materials which can be used for the light emitting layer, pyrene derivatives, styrylamine derivatives, chrysene derivatives, fluoranthene derivatives, fluorene derivatives, diamine derivatives, triarylamine derivatives and the like can be used. Specifically, N,N′-bis[4-(9H-carbazol-9-yl)phenyl]-N,N′-diphenyl stilbene-4,4′-diamine (abbreviation: YGA2S), 4-(9H-carbazol-9-yl)-4′-(10-phenyl-9-anthryl)triphenylamine (abbreviation: YGAPA), 4-(10-phenyl-9-anthryl)-4′-(9-phenyl-9H-carbazol-3-yl)triphenylamine (abbreviation: PCBAPA) and the like are used.

As green fluorescent light emitting materials which can be used for the light emitting layer, aromatic amine derivatives and the like can be used. Specifically, N-(9,10-diphenyl-2-anthryl)-N, 9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), N-[9,10-bis(1,1′-biphenyl-2-yl)]-N-[4-(9H-carbazol-9-yl)phenyl]-N-phenylanthracen-2-amine (abbreviation: 2YGABPhA), N,N,9-triphenylanthracen-9-amine (abbreviation: DPhAPhA) and the like are used.

As red fluorescent light emitting materials which can be used for the light emitting layer, tetracene derivatives, diamine derivatives and the like can be used. Specifically, N,N,N′,N′-tetrakis(4-methylphenyl)tetracene-5,11-di amine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD) and the like are used.

As blue phosphorescent light emitting materials which can be used for the light emitting layer, metal complexes such as iridium complexes, osmium complexes and platinum complexes are used. Specifically, bis[2-(4′,6′-difluorophenyl)pyridinato-N,C2′] iridium(III) tetrakis(1-pyrazolyl)borate (abbreviation: FIr₆), bis[2-(4′,6′-difluorophenyl)pyridinato-N,C2′]iridium(III) picolinate (abbreviation: FIrpic), bis[2-(3′,5′bistrifluoromethylphenyl)pyridinato-N,C2′] iridium (III) picolinate (abbreviation: Ir(CF₃ppy)₂(pic)), bis[2-(4′,6′-difluorophenyl)pyridinato-N,C2′] iridium(III) acetylacetonate (abbreviation: FIracac) and the like are used.

As green phosphorescent light emitting materials which can be used for the light emitting layer, iridium complexes and the like are used. Tris(2-phenylpyridinato-N,C2′) iridium(III) (abbreviation: Ir(ppy)₃), bis(2-phenylpyridinato-N,C2′) iridium(III) acetyl acetonate (abbreviation: Ir(ppy)₂(acac)), bis(1,2-diphenyl-1H-benzimidazolato) iridium(III) acetylacetonate (abbreviation: Ir(pbi)₂(acac)), bis(benzo[h]quinolinato) iridium(III) acetylacetonate (abbreviation: Ir(bzq)₂(acac)) and the like are used.

As red phosphorescent light emitting materials which can be used for the light emitting layer, metal complexes such as iridium complexes, platinum complexes, terbium complexes and europium complexes are used. Specifically, organometallic complexes such as bis[2-(2′-benzo[4,5-α]thienyl)pyridinato-N,C3′] acetylacetonate (abbreviation: Ir(btp)₂(acac)), bis(1-phenylisoquinolinato-N,C2′) iridium(III) acetylacetonate (abbreviation: Ir(piq)₂(acac)), (acetylacetonato)bis [2,3-bis(4-fluorophenyl)quinoxalinato] iridium(III) (abbreviation: Ir(Fdpq)₂(acac)) and 2,3,7,8,12,13,17,18-octaethyl-21H,23H-porphyrin platinum(II) (abbreviation: PtOEP) are used.

Also, rare-earth metal complexes such as tris(acetyl acetonato)(monophenanthroline) terbium(III) (abbreviation: Tb(acac)₃(Phen)), tris(1,3-diphenyl-1,3-propanedionato)(monophenanthroline) europium(III) (abbreviation: Eu(DBM)₃(Phen)) and tris[1-(2-thenoyl)-3,3,3-trifluoroacetonato](monophenanthroline) europium(III) (abbreviation: Eu(TTA)₃(Phen)) can be used as phosphorescent compounds because light is emitted from rare-earth metal ions (electron transition between different multiplicities).

### (Host Material for Light Emitting Layer)

The light emitting layer may have a composition in which any of the highly luminescent substances (guest materials) described above is dispersed in another substance (host material). Various substances can be used as the substance for dispersing a highly luminescent substance, and a substance which has a higher lowest unoccupied molecular orbital level (LUMO level) and a lower highest occupied molecular orbital level (HOMO level) than the highly luminescent substance is preferably used.

As the substance for dispersing the highly luminescent substance (host material), 1) metal complexes such as aluminum complexes, beryllium complexes or zinc complexes, 2) heterocyclic compounds such as oxadiazole derivatives, benzimidazole derivatives or phenanthroline derivatives, 3) condensed aromatic compounds such as carbazole derivatives, anthracene derivatives, phenanthrene derivatives, pyrene derivatives or chrysene derivatives and 4) aromatic amine compounds such as triarylamine derivatives or condensed polycyclic aromatic amine derivatives can be used. Specifically, metal complexes such as tris(8-quinolinolato) aluminum(III) (abbreviation: Alq), tris(4-methyl-8-quinolinolato) aluminum(III) (abbreviation: Almq₃), bis(10-hydroxybenzo[h] quinolinato) beryllium(II) (abbreviation: BeBq₂), bis(2-methyl-8-quinolinolato)(4-phenylphenolato) aluminum(III) (abbreviation: BAlq), bis(8-quinolinolato) zinc(II) (abbreviation: Znq), bis[2-(2-benzoxazolyl)phenolato] zinc(II) (abbreviation: ZnPBO) and bis[2-(2-benzothiazolyl)phenolato] zinc(II) (abbreviation: ZnBTZ), heterocyclic compounds such as 2-(4-biphenylyl)-5-(4-tert-butylphenyl)-1,3,4-oxadiazole (abbreviation: PBD), 1,3-bis [5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), bathophenanthroline (abbreviation: BPhen) and bathocuproine (abbreviation: BCP), condensed aromatic compounds such as 9-[4-(10-phenyl-9-anthryl)phenyl]-9H-carbazole (abbreviation: CzPA), 3,6-diphenyl-9-[4-(10-phenyl-9-anthryl)phenyl]-9H-carbazole (abbreviation: DPCzPA), 9,10-bis(3,5-diphenylphenyl)anthracene (abbreviation: DPPA), 9,10-di(2-naphthyl)anthracene (abbreviation: DNA), 2-tert-butyl-9, 10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 3,3′,3″-(benzene-1,3, 5-triyl)tripyrene (abbreviation: TPB3),9,10-diphenylanthracene (abbreviation: DPAnth) and 6,12-dimethoxy-5,11-diphenylchrysene, aromatic amine compounds such as N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), NPB (or α-NPD), TPD, DFLDPBi and BSPB and the like can be used. Two or more kinds of the substance for dispersing the highly luminescent substance (guest material) (host material) can be used.

The thickness of the light emitting layer is preferably 5 to 50 nm, more preferably 7 to 50 nm, even more preferably 10 to 50 nm. When the thickness is 5 nm or more, it is easy to form the light emitting layer, and when 50 nm or less, the driving voltage can be prevented from increasing.

### (Electron Transporting Layer)

The electron transporting layer is an organic layer formed between the light emitting layer and the cathode, and has a function of transporting electrons from the cathode to the light emitting layer. In the case where the electron transporting layer is formed of plural layers, the organic layer close to the cathode may be defined as an electron injection layer. The electron injection layer has a function of efficiently injecting electron from the cathode to the organic layer unit.

In the present invention, the electron transporting material for use in the electron transporting layer is as described above.

The thickness of the electron transporting layer is not specifically limited but is preferably 1 nm to 100 nm. In the case where the electron transporting layer of the organic EL device has a two-layer configuration of a first electron transporting layer (anode side) and a second electron transporting layer (cathode side), the thickness of the first electron transporting layer is preferably 5 to 60 nm, more preferably 10 to 40 nm; and the thickness of the second electron transporting layer is preferably 1 to 20 nm, more preferably 1 to 10 nm.

As the constituent component of the electron injection layer that may be arranged in adjacent to the electron transporting layer, an insulator or a semiconductor is preferably used as the inorganic compound in addition to a nitrogen-containing cyclic derivative. When the electron injection layer is formed of an insulator or a semiconductor, current leakage can be effectively prevented and electron injection performance can be enhanced.

As the insulator, at least one metal compound selected from the group consisting of an alkali metal chalcogenide, an alkaline earth metal chalcogenide, an alkali metal halide and an alkaline earth metal halide is preferably used. When the electron injection layer is formed of such an alkali metal chalcogenide, the configuration is preferred from the viewpoint that electron injection performance can be further improved. Specifically, preferred examples of alkali metal chalcogenides include Li₂O, K₂O, Na₂S, Na₂Se and Na₂O; preferred examples of alkaline earth metal chalcogenides include CaO, BaO, SrO, BeO, BaS and CaSe. Preferred examples of alkali metal halides include LiF, NaF, KF, LiCl, KCl and NaCl. Preferred examples of alkaline earth metal halides include fluorides such as CaF₂, BaF₂, SrF₂, MgF₂ and BeF₂, and other halides than fluorides.

The semiconductor includes one alone or two or more, as combined, of an oxide, a nitride, an oxynitride and the like containing at least one element of Ba, Ca, Sr, Yb, Al, Ga, In, Li, Na, Cd, Mg, Si, Ta, Sb and Zn. Preferably, the inorganic compound to constitute the electron injection layer is a microcrystalline or amorphous insulating thin film. When the electron injection layer is formed of such an insulating thin film, a more homogeneous thin film can be formed and therefore pixel defects such as dark spots can be reduced. The inorganic compound includes an alkali metal chalcogenide, an alkaline earth metal chalcogenide, an alkali metal halide and an alkaline earth metal halide.

In the case where such an insulator or a semiconductor is used, a preferred thickness of the layer is 0.1 nm to 15 nm or so. The electron injection layer in the present invention may contain the above-mentioned electron donating dopant material.

### (Hole Transporting Layer)

The hole transporting layer is an organic layer formed between the light emitting layer and the anode, and has a function of transporting holes from the anode to the light emitting layer. In the case where the hole transporting layer is formed of plural layers, the organic layer close to the anode may be defined as a hole injection layer. The hole injection layer has a function of efficiently injecting holes from the anode to the organic layer unit.

The hole transporting layer of the organic EL device of the present invention may have a two-layer configuration of a first hole transporting layer (anode side) and a second hole transporting layer (cathode side).

The thickness of the hole transporting layer is not specifically limited but is preferably 10 to 200 nm. When the hole transporting layer has a two-layer configuration of a first hole transporting layer (anode side) and a second hole transporting layer (cathode side), the thickness of the first hole transporting layer is preferably 50 to 150 nm, more preferably 50 to 110 nm, and the thickness of the second hole transporting layer is preferably 5 to 50 nm, more preferably 5 to 30 nm.

In the organic EL device of the present invention, a layer containing an acceptor material may be attached to the hole transporting layer or to the anode side of the first hole transporting layer. With that, lowering the driving voltage and reduction in the production cost can be expected.

### (Space Layer)

The space layer is, for example when a fluorescent light emitting layer and a phosphorescent light emitting layer are laminated, a layer which is provided between the fluorescent light emitting layer and the phosphorescent light emitting layer for the purposes of preventing the excitons produced in the phosphorescent light emitting layer from diffusing in the fluorescent light emitting layer or of adjusting the carrier balance. Also, the space layer can be provided between phosphorescent light emitting layers.

Because the space layer is provided between light emitting layers, a material having both electron transporting capability and hole transporting capability is preferable. Also, to prevent the diffusion of the triplet energy in a neighboring phosphorescent light emitting layer, the triplet energy is preferably 2.6 eV or more. The materials used for the space layer are materials similar to those used for the hole transporting layer.

### (Blocking Layer)

The organic EL device of the present invention can also have a blocking layer such as an electron blocking layer, a hole blocking layer or a triplet blocking layer, at a part neighboring a light emitting layer. Here, the electron blocking layer is a layer which prevents the leakage of electrons from the light emitting layer to the hole transporting layer, and is arranged between the light emitting layer and the hole transporting layer. The hole blocking layer is a layer which prevents the leakage of holes from the light emitting layer to the electron transporting layer, and is arranged between the light emitting layer and the electron transporting layer.

The triplet blocking layer has a function of inhibiting the energy deactivation of a triplet exciton on a molecule of the electron transporting layer other than the light emitting dopant by preventing the triplet exciton produced in the light emitting layer from diffusing in the surrounding layers and by trapping the triplet exciton in the light emitting layer, as described below.

### [Electronic Device]

The organic EL device obtained using the compound of the present invention has a further improved light emission efficiency. Accordingly, the device can be used for electronic devices such as display parts including an organic EL panel module and the like; display devices of a television, a mobile phone, a personal computer and the like; and light emitting devices including a light, a vehicle light and the like.

### EXAMPLES

Next, the present invention is explained in further detail by Examples, but the present invention is not limited at all by these.

In the following, an expression of compound (1) includes a case of compound (1′).

### Example 1

A glass substrate with an ITO transparent electrode (anode) of 25 mm×75 mm×1.1 mm (thickness) (manufactured by GEOMATEC Co., Ltd.) was subjected to ultrasonic cleaning in isopropyl alcohol for five minutes and then to UV ozone cleaning for 30 minutes. The thickness of the ITO transparent electrode was 130 nm.

The glass substrate with the transparent electrode line after cleaning was attached to a substrate holder of a vacuum evaporator, and an electron acceptor compound HI shown below was first deposited on the surface with the transparent electrode line to cover the transparent electrode, and an HI film having a thickness of 5 nm was thus formed.

On the compound HI film, an aromatic amine derivative (compound HT-1) shown below was deposited as a first hole transporting material to form a first hole transporting layer having a thickness of 80 nm.

Subsequently to the formation to the first hole transporting layer, an aromatic amine derivative (compound HT-2) shown below was deposited as a second hole transporting material to form a second hole transporting layer having a thickness of 10 nm.

Further, on the second hole transporting layer, the following compound BH as a host material and the following compound BD as a fluorescent dopant material were co-deposited to form a light emitting layer having a thickness of 25 nm. The concentration of the compound BD in the light emitting layer was 4.0% by mass. The co-deposited film functions as a light emitting layer.

Subsequently to the formation of the light emitting layer, a film having a thickness of 25 nm was formed using the following compound (1-1) as the compound (1) and the following compound (2-1) as the component (2) in a ratio by mass of 5/5. The compound 1 film functions as an electron transporting layer.

Next, a film of LiF having a thickness of 1 nm was formed as an electron injection layer, at a film formation speed of 0.1 angstrom/sec. A metal Al was deposited on the LiF film to form a metal cathode having a thickness of 80 nm.

The organic EL device of Example 1 has the following layer configuration.

ITO (130 nm)/HI (5 nm)/HT-1 (80 nm)/HT-2 (10 nm)/BH:BD (25 nm: 4% by mass)/compound (1-1):compound (2-1) (ratio by mass, 5:5) (25 nm)/LiF (1 nm)/Al (80 nm).

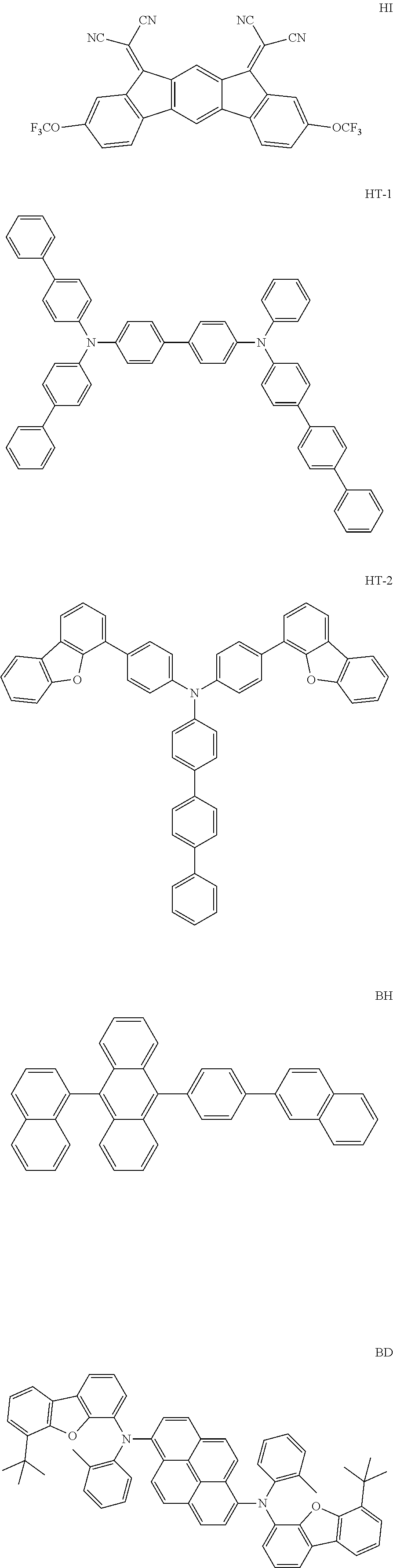

### Examples 2 to 6 and Comparative Examples 1 to 5

Organic EL devices were produced in the same manner as in Example 1 except that the compounds (1) and (2) to be used in the electron transporting layer were changed to the compounds listed in Table 2.

The compounds used in the electron transporting layer in Examples 1 to 6 and Comparative Examples 1 to 5 are shown below.

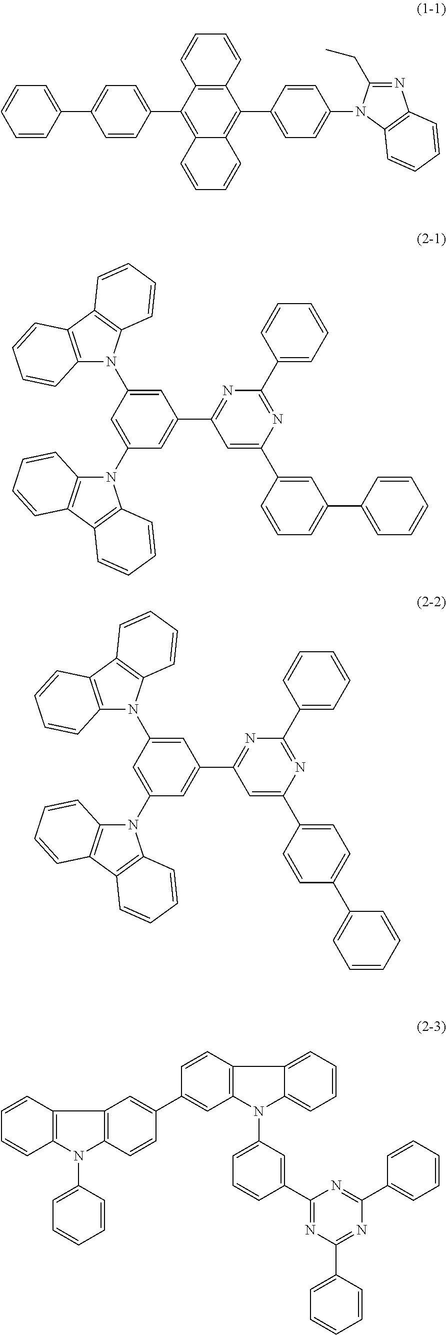

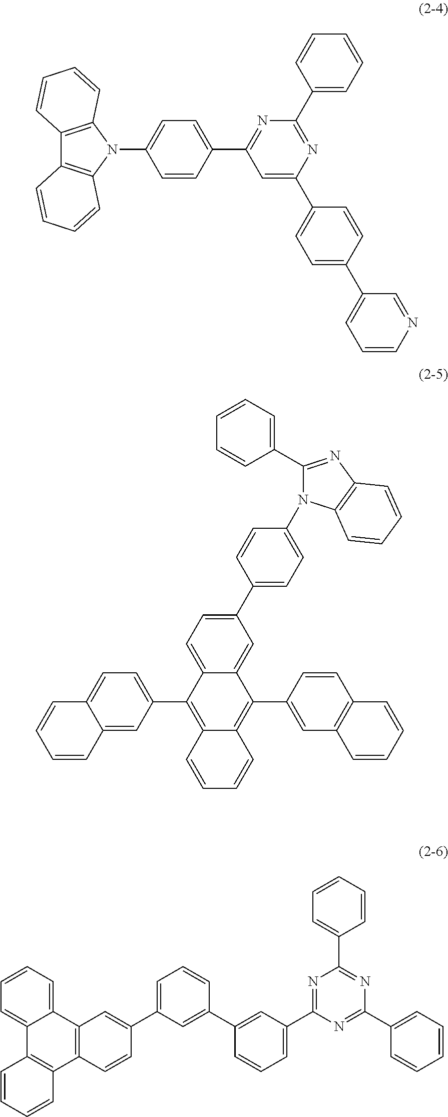 [SMILES: c1ccc(-c2nc(-c3ccc(-c4cccnc4)cc3)cc(-c3ccc(-n4c5ccccc5c5ccccc54)cc3)n2)cc1 ; c1ccc(-c2nc3ccccc3n2-c2ccc(-c3ccc4c(-c5ccc6ccccc6c5)c5ccccc5c(-c5ccc6ccccc6c5)c4c3)cc2)cc1 ; c1ccc(-c2nc(-c3ccccc3)nc(-c3cccc(-c4cccc(-c5ccc6c7ccccc7c7ccccc7c6c5)c4)c3)n2)cc1]

The electron mobility and the electron affinity of these compounds are shown in Table 1.

The electron mobility and the electron affinity were measured as follows.

### (1) Measurement of Electron Mobility

The electron mobility can be measured through impedance spectrometry in the manner mentioned below.

A device having at least an anode, a cathode and a layer sandwiched between the anode and the cathode and containing a compound Target whose electron mobility is to be measured (this may be referred to as a Target-containing layer) was produced. The thickness of the Target-containing layer was 200 nm. While a bias DC voltage was applied to the device, a slight alternating voltage of 0.1 V was applied thereto. The alternating current value (absolute value and phase) at this time was measured. This measurement was carried out while changing the frequency of the alternating voltage, and from the current value and the voltage value, the complex impedance (Z) was calculated. At this time, the frequency dependence of the imaginary part (ImM) of the modulus M=iωZ (i: imaginary unit, ω: angular frequency) was obtained, and the reciprocal number of the frequency co to give a maximum value of ImM was defined as the response time of electrons for conducting the Target-containing layer. With that, according to the following computational expression, the electron mobility (unit: cm²/(V·s)) was calculated.

### (Computational Expression)

Electron mobility=(thickness of Target-containing layer)²/(response time×voltage)

More precisely, the electron mobility in Examples and Comparative Examples was measured using a device for mobility evaluation produced according to the following process.

A glass substrate having a size of 25 mm×75 mm×1.1 mm thick was ultrasonically washed in isopropyl alcohol for 5 minutes. After the ultrasonic washing, this was subjected to UV ozone washing for 30 minutes.

After thus washed, the glass substrate was set on a substrate holder of a vacuum deposition apparatus, in which, first, a metal aluminum (Al) was deposited thereon to form a metal Al anode having a thickness of 80 nm.

Next, the compound Target for measurement of electron mobility was deposited on the side having the metal Al anode line formed thereon, thereby forming a 200-nm thick layer to cover the metal Al anode.

Next, on the compound Target, a compound ET2 was deposited to form an electron transporting layer having a thickness of 10 nm.

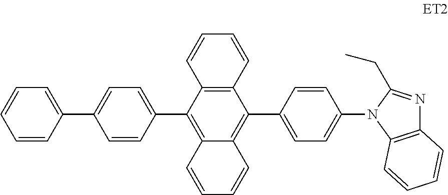 [SMILES: CCc1nc2ccccc2n1-c1ccc(-c2c3ccccc3c(-c3ccc(-c4ccccc4)cc3)c3ccccc23)cc1]

Next, on the electron transporting layer, lithium fluoride (LiF) was deposited to form an electron injecting electrode (cathode) having a thickness of 1 nm.

With that, on the electron injecting electrode, a metal aluminum (Al) was deposited to form a metal Al cathode having a thickness of 80 nm.

The configuration of the device for mobility evaluation is shown in a summary form as follows.

Al(80)/Target(200)/ET2(10)/LiF(1)/Al(80)

The parenthesized number means the thickness (unit: nm).

Subsequently, using the device for mobility evaluation produced according to the above-mentioned process, the electron mobility is measured according to the following process.

The device for mobility evaluation is set on an impedance measurement apparatus, and the impedance thereof is measured.

The impedance measurement was carried out by scanning the measurement frequency in a range of 1 Hz to 1 MHz. In so doing, an alternating voltage of 0.1 V and a bias DC voltage V were applied at the same time to the device for mobility evaluation.

From the measured complex impedance (Z), the modulus M was calculated using the following computational expression (C1).

M=iωZ Computational Expression (C1):

In the above computational expression (C1), i means an imaginary unit whose square is −1, and ω is an angular frequency [rad/s].

In a Bode plot where longitudinal axis indicates the imaginary part of the modulus M and the horizontal axis indicates the frequency [Hz], the electric time constant τ [s] of the device for mobility evaluation was obtained from the frequency fₘₐₓ showing the peak, using the following computational expression (C2).

τ=1/(2πfₘₐₓ) Computational Expression (C2):

In the above computational expression (C2), π is a sign indicting the circumference ratio.

Using the above time constant τ, the electron mobility μ [cm²/(V·s)] was calculated from the relationship of the following computational expression (C3).

μ=d²/(Vτ) Computational Expression (C3):

The mobility in this description is a value when the root square of the electric field intensity E^{1/2}=500 [V^{1/2}/cm^{1/2}]. The root square of the electric field intensity E^{1/2} was calculated from the relationship of the following computational expression (C4).

E^{1/2}=V^{1/2}/d^{1/2} Computational Expression (C4):

In the above-mentioned computational expressions (C3) and (C4), d means the total thickness of the organic thin film constituting the device, and relative to the configuration of the device for mobility evaluation, d=210 [nm].

In the computational expressions (C3) and (C4), V means a bias DV voltage [v] in impedance measurement. Under the measurement condition of Examples, the square root of the electric field intensity E^{1/2}=500 [V^{1/2}/cm^{1/2}] when V=5.25 [V]. Accordingly, the electron mobility in Examples is a value at a bias DC voltage V=5.25 [V]. Depending on the size of the measurement step to be mentioned below, measurement could not be carried out when V=5.25 [V], but in such a case, an extrapolation value from the measurement point around V=5.25 [V] was used.

The above-mentioned bias DC voltage is described in detail hereinunder.

In the measurement method employed in Examples and Comparative Examples, the sweep range of the bias DC voltage differs depending on the device for mobility evaluation, but the sweeping was carried out in a range of from 0 V to at most 20 V. The sweep range varies, because a high voltage is needed for sufficient charge injection for measurement when the device for mobility evaluation has a low electron mobility and therefore the upper limit of the sweep range must be large.

Within the above sweep range, the measurement was carried out at intervals of constant voltages. In the measurement, when the upper limit of the sweep range is small, the measurement points are at 0.2 V, and in the case where the measurement is carried out to a high voltage of around 20V, the measurement points are at 0.8 V, that is, in the voltage sweep range, the measurement steps can be controlled so that the measurement time would not be so long.

In Examples and Comparative Examples, for impedance measurement, 1260 Model Impedance Analyzer by Solartron Metrology Corporation was used, and for high-definition measurement, 1296 Model Permittivity Measurement Interface was used together.

### (2) Measurement of Electron Affinity

The electron affinity was calculated from the difference between the singlet energy S and the ionization potential Ip of the compound.

### Measurement of Ionization Potential Ip

The ionization potential was measured as follows. A single layer of each layer constituting the organic EL device was separately deposited in a mode of vacuum deposition on a glass substrate, and the thin film on the glass substrate was analyzed in air using a photoelectron spectrometer (AC-3, manufactured by Riken Keiki Co., Ltd.). Specifically, the material was irradiated with light, whereupon the quantity of electrons to be formed through charge separation was measured to determine the ionization potential. Relative to the energy of the irradiated light, the released photoelectrons were plotted as the 1/2 power thereof, and the threshold value of the photoelectron release energy was referred to as the ionization potential (Ip).

### Measurement of Singlet Energy S

The singlet energy S was measured as follows.

A solution in toluene of the compound to be analyzed (10 μmol/L) was prepared, put into a quartz cell, and the absorption spectrum (longitudinal axis: emission intensity, horizontal axis: wavelength) of this sample at room temperature (300 K) was obtained. Relative to the fall on the long wavelength side of this absorption spectrum, a tangent line was drawn, and the wavelength value λedge [mm] at the intersection between the tangent line and the horizontal axis was substituted into the conversion expression 1 shown below to calculate the singlet energy.

S[eV]=1239.85/λedge Conversion Expression 1:

In this description, the absorption spectrum was drawn using a spectral photometer (apparatus name; U3310) manufactured by Hitachi Ltd.

The tangent line to the fall on the long wavelength side of the absorption spectrum was drawn as follows. When moving on the spectral curve from the maximum value on the long wavelength side among the local maximum values of the absorption spectrum, toward the long wavelength direction, the tangent line at each point on the curve is taken into consideration. The inclination of the tangent line reduces along with the fall of the curve (that is, with the decrease in the value of the longitudinal axis), and thereafter increases in a repeated manner. The tangent line drawn at a point at which the inclination value is a local minimum value, drawn on the longest wavelength side (but except for a case where the absorbance is 0.1 or less) is defined as the tangent line to the fall on the long wavelength side of the absorption spectrum.

The local maximum point at a value of absorbance of 0.2 or less was not included in the above-mentioned local maximum value of the long wavelength side.

### Measurement of Electron Affinity (Af)

Using the measured values of the ionization potential Ip and the singlet energy S of the compound measured according to the above-mentioned methods, the electron affinity was calculated from the following computational expression.

Af=Ip−S

TABLE 1

| | Electron Mobility | Electron Affinity |
|---|---|---|
| | cm²/Vs | eV |
| Compound (1-1) | 2.0 × 10⁻⁴ | 2.08 |
| Compound (2-1) | 2.2 × 10⁻⁵ | 2.29 |
| Compound (2-2) | 9.5 × 10⁻⁵ | 2.35 |
| Compound (2-3) | 2.9 × 10⁻⁶ | 2.39 |
| Compound (2-4) | 1.5 × 10⁻⁵ | 2.25 |
| Compound (2-5) | 6.7 × 10⁻⁵ | 2.21 |
| Compound (2-6) | 1.6 × 10⁻⁵ | 2.36 |

### <Evaluation of Device Performance in Examples 1 to 6 and Comparative Examples 1 to 5>

The organic EL devices obtained in Examples 1 to 6 and Comparative Examples 1 to 5 were evaluated as follows. The results are shown in Table 2.

### (1) Driving Voltage (V)

The device was switched on by conduction between the ITO transparent electrode and the metal Al cathode so that the current density could be 10 mA/cm², whereupon the voltage (unit: V) was measured.

### (2) External Quantum Efficiency (EQE: %)

A voltage was applied to the device so that the current density could be 10 mA/cm², whereupon the spectral radiance spectrum was measured using a spectral radiance meter “CS-1000” (product name, manufactured by Konica Minolta Inc.).

From the resultant spectral radiance spectrum, the external quantum efficiency (EQE) (unit: %) was calculated under the assumption of Lambertian radiation.

### (3) Measurement of Lifetime

In driving at a current density of 50 mA/cm², the time taken until the brightness reached 95% of the initial brightness (LT95) was measured.

TABLE 2

| | | | | External | |
|---|---|---|---|---|---|
| | Compound of Electron | | Driving | Quantum | |
| | Transporting Layer | | Voltage | Efficiency | LT95 |
| | Compound (1) | Compound (2) | (V) | EQE (%) | (h) |
| Example 1 | Compound (1-1) | Compound (2-1) | 3.9 | 9.2 | 146 |
| Example 2 | Compound (1-1) | Compound (2-2) | 4 | 8.7 | 209 |
| Example 3 | Compound (1-1) | Compound (2-3) | 4.2 | 8.3 | 215 |
| Example 4 | Compound (1-1) | Compound (2-4) | 3.9 | 8.8 | 176 |
| Example 5 | Compound (1-1) | Compound (2-5) | 3.7 | 8.5 | 158 |
| Example 6 | Compound (1-1) | Compound (2-6) | 3.7 | 9.9 | 81 |

| | | | | |
|---|---|---|---|---|
| Comparative | Compound (1-1) | 3.4 | 7.3 | 59 |
| Example 1 | | | | |
| Comparative | Compound (2-1) | 8.3 | 4.2 | 1 |
| Example 2 | | | | |
| Comparative | Compound (2-2) | 6.9 | 5.2 | 1 |
| Example 3 | | | | |
| Comparative | Compound (2-3) | 7.7 | 3.6 | 1 |
| Example 4 | | | | |
| Comparative | Compound (2-4) | 4.2 | 8.3 | 46 |
| Example 5 | | | | |

### Examples 7 to 12 and Comparative Examples 6 to 9

Organic EL devices were produced in the same manner as in Example 1, except that the compounds (1) and (2) to be used in the electron transporting layer were changed to the compounds described in Table 4.

The compounds used in the electron transporting layer in Examples 7 to 12 and Comparative Examples 6 to 9 are shown below.

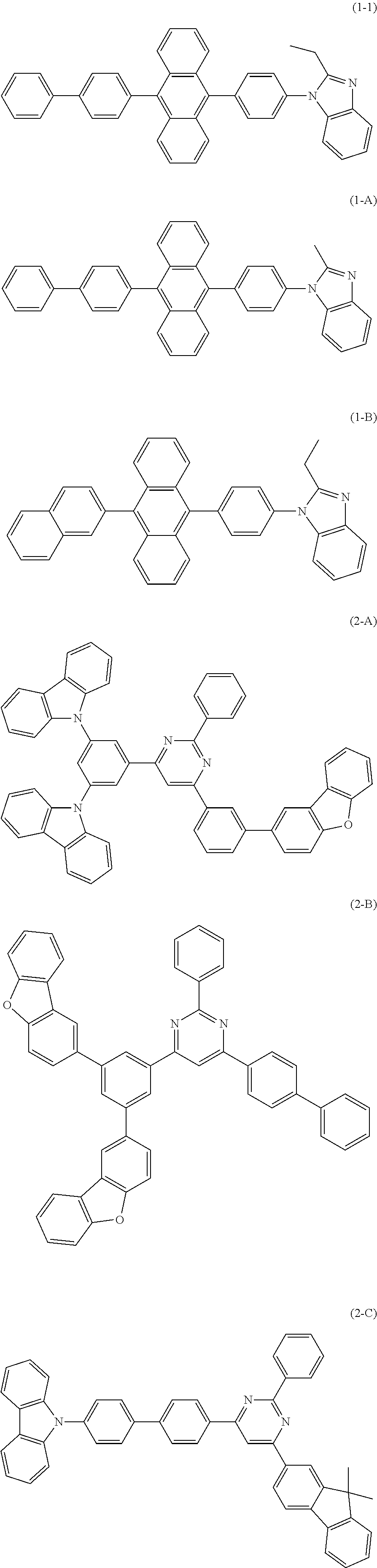

The electron mobility and the electron affinity of these compounds are shown in Table 3.

The electron mobility and the electron affinity were measured in the same manner as in Example 1.

TABLE 3

| | Electron Mobility | Electron Affinity |
|---|---|---|
| | cm²/Vs | eV |
| Compound (1-1) | 2.0 × 10⁻⁴ | 2.08 |
| Compound (1-A) | 8.4 × 10⁻⁵ | 2.07 |
| Compound (1-B) | 4.0 × 10⁻⁴ | 2.10 |
| Compound (2-A) | 2.0 × 10⁻⁵ | 2.25 |
| Compound (2-B) | 2.2 × 10⁻⁵ | 2.19 |
| Compound (2-C) | 8.2 × 10⁻⁶ | 2.20 |

### <Evaluation of Device Performance in Examples 7 to 12 and Comparative Examples 6 to 9>

The organic EL devices obtained in Examples 7 to 12 and Comparative Examples 6 to 9 were evaluated in point of the following. The results are shown in Table 4.

### (1) External Quantum Efficiency (EQE: %)

The external quantum efficiency (EQE) (unit: %) was calculated in the same manner as in Example 1, except that a voltage was applied to the device so that the current density could be 1 mA/cm².

### (2) Measurement of Lifetime

In driving at a current density of 50 mA/cm², the time taken until the brightness reached 90% of the initial brightness (LT90) was measured.

TABLE 4

| | | | External | |
|---|---|---|---|---|
| | Compound of Electron | | Quantum | |
| | Transporting Layer | | Efficiency | LT90 |
| | Compound (1) | Compound (2) | EQE (%) | (h) |
| Example 7 | Compound (1-1) | Compound (2-A) | 9.0 | 210 |
| Example 8 | Compound (1-1) | Compound (2-B) | 9.2 | 176 |
| Example 9 | Compound (1-1) | Compound (2-C) | 6.6 | 132 |
| Example 10 | Compound (1-A) | Compound (2-A) | 8.1 | 325 |
| Example 11 | Compound (1-B) | Compound (2-A) | 7.2 | 210 |
| Example 12 | Compound (1-B) | Compound (2-B) | 7.1 | 140 |

| | | | |
|---|---|---|---|
| Comparative | Compound (1-1) | 5.8 | 103 |
| Example 6 | | | |
| Comparative | Compound (1-B) | 5.7 | 43 |
| Example 7 | | | |
| Comparative | Compound (2-B) | 6.7 | 20 |
| Example 8 | | | |
| Comparative | Compound (2-C) | 5.6 | 11 |
| Example 9 | | | |

### REFERENCE SIGNS LIST

1 Organic Electroluminescence Device
2 Substrate
3 Anode
4 Cathode
5 Light Emitting Layer
6 Hole Injection Layer/Hole Transporting Layer
7 Electron Injection Layer/Electron Transporting Layer
10 Light Emitting Unit

1. An organic electroluminescence device comprising a cathode, an anode, and an organic thin film layer which is formed of one layer or plural layers at least containing a light emitting layer and which is sandwiched between the cathode and the anode,
the device further comprising an electron transporting layer between the light emitting layer and the cathode,
wherein the electron transporting layer contains at least compound (1) and compound (2), and the compound (1) and the compound (2) satisfy the following expression (A):
Electron mobility of compound (1)>Electron mobility of compound (2)>10⁻⁷ cm²/Vs (A)
wherein the compound (1) is a compound selected from compounds represented by the following formulae (I), (II) and (III) and the compound (2) is a compound selected from compounds represented by the following formula (IV) and compounds represented by the following formula (V): 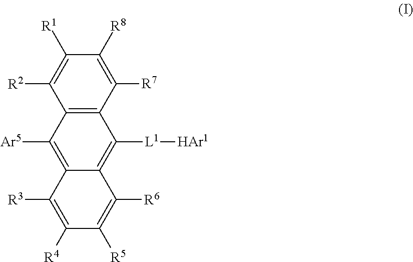
wherein L¹ represents a single bond, a substituted or unsubstituted arylene group having 6 to 30 ring carbon atoms, or a substituted or unsubstituted heteroarylene group having 5 to 30 ring atoms;
Ar⁵ represents a substituted or unsubstituted aryl group having 6 to 30 ring carbon atoms, or a substituted or unsubstituted heteroaryl group having 5 to 30 ring atoms; and
HAr¹ represents a group represented by the following formula (a): 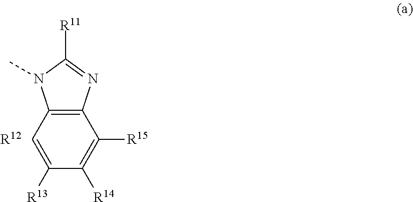
wherein R¹ to R⁸ and R¹¹ to R¹⁵ each independently represent a hydrogen atom, a fluorine atom, a cyano group, a substituted or unsubstituted alkyl group having 1 to 20 carbon atom, a substituted or unsubstituted cycloalkyl group having 3 to 20 ring carbon atoms, a substituted or unsubstituted alkoxy group having 1 to 20 carbon atoms, a substituted or unsubstituted aryloxy group having 6 to 30 ring carbon atoms, a substituted or unsubstituted alkylthio group having 1 to 20 carbon atoms, a substituted or unsubstituted arylthio group having 6 to 30 ring carbon atoms, a substituted or unsubstituted aryl group having 6 to 30 ring carbon atoms, a substituted or unsubstituted heteroaryl group having 5 to 30 ring atoms, or a group represented by —Si(R₁₀₁)(R₁₀₂)(R₁₀₃) where R₁₀₁ to R₁₀₃ each independently represent a hydrogen atom, a substituted or unsubstituted alkyl group having 1 to 20 carbon atoms, or a substituted or unsubstituted aryl group having 6 to 30 ring carbon atoms: 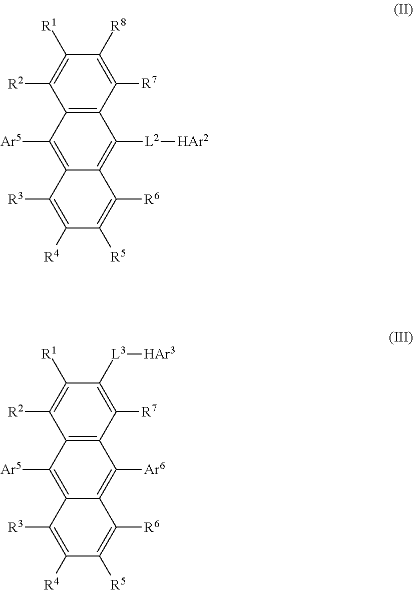
wherein L² and L³ each independently represent a single bond, a substituted or unsubstituted arylene group having 6 to 30 ring carbon atoms, or a substituted or unsubstituted heteroarylene group having 5 to 30 ring atoms;
Ar⁵ and Ar⁶ each represent a substituted or unsubstituted aryl group having 6 to 30 ring carbon atoms, or a substituted or unsubstituted heteroaryl group having 5 to 30 ring atoms;
R¹ to R⁸ are as defined above;
HAr² and HAr³ each independently represent a group represented by the following formula (b): 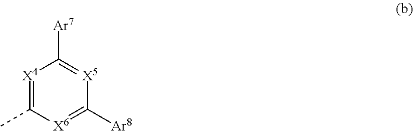
wherein Ar⁷ and Ar⁹ each independently represent a hydrogen atom, a substituted or unsubstituted aryl group having 6 to 30 ring carbon atoms, or a substituted or unsubstituted heteroaryl group having 5 to 30 ring atoms; and
X⁴ to X⁶ each independently represent N or CR⁰, with the proviso that at least one is N, R⁰ represents a hydrogen atom, a substituted or unsubstituted alkyl group having 1 to 20 carbon atoms, or a substituted or unsubstituted aryl group having 6 to 30 ring carbon atoms, and when plural R⁰'s are present, they may be the same or different: 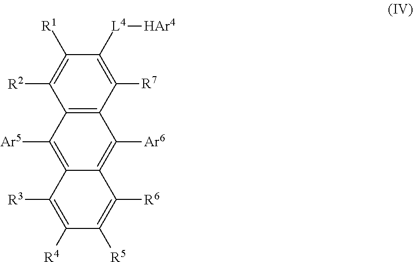
wherein Ar⁵, Ar⁶, and R¹ to R⁷ are as defined above;
L⁴ represents a single bond, a substituted or unsubstituted arylene group having 6 to 30 ring carbon atoms, or a substituted or unsubstituted heteroarylene group having 5 to 30 ring atoms; and
HAr⁴ represents a group represented by the following formula (a) or (c): 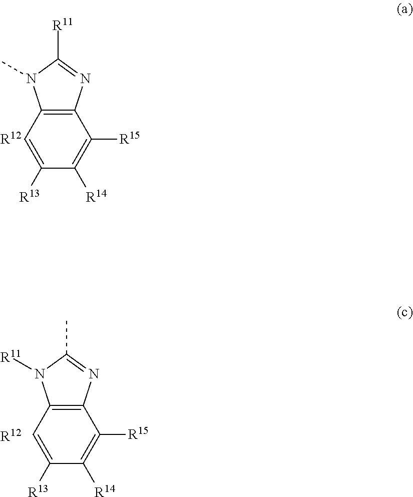
wherein R¹¹ to R¹⁵ are as defined above: 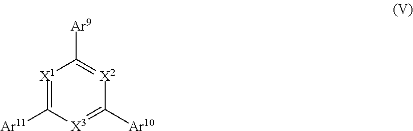
wherein Ar⁹ to Ar¹¹ each independently represent a hydrogen atom, or a monovalent residue containing at least one selected from aromatic hydrocarbon compounds represented by the following formulae (d) to (l), substituted or unsubstituted heteroaromatic compounds each having 5 to 30 ring atoms, and groups formed by bonding a plurality of these compounds to each other, and when a plurality of the compounds is bonded, the compounds which each constitute a bonding unit may be the same or different: 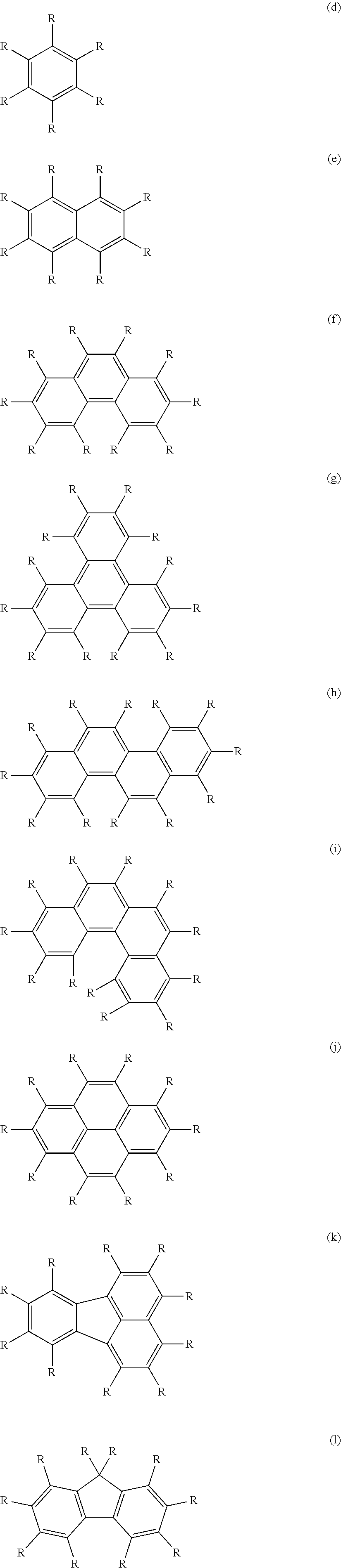
wherein R represents a hydrogen atom, a fluorine atom, a cyano group, or a substituted or unsubstituted alkyl group having 1 to 20 carbon atoms; and
X¹ to X³ each independently represent N or CR⁰, with the proviso that at least one is N, and R⁰ is as defined above.

2. The organic electroluminescence device according to claim 1, wherein the compound (1) and the compound (2) satisfy the following expression (B):
Electron affinity of compound (1)(Af1)<Electron affinity of compound (2)(Af2) (B).

3. The organic electroluminescence device according to claim 1, wherein the electron mobility of the compound (1)>10⁻⁴ cm²/Vs.

4. The organic electroluminescence device according to claim 1, wherein the compound (1) is a compound selected from compounds represented by the formula (I).

5. The organic electroluminescence device according to claim 4, wherein in the formula (I), Ar⁵ is a substituted or unsubstituted aryl group having 6 to 30 ring carbon atoms.

6. The organic electroluminescence device according to claim 4, wherein in the formula (I), L¹ is a substituted or unsubstituted arylene group having 6 to 30 ring carbon atoms.

7. The organic electroluminescence device according to claim 4, wherein in the formula (I), R¹ to R⁸ each are independently a hydrogen atom.

8. The organic electroluminescence device according to claim 4, wherein in the formula (I), R¹¹ to R¹⁵ in the formula (a) each are independently a hydrogen atom, or a substituted or unsubstituted alkyl group having 1 to 20 carbon atoms.

9. The organic electroluminescence device according to claim 4, wherein in the formula (I), R¹¹ in the formula (a) is an unsubstituted alkyl group having 1 to 6 carbon atoms.

10. The organic electroluminescence device according to claim 4, wherein in the formula (I), Ar⁵ is a unsubstituted aryl group having 6 to 18 ring carbon atoms, L¹ is an unsubstituted arylene group having 6 to 18 ring carbon atoms, R¹ to R⁸ each are independently a hydrogen atom, R¹¹ in the formula (a) is an unsubstituted alkyl group having 1 to 6 carbon atoms, and R¹² to R¹⁵ each are independently a hydrogen atom.

11. The organic electroluminescence device according to claim 1, wherein in the formula (V), at least one of Ar⁹ to Ar¹¹ is a group selected from the following formulae (m) and (n): 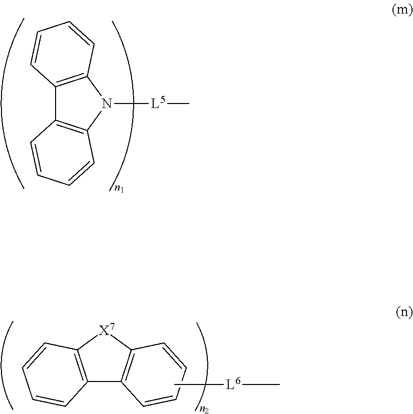
wherein X⁷ represents S or O, L⁵ represents a single bond, a residue having a valence of (n₁+1) derived from a substituted or unsubstituted arylene group having 6 to 30 ring carbon atoms, or a residue having a valence of (n₁+1) derived from a substituted or unsubstituted heteroarylene group having 5 to 30 ring atoms, L⁶ represents a single bond, a residue having a valence of (n₂+1) derived from a substituted or unsubstituted arylene group having 6 to 30 ring carbon atoms, or a residue having a valence of (n₂+1) derived from a substituted or unsubstituted heteroarylene group having 5 to 30 ring atoms, n₁ represents an integer of 1 to 3, and n₂ represents an integer of 1 to 3.

12. The organic electroluminescence device according to claim 1, wherein the formula (V) is represented by the following formula (V-1): 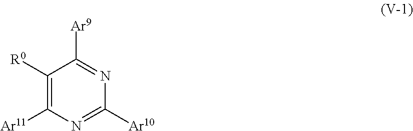
wherein Ar⁹ to Ar¹¹ and R⁰ are as defined above.

13. The organic electroluminescence device according to claim 1, wherein the formula (V) is represented by the following formula (V-2): 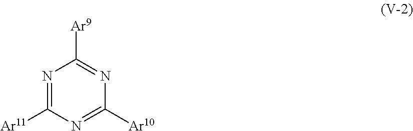
wherein Ar⁹ to Ar¹¹ are as defined above.

14. The organic electroluminescence device according to claim 1, wherein in the formula (V), Ar⁹ is a group selected from the following formulae (m) and (n), X¹ is CR⁰, and X² and X³ each are N: 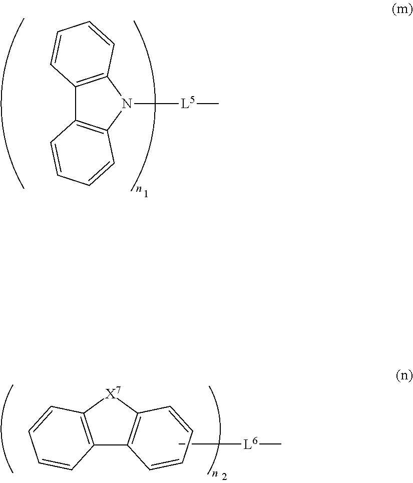
wherein X⁷, L⁵, L⁶, n₁ and n₂ are as defined above.

15. The organic electroluminescence device according to claim 1, wherein in the formula (V),
Ar⁹ is a group selected from the following formulae (m) and (n): 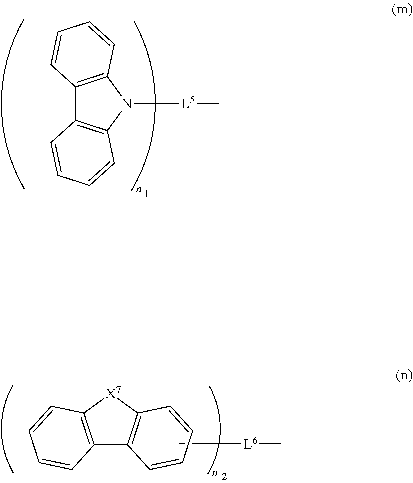
wherein X⁷ represents S or O, L⁵ represents a residue having a valence of (n₁+1) derived from a substituted or unsubstituted arylene group having 6 to 18 ring carbon atoms, L⁶ represents a residue having a valence of (n₂+1) derived from a substituted or unsubstituted arylene group having 6 to 18 ring carbon atoms, n₁ represents an integer of 1 to 2, and n₂ represents an integer of 1 to 2;
Ar¹⁰ and Ar¹¹ each are independently a hydrogen atom, or a monovalent residue containing at least one selected from aromatic hydrocarbon compounds represented by the following formulae (d) to (l), substituted or unsubstituted heteroaromatic compounds each having 5 to 12 ring atoms, and groups formed by bonding a plurality of these compounds to each other: 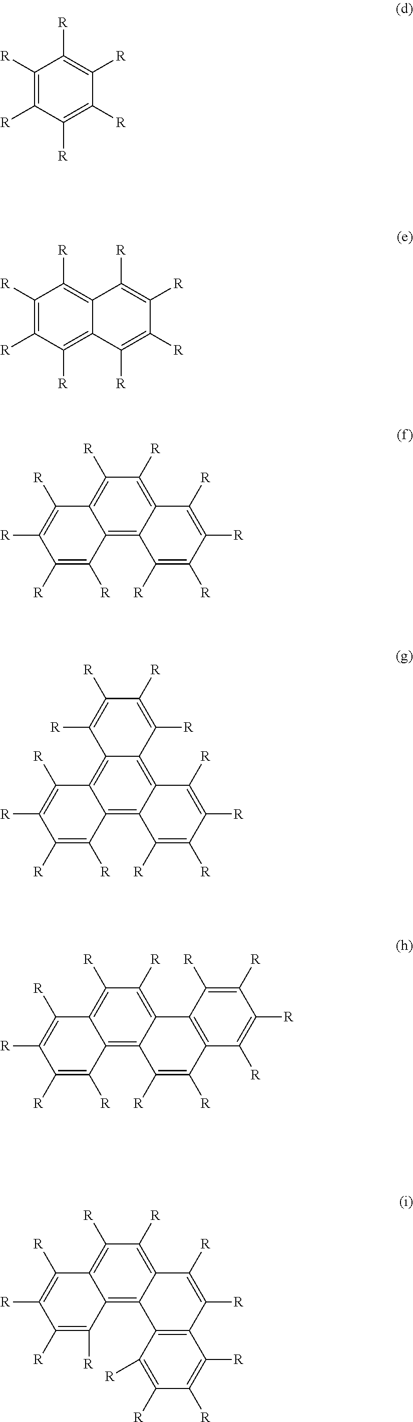 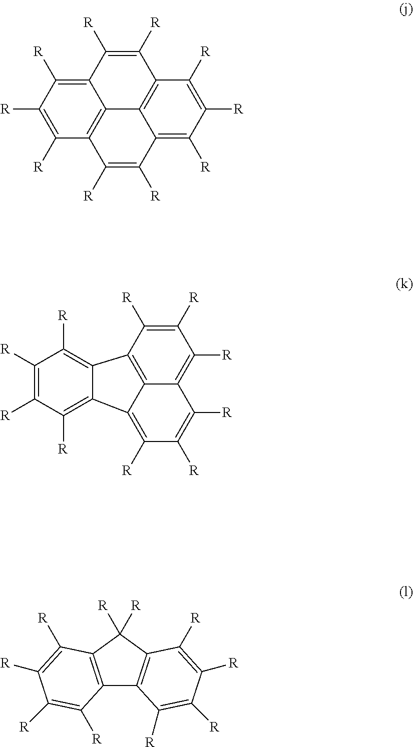
wherein R represents a hydrogen atom or an unsubstituted alkyl group having 1 to 6 carbon atoms;
X¹ represents CR⁰ where R⁰ is as defined above; and
X² and X³ each represent N.

16. The organic electroluminescence device according to claim 1 or 10, wherein the compound (2) is a compound selected from compounds represented by the formula (V).

17. The organic electroluminescence device according to claim 16, wherein in the formula (V),
Ar⁹ is a group selected from the following formula (m) and (n): 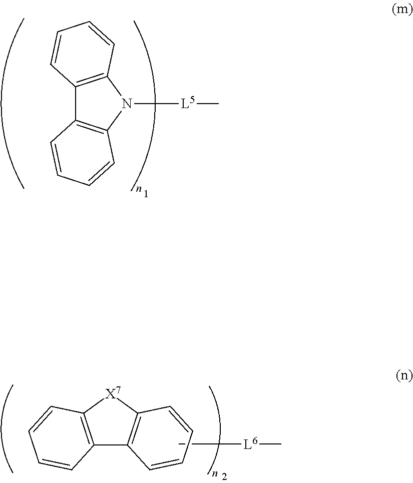
wherein X⁷ represents S or O, L⁵ represents a residue having a valence of (n₁+1) derived from a substituted or unsubstituted arylene group having 6 to 18 ring carbon atoms, L⁶ represents a residue having a valence of (n₂+1) derived from a substituted or unsubstituted arylene group having 6 to 18 ring carbon atoms, n₁ represents an integer of 1 to 2, and n₂ represents an integer of 1 to 2;
Ar¹⁰ and Ar¹¹ each independently represent a hydrogen atom, or a monovalent residue containing at least one selected from aromatic hydrocarbon compounds represented by the following formulae (d) to (l), substituted or unsubstituted heteroaromatic compounds each having 5 to 12 ring atoms, and groups formed by bonding a plurality of these compounds to each other: 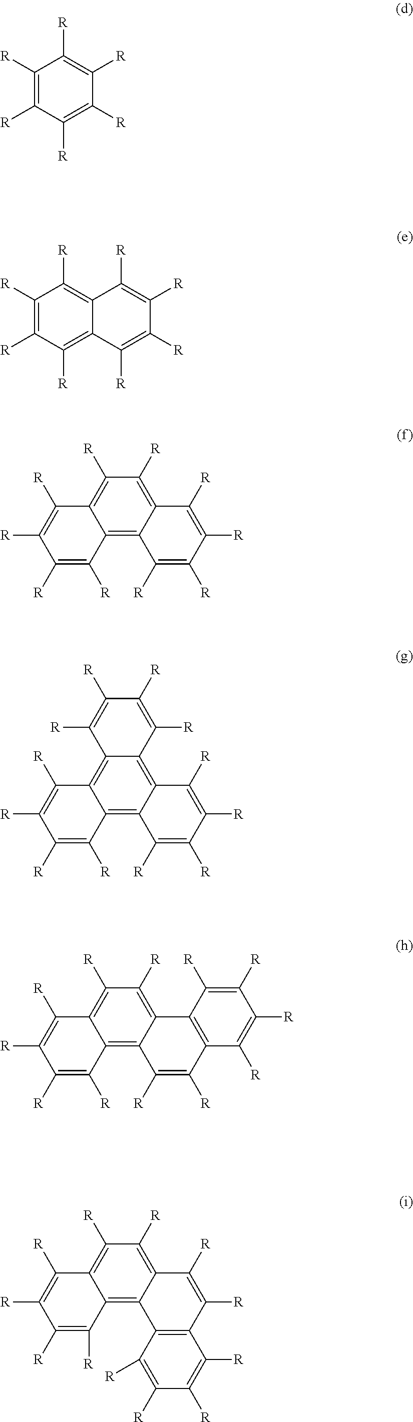 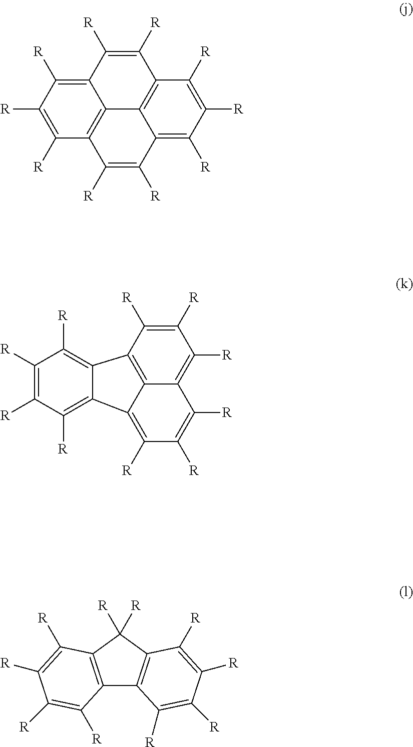
wherein R represents a hydrogen atom or an unsubstituted alkyl group having 1 to 6 carbon atoms;
X¹ represents CR⁰where R⁰ is as defined above; and
X² and X³ each represent N.

18. The organic electroluminescence device according to claim 1, wherein the compound (1) is a compound selected from compounds represented by the formula (I), and the compound (2) is a compound selected from compounds represented by the formula (V).

19. An organic electroluminescence device comprising a cathode, an anode, and an organic thin film layer which is formed of one layer or plural layers at least containing a light emitting layer and which is sandwiched between the cathode and the anode,
the device further comprising an electron transporting layer between the light emitting layer and the cathode,
wherein the electron transporting layer contains at least the following compound (1′) and the following compound (2), and
compound (1′) is a compound selected from the compounds represented by the following formula (I) and compound (2) is a compound selected from compounds represented by the following formula (IV) and compounds represented by the following formula (V): 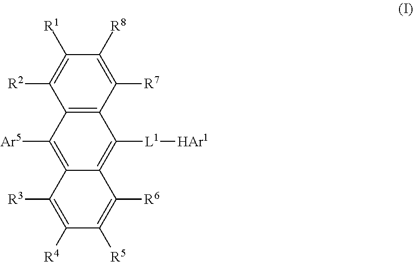
wherein L¹ represents a single bond, a substituted or unsubstituted arylene group having 6 to 30 ring carbon atoms, or a substituted or unsubstituted heteroarylene group having 5 to 30 ring atoms;
Ar⁵ represents a substituted or unsubstituted aryl group having 6 to 30 ring carbon atoms, or a substituted or unsubstituted heteroaryl group having 5 to 30 ring atoms; and
HAr¹ represents a group represented by the following formula (a): 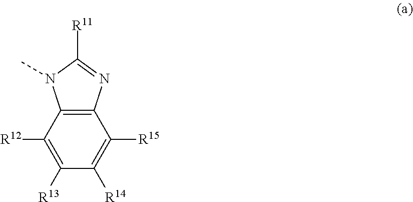
wherein R¹ to R⁸ and R¹¹ to R¹⁵ each independently represent a hydrogen atom, a fluorine atom, a cyano group, a substituted or unsubstituted alkyl group having 1 to 20 carbon atom, a substituted or unsubstituted cycloalkyl group having 3 to 20 ring carbon atoms, a substituted or unsubstituted alkoxy group having 1 to 20 carbon atoms, a substituted or unsubstituted aryloxy group having 6 to 30 ring carbon atoms, a substituted or unsubstituted alkylthio group having 1 to 20 carbon atoms, a substituted or unsubstituted arylthio group having 6 to 30 ring carbon atoms, a substituted or unsubstituted aryl group having 6 to 30 ring carbon atoms, a substituted or unsubstituted heteroaryl group having 5 to 30 ring atoms, or a group represented by —Si(R₁₀₁)(R₁₀₂)(R₁₀₃) where R₁₀₁ to R₁₀₃ each independently represent a hydrogen atom, a substituted or unsubstituted alkyl group having 1 to 20 carbon atoms, or a substituted or unsubstituted aryl group having 6 to 30 ring carbon atoms; 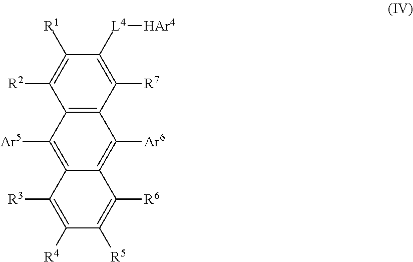
wherein Ar⁵, Ar⁶, and R¹ to R⁷ are as defined above;
L⁴ represents a single bond, a substituted or unsubstituted aryl ene group having 6 to 30 ring carbon atoms, or a substituted or unsubstituted heteroarylene group having 5 to 30 ring atoms; and
HAr⁴ represents a group represented by the following formula (a) or (c): 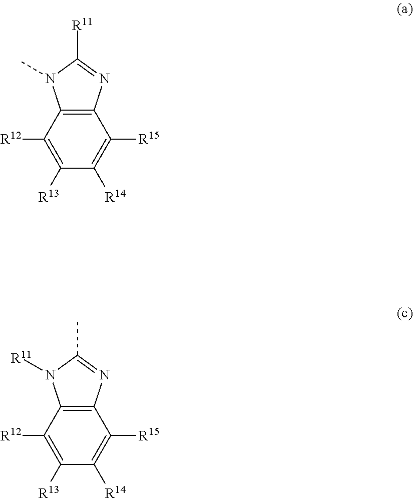
wherein R¹¹ to R¹⁵ are as defined above; 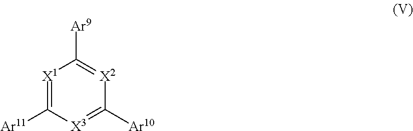
wherein Ar⁹ to Ar¹¹ each independently represent a hydrogen atom, or a monovalent residue containing at least one selected from aromatic hydrocarbon compounds represented by the following formulae (d) to (l), substituted or unsubstituted heteroaromatic compounds each having 5 to 30 ring atoms, and groups formed by bonding a plurality of these compounds to each other, and when a plurality of the compounds is bonded, the compounds which each constitute a bonding unit may be the same or different; 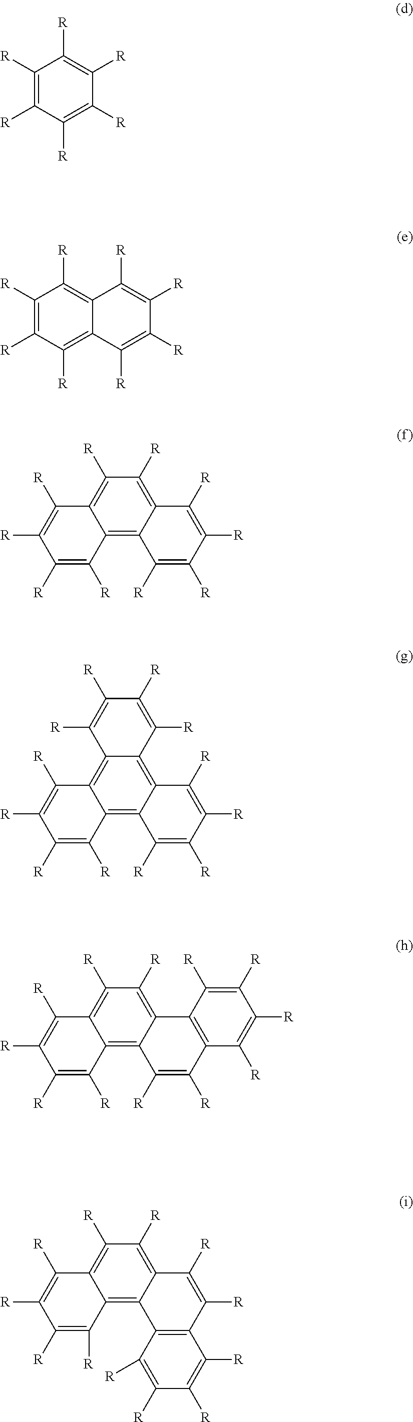 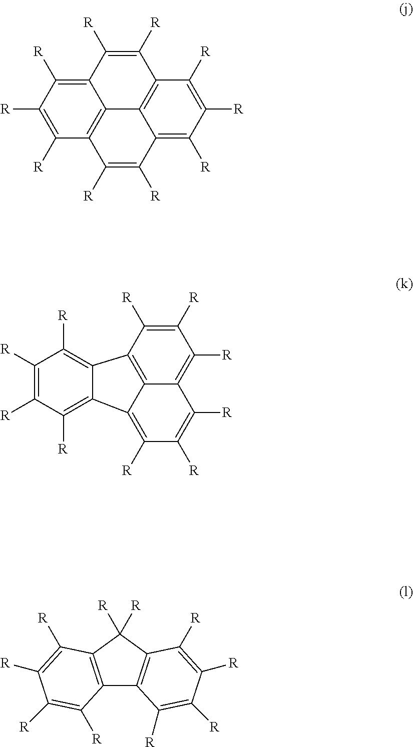
wherein R represents a hydrogen atom, a fluorine atom, a cyano group, or a substituted or unsubstituted alkyl group having 1 to 20 carbon atoms;
X¹ to X³ each independently represent N or CR⁰, with the proviso that at least one is N; and
R⁰ represents a hydrogen atom, a substituted or unsubstituted alkyl group having 1 to 20 carbon atoms, or a substituted or unsubstituted aryl group having 6 to 30 ring carbon atoms, and when the formula has plural R⁰'s, they may be the same or different.

20. The organic electroluminescence device according to claim 19, wherein in the formula (I), Ar⁵ is an unsubstituted aryl group having 6 to 18 ring carbon atoms, L¹ is an unsubstituted arylene group having 6 to 18 ring carbon atoms, R¹ to R⁸ each are independently a hydrogen atom, R¹¹ in the formula (a) is an unsubstituted alkyl group having 1 to 6 carbon atoms, and R¹² to R¹⁵ in the formula (a) each are independently a hydrogen atom.

21. The organic electroluminescence device according to claim 19, wherein in the formula (V),
Ar⁹ is a group selected from the following formula (m) and (n): 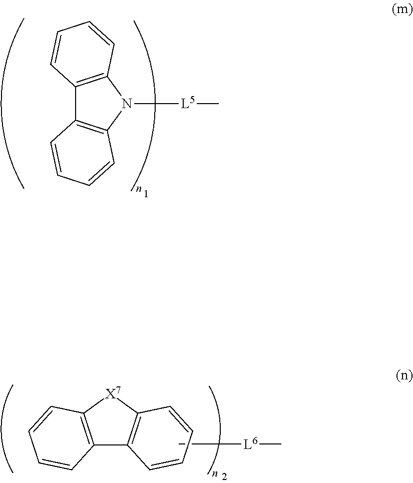
wherein X⁷ represents S or O, L⁵ represents a residue having a valence of (n₁+1) derived from a substituted or unsubstituted arylene group having 6 to 18 ring carbon atoms, L⁶ represents a residue having a valence of (n₂+1) derived from a substituted or unsubstituted arylene group having 6 to 18 ring carbon atoms, n₁ represents an integer of 1 to 2, and n₂ represents an integer of 1 to 2;
Ar¹⁰ and Ar¹¹ each independently represent a hydrogen atom, or a monovalent residue containing at least one selected from aromatic hydrocarbon compounds represented by the following formulae (d) to (l), substituted or unsubstituted heteroaromatic compounds each having 5 to 12 ring atoms, and groups formed by bonding a plurality of these compounds to each other: 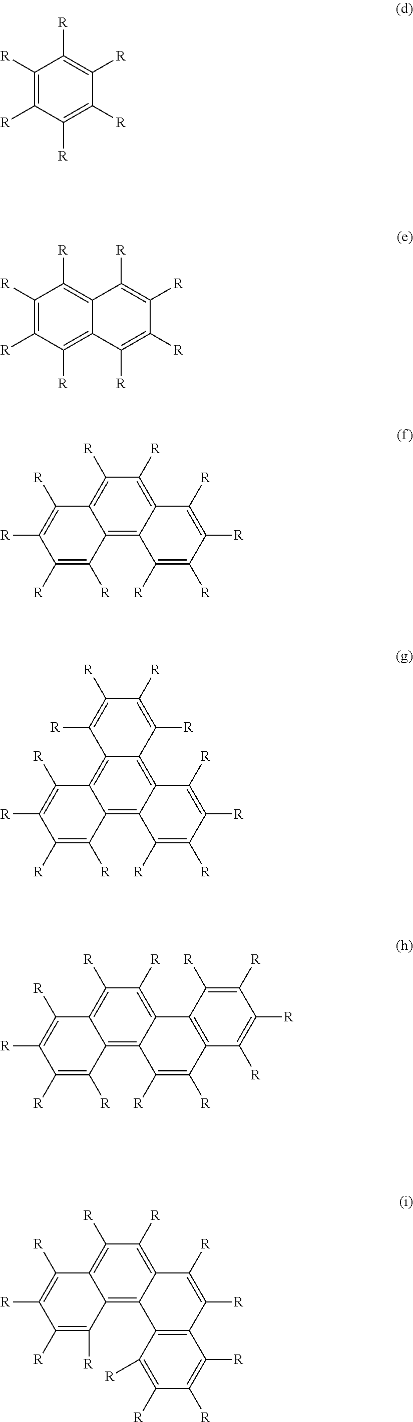 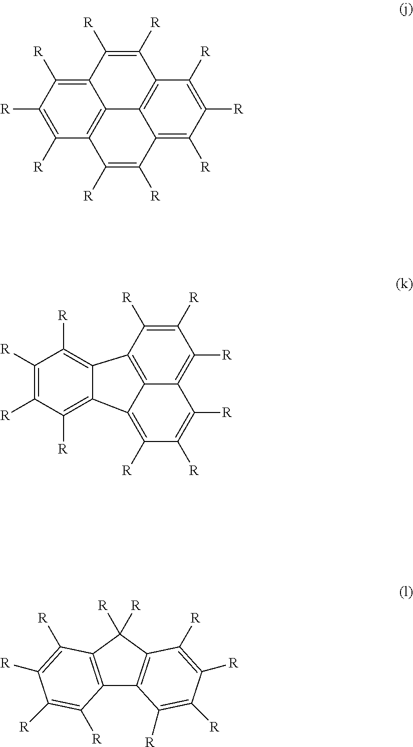
wherein R represents a hydrogen atom or an unsubstituted alkyl group having 1 to 6 carbon atoms;
X¹ represents CR⁰where R⁰ is as defined above; and
X² and X³ each represent N.

22. The organic electroluminescence device according to claim 1 or 19, wherein the ratio of the compound (1) to the compound (2) is 1/9 to 9/1 by mass.

23. The organic electroluminescence device according to claim 1 or 19, wherein the light emitting layer is adjacent to the electron transporting layer containing the compound (1) and the compound (2).

24. An electronic device provided with the organic electroluminescence device according to claim 1 or 19.
